(19) United States
(12) Patent Application Publication
(10) Pub. No.: US 2026/0279411 A1
(43) Pub. Date: Sep. 17, 2026

(54) SEMICONDUCTOR MEMORY DEVICE

(71) Applicant: Kioxia Corporation, Tokyo (JP)

(72) Inventor: Hisashi KATO, Yokkaichi (JP)

(73) Assignee: Kioxia Corporation, Tokyo (JP)

(21) Appl. No.: 19/307,132

(22) Filed: Aug. 22, 2025

(30) Foreign Application Priority Data
Mar. 14, 2025 (JP) 2025-041487

(51) Int. Cl. G11C 5/06; G11C 16/04; H01L 23/00; H01L 25/18; H10B 43/10; H10B 43/27; H10B 43/35; H10B 43/40; H10D 80/30

(52) U.S. Cl. CPC G11C 5/063; G11C 16/0483; H10B 43/10; H10B 43/27; H10B 43/35; H10B 43/40; H10D 80/30; H10W 90/00; H10W 90/792

(57) ABSTRACT

According to one embodiment, a semiconductor memory device includes a first chip and a second chip provided on a first surface of the first chip in a first direction. The second chip includes: a first region including a first layer stack in which first insulating layers and first interconnect layers are alternately stacked in the first direction; a second region including a second layer stack in which the first insulating layers and second insulating layers are alternately stacked in the first direction; a first memory pillar arranged in the first region and penetrating the first layer stack in the first direction; and a first contact arranged in the second region, penetrating the second layer stack in the first direction, and connected to a second interconnect layer above the second layer stack.

### CROSS-REFERENCE TO RELATED APPLICATION(S)

This application is based upon and claims the benefit of priority from Japanese Patent Application No. 2025-041487, filed Mar. 14, 2025, the entire contents of which are incorporated herein by reference.

### FIELD

Embodiments described herein relate generally to a semiconductor memory device.

### BACKGROUND

A NAND flash memory is known as a semiconductor memory device capable of storing data in a non-volatile manner.

### BRIEF DESCRIPTION OF DRAWINGS

FIG. 1 is a block diagram illustrating an example of a configuration of a memory system including a semiconductor memory device according to the first embodiment.

FIG. 2 is a circuit diagram illustrating an example of a circuit configuration of a memory cell array included in the semiconductor memory device according to the first embodiment.

FIG. 3 is a perspective view illustrating an outline of a bonding structure of the semiconductor memory device according to the first embodiment.

FIG. 4 is a plan view illustrating an example of a planar layout of the semiconductor memory device according to the first embodiment.

FIG. 5 is a plan view illustrating an example of a planar layout of the memory cell array in a core region of the semiconductor memory device according to the first embodiment.

FIG. 6 is a plan view illustrating an example of a planar layout in a memory area of the memory cell array included in the semiconductor memory device according to the first embodiment.

FIG. 7 is a cross-sectional view taken along line VII-VII of FIG. 6, illustrating an example of a cross-sectional structure in the memory area of the memory cell array included in the semiconductor memory device according to the first embodiment.

FIG. 8 is a cross-sectional view taken along line VIII-VIII in FIG. 7, illustrating an example of a cross-sectional structure of a memory pillar included in the semiconductor memory device according to the first embodiment.

FIG. 9 is a plan view illustrating an example of a planar layout of the core region, a peripheral region, a wall region, and a kerf region of the semiconductor memory device according to the first embodiment.

FIG. 10 is a cross-sectional view taken along line X-X of FIG. 9, illustrating an example of a cross-sectional structure in a contact area of the memory cell array included in the semiconductor memory device according to the first embodiment.

FIG. 11 is a cross-sectional view taken along line XI-XI of FIG. 9, illustrating an example of a cross-sectional structure in the contact area of the memory cell array included in the semiconductor memory device according to the first embodiment.

FIG. 12 is a cross-sectional view taken along line XII-XII of FIG. 9, illustrating an example of a cross-sectional structure in the peripheral region, the wall region, and the kerf region of the semiconductor memory device according to the first embodiment.

FIG. 13 is a cross-sectional view illustrating an example of a cross-sectional structure of the core region of the semiconductor memory device according to the first embodiment.

FIG. 14 is a cross-sectional view illustrating an example of a cross-sectional structure of the peripheral region and the wall region of the semiconductor memory device according to the first embodiment.

FIG. 15 is a cross-sectional view illustrating an example of a cross-sectional structure in the process of manufacturing the semiconductor memory device according to the first embodiment.

FIG. 16 is a cross-sectional view illustrating an example of a cross-sectional structure in the process of manufacturing the semiconductor memory device according to the first embodiment.

FIG. 17 is a cross-sectional view illustrating an example of a cross-sectional structure in the process of manufacturing the semiconductor memory device according to the first embodiment.

FIG. 18 is a cross-sectional view illustrating an example of a cross-sectional structure in the process of manufacturing the semiconductor memory device according to the first embodiment.

FIG. 19 is a cross-sectional view illustrating an example of a cross-sectional structure in the process of manufacturing the semiconductor memory device according to the first embodiment.

FIG. 20 is a cross-sectional view illustrating an example of a cross-sectional structure in the process of manufacturing the semiconductor memory device according to the first embodiment.

FIG. 21 is a cross-sectional view illustrating an example of a cross-sectional structure in the process of manufacturing the semiconductor memory device according to the first embodiment.

FIG. 22 is a cross-sectional view illustrating an example of a cross-sectional structure in the process of manufacturing the semiconductor memory device according to the first embodiment.

FIG. 23 is a cross-sectional view illustrating an example of a cross-sectional structure in the process of manufacturing the semiconductor memory device according to the first embodiment.

FIG. 24 is a cross-sectional view illustrating an example of a cross-sectional structure in the process of manufacturing the semiconductor memory device according to the first embodiment.

FIG. 25 is a cross-sectional view illustrating an example of a cross-sectional structure in the process of manufacturing the semiconductor memory device according to the first embodiment.

FIG. 26 is a cross-sectional view illustrating an example of a cross-sectional structure in the process of manufacturing the semiconductor memory device according to the first embodiment.

FIG. 27 is a cross-sectional view illustrating an example of a cross-sectional structure in the process of manufacturing the semiconductor memory device according to the first embodiment.

FIG. 28 is a cross-sectional view illustrating an example of a cross-sectional structure in the process of manufacturing the semiconductor memory device according to the first embodiment.

FIG. 29 is a cross-sectional view illustrating an example of a cross-sectional structure in the process of manufacturing the semiconductor memory device according to the first embodiment.

FIG. 30 is a cross-sectional view illustrating an example of a cross-sectional structure in the process of manufacturing the semiconductor memory device according to the first embodiment.

FIG. 31 is a cross-sectional view illustrating an example of a cross-sectional structure in the process of manufacturing the semiconductor memory device according to the first embodiment.

FIG. 32 is a cross-sectional view illustrating an example of a cross-sectional structure in the process of manufacturing the semiconductor memory device according to the first embodiment.

FIG. 33 is a cross-sectional view illustrating an example of a cross-sectional structure in the process of manufacturing the semiconductor memory device according to the first embodiment.

FIG. 34 is a cross-sectional view illustrating an example of a cross-sectional structure in the process of manufacturing the semiconductor memory device according to the first embodiment.

FIG. 35 is a cross-sectional view illustrating an example of a cross-sectional structure in the process of manufacturing the semiconductor memory device according to the first embodiment.

FIG. 36 is a cross-sectional view illustrating an example of a cross-sectional structure in the process of manufacturing the semiconductor memory device according to the first embodiment.

FIG. 37 is a cross-sectional view illustrating an example of a cross-sectional structure in the process of manufacturing the semiconductor memory device according to the first embodiment.

FIG. 38 is a cross-sectional view illustrating an example of a cross-sectional structure in the process of manufacturing the semiconductor memory device according to the first embodiment.

FIG. 39 is a cross-sectional view illustrating an example of a cross-sectional structure in the process of manufacturing the semiconductor memory device according to the first embodiment.

FIG. 40 is a cross-sectional view illustrating an example of a cross-sectional structure in the process of manufacturing the semiconductor memory device according to the first embodiment.

FIG. 41 is a cross-sectional view illustrating an example of a cross-sectional structure in the process of manufacturing the semiconductor memory device according to the first embodiment.

FIG. 42 is a cross-sectional view illustrating an example of a cross-sectional structure in a peripheral region of a semiconductor memory device according to a first modification of the first embodiment.

FIG. 43 is a cross-sectional view illustrating an example of a cross-sectional structure in a peripheral region of a semiconductor memory device according to a second modification of the first embodiment.

FIG. 44 is a cross-sectional view illustrating an example of a cross-sectional structure in a peripheral region of a semiconductor memory device according to a third modification of the first embodiment.

FIG. 45 is a cross-sectional view illustrating an example of a cross-sectional structure in a peripheral region of a semiconductor memory device according to a fourth modification of the first embodiment.

FIG. 46 is a cross-sectional view illustrating an example of a cross-sectional structure in a peripheral region of a semiconductor memory device according to a fifth modification of the first embodiment.

FIG. 47 is a cross-sectional view illustrating an example of a cross-sectional structure in a peripheral region of a semiconductor memory device according to a sixth modification of the first embodiment.

FIG. 48 is a cross-sectional view illustrating an example of a cross-sectional structure of a core region of a semiconductor memory device according to a seventh modification of the first embodiment.

FIG. 49 is a cross-sectional view illustrating an example of a cross-sectional structure of a peripheral region of the semiconductor memory device according to the seventh modification of the first embodiment.

FIG. 50 is a cross-sectional view illustrating an example of a cross-sectional structure in the process of manufacturing the semiconductor memory device according to the seventh modification of the first embodiment.

FIG. 51 is a cross-sectional view illustrating an example of a cross-sectional structure in the process of manufacturing the semiconductor memory device according to the seventh modification of the first embodiment.

FIG. 52 is a cross-sectional view illustrating an example of a cross-sectional structure in the process of manufacturing the semiconductor memory device according to the seventh modification of the first embodiment.

FIG. 53 is a cross-sectional view illustrating an example of a cross-sectional structure in the process of manufacturing the semiconductor memory device according to the seventh modification of the first embodiment.

FIG. 54 is a cross-sectional view illustrating an example of a cross-sectional structure in a peripheral region of a semiconductor memory device according to a second embodiment.

FIG. 55 is a plan view illustrating an example of a planar layout of the peripheral region of the semiconductor memory device according to the second embodiment.

FIG. 56 is a cross-sectional view illustrating an example of a cross-sectional structure in the process of manufacturing the semiconductor memory device according to the second embodiment.

FIG. 57 is a cross-sectional view illustrating an example of a cross-sectional structure in the process of manufacturing the semiconductor memory device according to the second embodiment.

FIG. 58 is a cross-sectional view illustrating an example of a cross-sectional structure in the process of manufacturing the semiconductor memory device according to the second embodiment.

FIG. 59 is a cross-sectional view illustrating an example of a cross-sectional structure in the process of manufacturing the semiconductor memory device according to the second embodiment.

FIG. 60 is a cross-sectional view illustrating an example of a cross-sectional structure in the process of manufacturing the semiconductor memory device according to the second embodiment.

FIG. 61 is a cross-sectional view illustrating an example of a cross-sectional structure in the process of manufacturing the semiconductor memory device according to the second embodiment.

FIG. 62 is a cross-sectional view illustrating an example of a cross-sectional structure in the process of manufacturing the semiconductor memory device according to the second embodiment.

FIG. 63 is a cross-sectional view illustrating an example of a cross-sectional structure in the process of manufacturing the semiconductor memory device according to the second embodiment.

FIG. 64 is a cross-sectional view illustrating an example of a cross-sectional structure in the process of manufacturing the semiconductor memory device according to the second embodiment.

FIG. 65 is a cross-sectional view illustrating an example of a cross-sectional structure in the process of manufacturing the semiconductor memory device according to the second embodiment.

FIG. 66 is a cross-sectional view illustrating an example of a cross-sectional structure in the process of manufacturing the semiconductor memory device according to the second embodiment.

FIG. 67 is a cross-sectional view illustrating an example of a cross-sectional structure in a peripheral region of a semiconductor memory device according to a modification of the second embodiment.

FIG. 68 is a cross-sectional view illustrating an example of a cross-sectional structure in the process of manufacturing the semiconductor memory device according to the modification of the second embodiment.

FIG. 69 is a cross-sectional view illustrating an example of a cross-sectional structure in the process of manufacturing the semiconductor memory device according to the modification of the second embodiment.

FIG. 70 is a cross-sectional view illustrating an example of a cross-sectional structure in the process of manufacturing the semiconductor memory device according to the modification of the second embodiment.

FIG. 71 is a cross-sectional view illustrating an example of a cross-sectional structure in the process of manufacturing the semiconductor memory device according to the modification of the second embodiment.

FIG. 72 is a cross-sectional view illustrating an example of a cross-sectional structure in the process of manufacturing the semiconductor memory device according to the modification of the second embodiment.

FIG. 73 is a cross-sectional view illustrating an example of a cross-sectional structure in a peripheral region of a semiconductor memory device according to a third embodiment.

FIG. 74 is a plan view illustrating an example of a planar layout of the peripheral region of the semiconductor memory device according to the third embodiment.

FIG. 75 is a cross-sectional view illustrating an example of a cross-sectional structure in the process of manufacturing the semiconductor memory device according to the third embodiment.

FIG. 76 is a cross-sectional view illustrating an example of a cross-sectional structure in the process of manufacturing the semiconductor memory device according to the third embodiment.

FIG. 77 is a cross-sectional view illustrating an example of a cross-sectional structure in the process of manufacturing the semiconductor memory device according to the third embodiment.

FIG. 78 is a cross-sectional view illustrating an example of a cross-sectional structure in the process of manufacturing the semiconductor memory device according to the third embodiment.

FIG. 79 is a cross-sectional view illustrating an example of a cross-sectional structure in the process of manufacturing the semiconductor memory device according to the third embodiment.

FIG. 80 is a cross-sectional view illustrating an example of a cross-sectional structure in the process of manufacturing the semiconductor memory device according to the third embodiment.

FIG. 81 is a cross-sectional view illustrating an example of a cross-sectional structure in the process of manufacturing the semiconductor memory device according to the third embodiment.

FIG. 82 is a cross-sectional view illustrating an example of a cross-sectional structure in the process of manufacturing the semiconductor memory device according to the third embodiment.

FIG. 83 is a cross-sectional view illustrating an example of a cross-sectional structure in the process of manufacturing the semiconductor memory device according to the third embodiment.

FIG. 84 is a cross-sectional view illustrating an example of a cross-sectional structure in the process of manufacturing the semiconductor memory device according to the third embodiment.

FIG. 85 is a cross-sectional view illustrating an example of a cross-sectional structure in a peripheral region of a semiconductor memory device according to a modification of the third embodiment.

FIG. 86 is a plan view illustrating an example of a planar layout of a memory cell array in a core region of a semiconductor memory device according to a fourth embodiment.

FIG. 87 is a plan view illustrating an example of a planar layout in a contact area of the memory cell array included in the semiconductor memory device according to the fourth embodiment.

FIG. 88 is a cross-sectional view taken along line S1-S1 of FIG. 87, illustrating an example of a cross-sectional structure in the contact area of the memory cell array included in the semiconductor memory device according to the fourth embodiment.

FIG. 89 is a cross-sectional view illustrating an example of a cross-sectional structure in a peripheral region of the semiconductor memory device according to the fourth embodiment.

FIG. 90 is a cross-sectional view illustrating an example of a cross-sectional structure of the peripheral region of the semiconductor memory device according to the fourth embodiment.

FIG. 91 is a cross-sectional view illustrating an example of a cross-sectional structure in a peripheral region of a semiconductor memory device according to a modification of the fourth embodiment.

FIG. 92 is a cross-sectional view illustrating an example of a cross-sectional structure of the peripheral region of the semiconductor memory device according to the modification of the fourth embodiment.

### DETAILED DESCRIPTION

In general, according to one embodiment, a semiconductor memory device includes a first chip and a second chip provided on a first surface of the first chip in a first direction. The second chip includes: a first region including a first layer stack in which a plurality of first insulating layers and a plurality of first interconnect layers are alternately stacked in the first direction; a second region including a second layer stack in which the plurality of first insulating layers and a plurality of second insulating layers are alternately stacked in the first direction; a first memory pillar arranged in the first region and penetrating the first layer stack in the first direction; and a first contact arranged in the second region, penetrating the second layer stack in the first direction, and connected to a second interconnect layer above the second layer stack. Embodiments will be described with reference to the drawings. The dimensions and ratios in the drawings are not necessarily the same as actual measurements. The illustrations of configurations include omissions as appropriate. In the following description, components having substantially the same function and configuration are denoted by the same reference numeral. In a case where elements having similar configurations are particularly distinguished from each other, different letters or numbers may be added to the end of the same reference numeral.

### 1. FIRST EMBODIMENT

### 1.1 Configuration

### 1.1.1 Configuration of Memory System

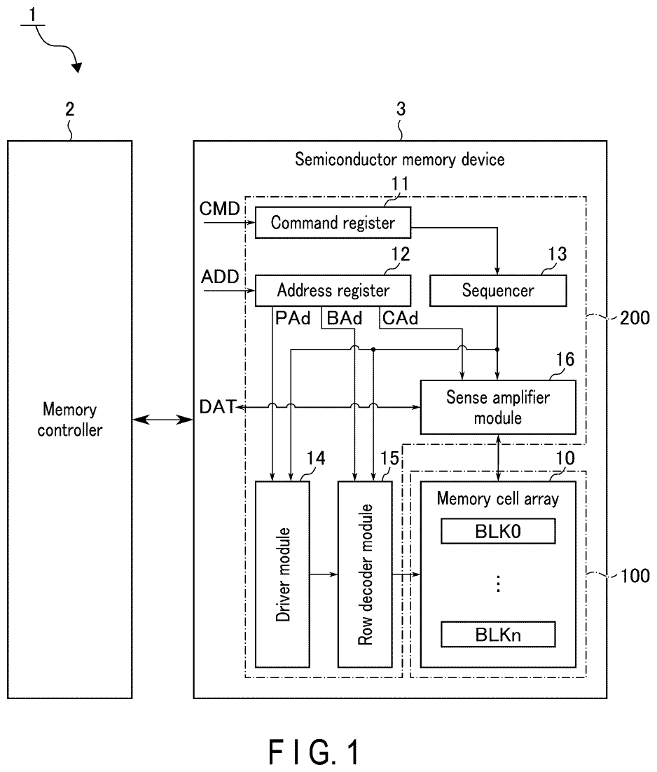

A configuration of a memory system including a semiconductor memory device according to the first embodiment will be described with reference to FIG. 1. FIG. 1 is a block diagram illustrating an example of a configuration of a memory system including a semiconductor memory device according to the first embodiment. A memory system 1 is a memory device configured to be connected to an external host device (not illustrated). The memory system 1 is, for example, a memory card such as an SD™ card, a universal flash storage (UFS), or a solid state drive (SSD). As illustrated in FIG. 1, the memory system 1 includes a memory controller 2 and a semiconductor memory device 3.

The memory controller 2 is, for example, an integrated circuit such as a system-on-a-chip (SoC). The memory controller 2 controls the semiconductor memory device 3 based on requests from the host device. For example, the memory controller 2 writes data requested to be written by the host device to the semiconductor memory device 3. In addition, the memory controller 2 reads data requested to be read by the host device from the semiconductor memory device 3 and transmits the data to the host device.

The semiconductor memory device 3 is a memory that stores data in a nonvolatile manner. The semiconductor memory device 3 is, for example, a NAND flash memory. Hereinafter, a NAND flash memory will be described as an example of the semiconductor memory device 3.

### 1.1.2 Configuration of Semiconductor Memory Device

The configuration of the semiconductor memory device 3 will be described with continued reference to FIG. 1. As illustrated in FIG. 1, the semiconductor memory device 3 includes an array chip 100 and a circuit chip 200.

The array chip 100 includes, for example, a memory cell array 10.

The memory cell array 10 includes a plurality of blocks BLK0 to BLKn (n is an integer greater than or equal to 1). Each block BLK is a collection of a plurality of memory cell transistors capable of storing data in a non-volatile manner. Each block BLK is used, for example, as a data erasing unit. The memory cell array 10 is also provided with a plurality of bit lines and a plurality of word lines. Each memory cell transistor is associated with, for example, one bit line and one word line. A detailed configuration of the memory cell array 10 will be described later.

The circuit chip 200 includes, for example, a command register 11, an address register 12, a sequencer 13, a driver module 14, a row decoder module 15, and a sense amplifier module 16.

The command register 11 is a circuit that stores commands CMD received by the semiconductor memory device 3 from the memory controller 2. The commands CMD include, for example, commands for causing the sequencer 13 to execute a read operation, a write operation, an erase operation, and the like.

The address register 12 is a circuit that stores addresses ADD received by the semiconductor memory device 3 from the memory controller 2. The addresses ADD include, for example, a block address BAd, a page address PAd, and a column address CAd. For example, the block address BAd, the page address PAd, and the column address CAd are used to select a block BLK, a word line, and a bit line, respectively.

The sequencer 13 is a circuit that controls the operation of other circuits according to a predetermined program. The sequencer 13 controls the entire operation of the semiconductor memory device 3. For example, the sequencer 13 controls the driver module 14, the row decoder module 15, the sense amplifier module 16, and the like based on the command CMD stored in the command register 11. For example, the sequencer 13 executes the read operation, the write operation, the erase operation, and the like.

The driver module 14 is a circuit that generates voltages used in the read operation, the write operation, the erase operation, and the like. The driver module 14 applies the generated voltage to a signal line corresponding to a selected word line based on the page address PAd stored in the address register 12, for example.

The row decoder module 15 is a circuit that selects one corresponding block BLK in the memory cell array 10 based on the block address BAd stored in the address register 12. The row decoder module 15 transfers the voltage applied to the signal line corresponding to the selected word line to the selected word line in the selected block BLK, for example.

The sense amplifier module 16 is a circuit that selects a bit line based on the column address CAd stored in the address register 12. For example, in the write operation, the sense amplifier module 16 applies a voltage based on write data DAT received from the memory controller 2 to the selected bit line. In addition, in the read operation, the sense amplifier module 16 determines the data stored in the memory cell transistor based on the voltage of the selected bit line. The sense amplifier module 16 transfers the determination result to the memory controller 2 as read data DAT.

### 1.1.3 Circuit Configuration of Memory Cell Array

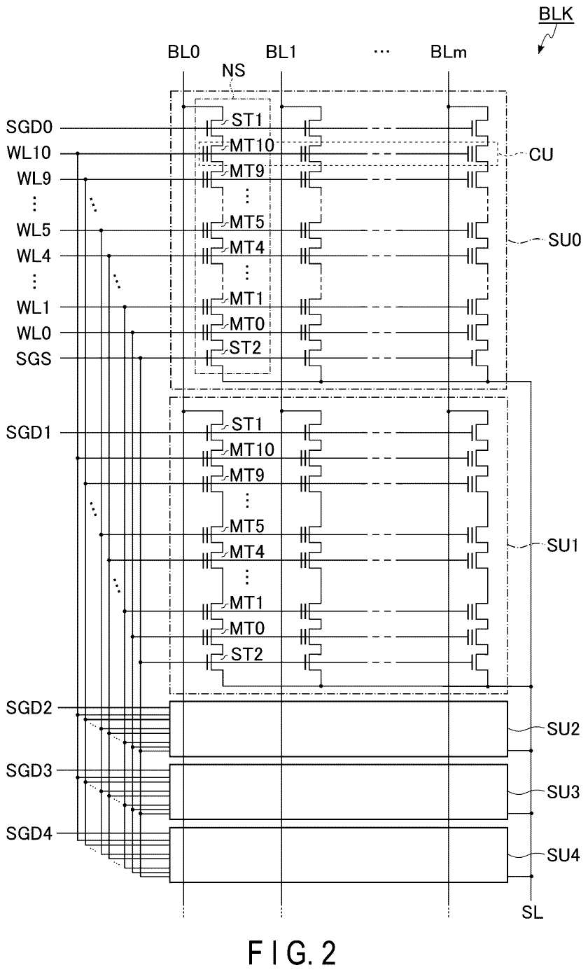

A circuit configuration of the memory cell array 10 will be described with reference to FIG. 2. FIG. 2 is a circuit diagram illustrating an example of the circuit configuration of the memory cell array 10 included in the semiconductor memory device 3 according to the first embodiment. FIG. 2 illustrates one block BLK among the blocks BLK included in the memory cell array 10. As illustrated in FIG. 2, the block BLK includes, for example, five string units SU0 to SU4. The string unit SU is a collection of NAND strings NS to be described later. For example, in the write operation or read operation, the NAND strings NS in the string unit SU are collectively selected.

Each string unit SU includes a plurality of NAND strings NS respectively associated with bit lines BL0 to BLm (m is an integer greater than or equal to 1). Each NAND string NS includes, for example, memory cell transistors MT0 to MT10 and select transistors ST1 and ST2. Each memory cell transistor MT includes a control gate and a charge storage layer, and stores data in a nonvolatile manner. Each of the select transistors ST1 and ST2 is used to select a string unit SU during various operations.

In each NAND string NS, the memory cell transistors MT0 to MT10 are connected in series. A drain of the select transistor ST1 is connected to the associated bit line BL. A source of the select transistor ST1 is connected to one end of the memory cell transistors MT0 to MT10 connected in series. A drain of the select transistor ST2 is connected to the other end of the memory cell transistors MT0 to MT10 connected in series. A source of the select transistor ST2 is connected to a source line SL.

In the same block BLK, the control gates of the memory cell transistors MT0 to MT10 are connected to word lines WL0 to WL10, respectively. The gates of the select transistors ST1 in the string units SU0 to SU4 are connected to select gate lines SGD0 to SGD4, respectively. The gates of the select transistors ST2 in the string units SU0 to SU4 are connected to a select gate line SGS.

Different column addresses CAd are assigned to the bit lines BL0 to BLm. Each bit line BL is shared by the NAND strings NS to which the same column address CAd is assigned across a plurality of blocks BLK. Each of the word lines WL0 to WL10 is provided for each block BLK. The source line SL is, for example, shared among a plurality of blocks BLK.

Such a collection of memory cell transistors MT connected to a shared word line WL in one string unit SU is referred to as, for example, a cell unit CU. For example, the storage capacity of a cell unit CU including memory cell transistors MT that each store 1-bit data is defined as “one-page data”. The cell unit CU may have a storage capacity of two-page data or more based on the number of bits of data stored in a memory cell transistor MT.

Note that the circuit configuration of the memory cell array 10 is not limited to the configuration described above. For example, the number of string units SU included in each block BLK may be designed as appropriate. The numbers of memory cell transistors MT and the number of select transistors ST1 and ST2 included in each NAND string NS can be designed as appropriate.

### 1.1.4 Structure of Semiconductor Memory Device

### 1.1.4.1 Bonding Structure of Semiconductor Memory Device

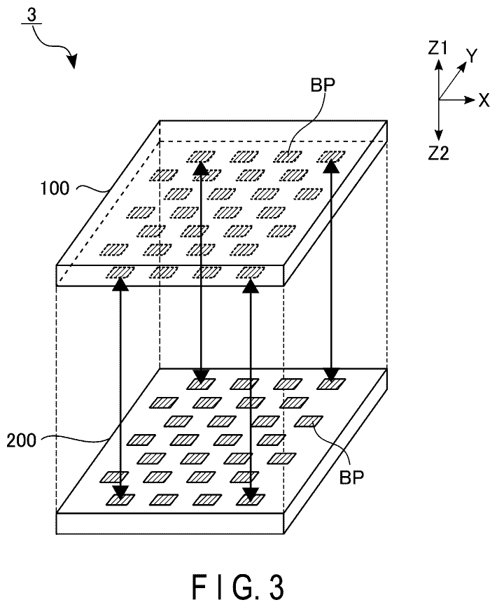

An outline of a bonding structure of the semiconductor memory device 3 will be described with reference to FIG. 3. FIG. 3 is a perspective view illustrating an outline of the bonding structure of the semiconductor memory device 3 according to the first embodiment.

As illustrated in FIG. 3, the semiconductor memory device 3 has a structure (bonding structure) in which the array chip 100 is bonded to the circuit chip 200. Each of the array chip 100 and the circuit chip 200 includes a plurality of bonding pads BP provided on surfaces facing each other. In the bonding structure, a bonding pad BP of the array chip 100 and a bonding pad BP of the circuit chip 200 are bonded to form one bonding pad BP. In other words, an electrode (conductor) forming a bonding pad BP provided on the array chip 100 and an electrode (conductor) forming a bonding pad BP provided on the circuit chip 200 are bonded to each other, whereby a bonding pad BP is formed.

Hereinafter, the surface where the array chip 100 and the circuit chip 200 are bonded (hereinafter, referred to as a “bonding surface BS”) is defined as an XY surface. Directions orthogonal to each other in the XY plane are defined as an X direction and a Y direction. The X direction corresponds to the direction in which the word lines WL extend. The Y direction corresponds to the direction in which the bit lines BL extend. Further, a direction substantially perpendicular to the XY plane and extending from the circuit chip 200 toward the array chip 100 is defined as a Z1 direction. A direction substantially perpendicular to the XY plane and extending from the array chip 100 toward the circuit chip 200 is defined as a Z2 direction. In a case where the direction is not limited to either the Z1 or Z2 direction, it is denoted as a Z direction.

### 1.1.4.2 Planar Layout of Semiconductor Memory Device

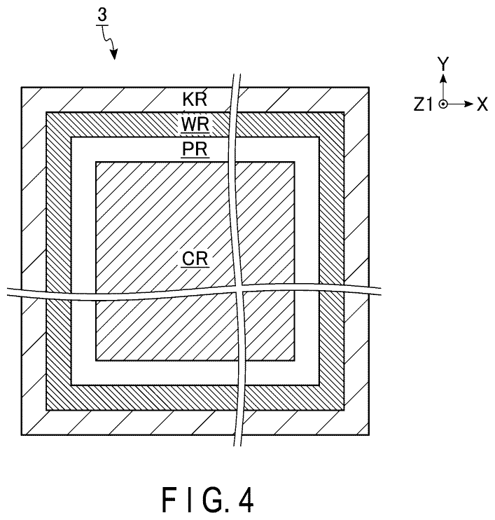

FIG. 4 is a plan view illustrating an example of a planar layout of the semiconductor memory device 3 according to the first embodiment. As illustrated in FIG. 4, the semiconductor memory device 3 (each of the array chip 100 and the circuit chip 200) includes, for example, a core region CR, a peripheral region PR, a wall region WR, and a kerf region KR.

The core region CR is, for example, a rectangular region provided in the vicinity of the center of a semiconductor substrate W1 (not illustrated) of the semiconductor memory device 3. In the core region CR, for example, the memory cell array 10, the command register 11, the address register 12, the row decoder module 15, the sense amplifier module 16, and the like are arranged.

The peripheral region PR is a rectangular frame-shaped region provided so as to surround the outer periphery of the core region CR. In the peripheral region PR, for example, the sequencer 13, the driver module 14, and the like are arranged. Furthermore, in the peripheral region PR, for example, contacts or the like for connecting an external device of the semiconductor memory device 3 to circuits provided in the circuit chip 200 are arranged.

The wall region WR is a rectangular frame-shaped region provided so as to surround the outer periphery of the peripheral region PR. In the wall region WR, at least one sealing portion ES (not illustrated) provided so as to surround the outer periphery of the peripheral region PR is arranged.

The kerf region KR is a rectangular frame-shaped region provided so as to surround the outer periphery of the wall region WR. The kerf region KR is in contact with the outermost periphery of the semiconductor memory device 3. In the kerf region KR, for example, an alignment mark or the like used during the manufacturing of the semiconductor memory device 3 is arranged.

### 1.1.4.3 Planar Layout of Memory Cell Array

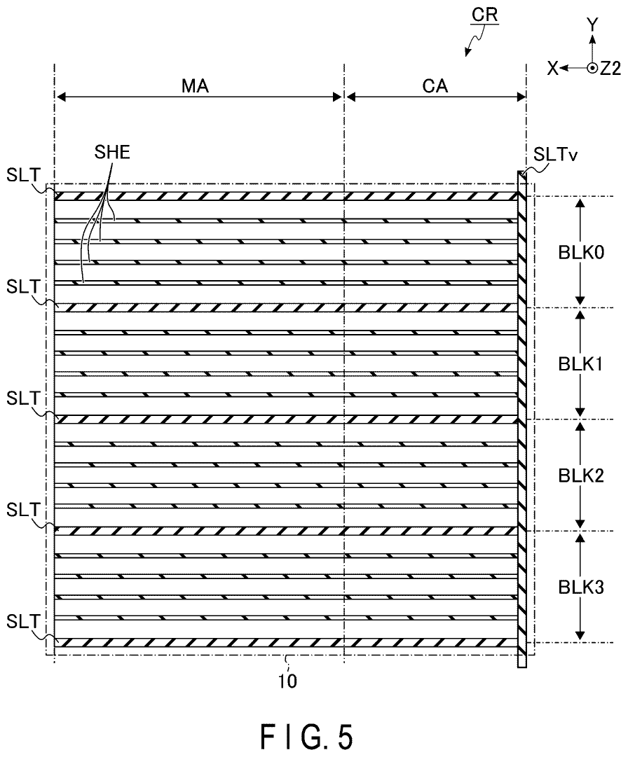

FIG. 5 is a plan view illustrating an example of a planar layout of the memory cell array 10 in the core region CR of the semiconductor memory device 3 according to the first embodiment. FIG. 5 illustrates a region corresponding to the four blocks BLK0 to BLK3 included in the memory cell array 10. As illustrated in FIG. 5, the memory cell array 10 includes, for example, a plurality of members SLT, a plurality of members SHE, and a member SLTv. In addition, the memory cell array 10 includes, for example, a memory area MA and a contact area CA arranged in the X direction.

Each member SLT has a portion extending along the X direction, and crosses the memory area MA and the contact area CA along the X direction. The members SLT are arranged in the Y direction. Each member SLT separates adjacent interconnects (for example, the word lines WL0 to WL10 and the select gate lines SGD and SGS), with the member SLT interposed between them. In each member SLT, a conductor with a side wall including an insulating spacer may be arranged, insulated from these interconnects, or an insulator may be embedded. In the memory cell array 10, each of the regions divided by the member SLT corresponds to one block BLK.

Each member SHE has a portion extending along the X direction, and crosses the memory area MA and the contact area CA along the X direction. The members SHE are arranged in the Y direction. In this example, four members SHE are arranged between each adjacent pair of members SLT in the Y direction. Each member SHE divides adjacent interconnects (at least the select gate lines SGD), with the member SHE interposed between them. Each member SHE has, for example, a structure in which an insulator is embedded. In the memory cell array 10, each of the regions divided by the members SLT and SHE corresponds to one string unit SU.

The member SLTv has a portion extending along the Y direction. The member SLTv is in contact with the end portion of each member SLT in the X direction and the end portion of each member SHE in the X direction. The member SLTv separates blocks BLK adjacent to each other in the Y direction. The member SLTv has, for example, a structure in which an insulator is embedded.

Note that the planar layout of the memory cell array 10 included in the semiconductor memory device 3 may be another layout. For example, the number of members SHE arranged between two adjacent members SLT can be designed as appropriate. The number of string units SU included in each block BLK can be changed based on the number of members SHE arranged between two adjacent members SLT.

### 1.1.4.4 Planar Layout of Memory Area

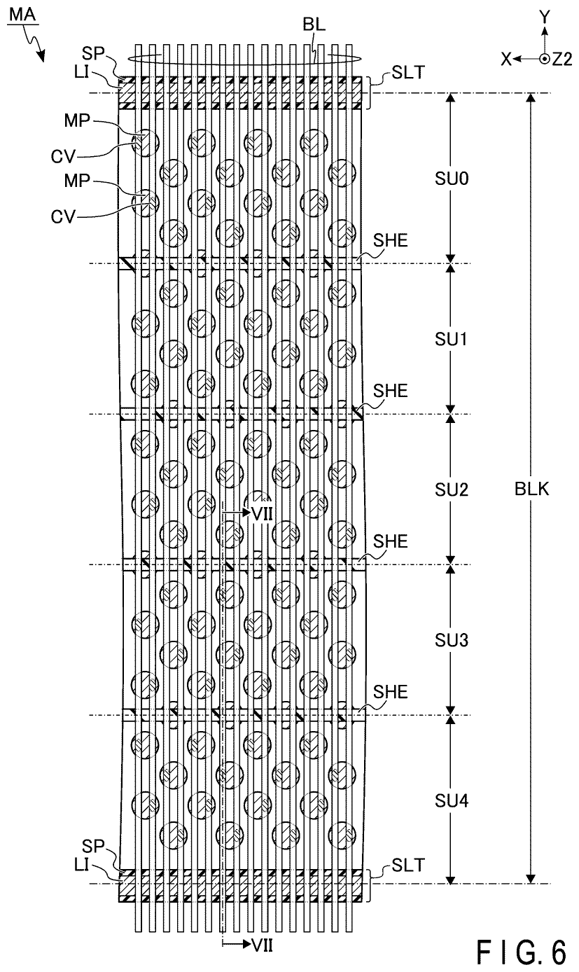

FIG. 6 is a plan view illustrating an example of a planar layout in the memory area MA of the memory cell array 10 included in the semiconductor memory device 3 according to the first embodiment. FIG. 6 illustrates a region including one block BLK (string units SU0 to SU4). As illustrated in FIG. 6, the semiconductor memory device 3 includes, for example, a plurality of memory pillars MP, a plurality of contacts CV, and a plurality of bit lines BL in the memory area MA.

The member SLT includes a contact LI and a spacer SP covering the side surfaces of the contact LI. Hereinafter, the contact LI includes a conductor 53. The spacer SP includes an insulator 54.

Each memory pillar MP is arranged in the memory area MA (core region CR) and functions as one NAND string NS. For example, the memory pillars MP are arranged in 24 staggered rows in the region between two adjacent members SLT. For example, one member SHE is placed to overlap each of the memory pillars MP of the fifth row, the memory pillars MP of the 10th row, the memory pillars MP of the 15th row, and the memory pillars MP of the 20th row, counted from the top of the page.

Each of the bit lines BL has a portion extending in the Y direction. The bit lines BL are arranged in the X direction. Each bit line BL is arranged so as to overlap at least one memory pillar MP for each string unit SU. In this example, two bit lines BL are arranged to overlap one memory pillar MP. The memory pillar MP is electrically connected to one of the overlapping bit lines BL via the contact CV. Note that the contact CV between a memory pillar MP in contact with two different select gate lines SGD and the bit line BL can be omitted.

Note that the planar layout in the memory area MA of the memory cell array 10 included in the semiconductor memory device 3 may be another layout. For example, the number and arrangement of the memory pillars MP, the members SHE, and the like arranged between two adjacent members SLT can be appropriately changed. The number of bit lines BL overlapping each memory pillar MP can be designed as appropriate.

### 1.1.4.5 Cross-sectional Structure of Memory Area

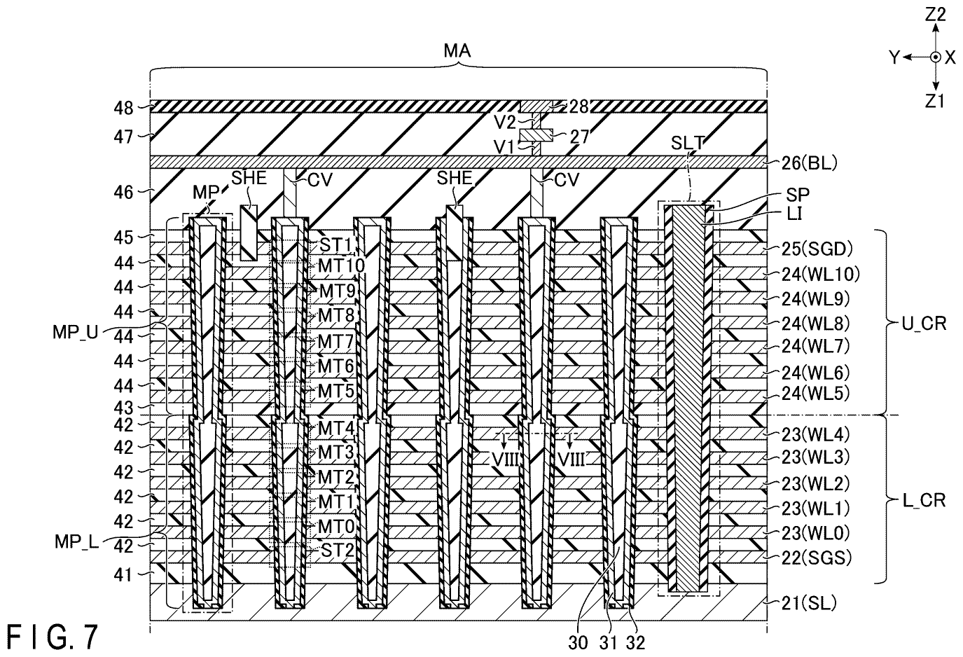

FIG. 7 is a cross-sectional view taken along line VII-VII of FIG. 6, illustrating an example of a cross-sectional structure in the memory area MA of the memory cell array 10 included in the semiconductor memory device 3 according to the first embodiment. As illustrated in FIG. 7, the memory cell array 10 further includes interconnect layers 21 to 28, insulating layers 41 to 48, and a plurality of contacts CV, V1, and V2 in the memory area MA. In the following description, the Z2 direction is defined as upward, and the Z1 direction is defined as downward.

The memory cell array 10 includes a lower stacked interconnect and an upper stacked interconnect. The lower stacked interconnect includes an interconnect layer 22 corresponding to the select gate line SGS and a plurality of interconnect layers 23 corresponding to the word lines WL0 to WL4. The upper stacked interconnect includes a plurality of interconnect layers 24 corresponding to the word lines WL5 to WL10 and an interconnect layer 25 corresponding to the select gate line SGD.

The interconnect layer 21 is provided above a semiconductor substrate W2 (not illustrated). The interconnect layer 21 is formed in, for example, a plate shape extending along the X direction on the XY plane. The interconnect layer 21 is used as the source line SL. The interconnect layer 21 includes, for example, phosphorus-doped silicon.

The insulating layer 41 and the interconnect layer 22 are stacked in this order on the interconnect layer 21. The insulating layer 41 includes, for example, silicon oxide (SiO₂). The interconnect layer 22 is formed in, for example, a plate shape extending along the X direction on the XY plane. The interconnect layer 22 is used as the select gate line SGS. The interconnect layer 22 includes, for example, tungsten.

The insulating layers 42 and the interconnect layers 23 are alternately stacked on the interconnect layer 22. The insulating layers 42 include, for example, silicon oxide. The interconnect layers 23 are formed in, for example, a plate shape extending along the X direction on the XY plane. The interconnect layers 23 are used as the word lines WL0 to WL4 in order from the interconnect layer 22 side. The interconnect layers 23 includes, for example, tungsten.

The insulating layer 43 is provided on the uppermost insulating layer 42. The insulating layer 43 includes, for example, tetra ethoxy silane (TEOS). The interconnect layers 24 and insulating layers 44 are alternately stacked on the insulating layer 43. The interconnect layers 24 are formed in, for example, a plate shape extending along the X direction on the XY plane. The interconnect layers 24 are used as the word lines WL5 to WL10 in order from the insulating layer 43 side. The interconnect layers 24 include, for example, tungsten. The insulating layers 44 include, for example, silicon oxide.

The interconnect layer 25, the insulating layer 45, and the insulating layer 46 are stacked in this order on the uppermost insulating layer 44. The interconnect layer 25 is formed in, for example, a plate shape extending along the X direction on the XY plane. The interconnect layer 25 is used as the select gate line SGD. The interconnect layer 25 includes, for example, tungsten. The insulating layer 46 can include a plurality of insulating films. The insulating layers 45 and 46 include, for example, silicon oxide.

Hereinafter, a structure in which a plurality of insulating layers (the insulating layers 41 and 42) and a plurality of interconnect layers (the interconnect layers 22 and 23) are alternately stacked in the Z direction is referred to as a “lower layer stack L_CR”. A structure in which a plurality of insulating layers (the insulating layers 43 to 45) and a plurality of interconnect layers (the interconnect layers 24 and 25) are alternately stacked in the Z direction is referred to as an “upper layer stack U_CR”. The core region CR includes the lower and upper layer stacks L_CR and U_CR.

The interconnect layer 26 is provided on the insulating layer 46. The interconnect layer 26 is formed in, for example, a line shape extending along the Y direction. The interconnect layer 26 is used as a bit line BL. In a region not illustrated, a plurality of interconnect layers 26 are arranged along the X direction. The interconnect layers 26 include, for example, copper.

The interconnect layer 27 is provided above the interconnect layer 26. The interconnect layer 27 is an interconnect that relays connection between the bit line BL and the sense amplifier module 16. The interconnect layers 26 and 27 are connected via a contact V1. An interconnect layer 28 is provided above the interconnect layer 27. The interconnect layer 28 corresponds to a bonding pad BP used for bonding. The interconnect layers 27 and 28 are connected via a contact V2. The interconnect layer 27 and the side surface of each of the contacts V1 and V2 are covered with an insulating layer 47. The insulating layer 47 can include a plurality of insulating films. The side surface of the interconnect layer 28 is covered with the insulating layer 48. The memory cell array 10 may include a plurality of interconnect layers 27 and a plurality of interconnect layers 28. The interconnect layers 27 and 28 include, for example, copper.

Each of the memory pillars MP is provided to extend along the Z direction and has, for example, a cylindrical shape. Each of the memory pillars MP includes an upper pillar MP_U and a lower pillar MP_L. The lower pillar MP_L penetrates the lower layer stack L_CR in the Z direction. The upper pillar MP_U penetrates the upper layer stack U_CR in the Z direction. The upper end of the lower pillar MP_L and the lower end of the upper pillar MP_U are in contact with each other at the boundary surface between the insulating layers 42 and 43. For example, each of the lower and upper pillars MP_L and MP_U has a cross-sectional area along the XY plane (XY cross-sectional area) that increases from the lower side to the upper side.

In addition, each of the memory pillars MP includes, for example, a core film 30, a semiconductor film 31, and a stacked film 32. The core film 30 is provided to extend along the Z direction. For example, the upper end of the core film 30 is located in the insulating layer 46, and the lower end of the core film 30 is located in the interconnect layer 21. The core film 30 includes, for example, an insulator such as silicon oxide. The semiconductor film 31 covers the periphery of the core film 30, for example. At the lower end of a memory pillar MP, a portion of the semiconductor film 31 is in contact with the interconnect layer 21. The semiconductor film 31 includes, for example, silicon. The stacked film 32 covers the side surface and the bottom surface of the semiconductor film 31, except for its portion where the semiconductor film 31 and the interconnect layer 21 are in contact with each other.

In the structure of the memory pillar MP illustrated in FIG. 7, the portion where the memory pillar MP intersects the interconnect layer 22 functions as the select transistor ST2. The portions where the memory pillar MP intersects with the interconnect layers 23 and 24 function as the memory cell transistors MT0 to MT10, respectively. The portion where the memory pillar MP intersects the interconnect layer 25 functions as the select transistor ST1.

The cylindrical contact CV is provided on the upper surface of the semiconductor film 31 in the memory pillar MP. In the region illustrated in FIG. 7, two contacts CV are shown for the corresponding two memory pillars MP among the six memory pillars MP. The memory pillars MP that do not overlap the members SHE and to which no contacts CV are connected in this region are connected with other contacts CV in a region not illustrated.

One interconnect layer 26, that is, one bit line BL is in contact with the upper surface of each contact CV. One contact CV is connected to one interconnect layer 26 in each of the spaces divided by the members SLT and SHE. That is, for example, each interconnect layer 26 is electrically connected with one memory pillar MP in the region between adjacent members SLT and SHE, and one memory pillar MP in the region between two adjacent members SHE.

The member SLT is formed to spread along the XZ plane, for example. The member SLT penetrates the interconnect layers 22 to 25 and the insulating layers 41 to 45. The member SLT is arranged in the core region CR and extends in the X direction to separate the lower and upper layer stacks L_CR and U_CR in the Y direction.

In the member SLT, the contact LI is provided so as to spread along the XZ plane, and the spacer SP is provided between the contact LI and each of the interconnect layers 22 to 25. The upper end of the contact LI is located, for example, in the insulating layer 46. The lower end of the contact LI is located, for example, in the interconnect layer 21. The spacer SP includes, for example, silicon oxide. The contact LI includes, for example, tungsten. Note that the contact LI may be omitted according to the structure of the memory cell array 10.

The members SHE are formed in, for example, a plate shape extending along the XZ plane and divide the interconnect layer 25. The upper end of the member SHE is located in the insulating layer 46. The lower end of the member SHE is located, for example, in the uppermost insulating layer 44. The member SHE includes, for example, an insulator such as silicon oxide. The upper end of the member SHE and the upper end of the member SLT may or may not be flush. In addition, the upper end of the member SHE and the upper end of the memory pillar MP may or may not be flush.

### 1.1.4.6 Cross-Sectional Structure of Memory Pillar

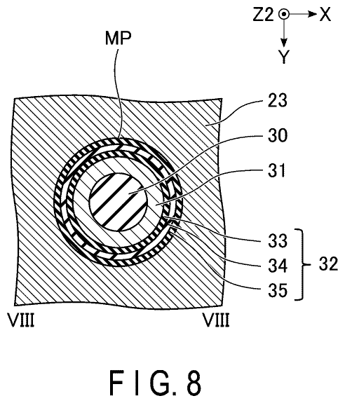

FIG. 8 is a cross-sectional view taken along line VIII-VIII in FIG. 7, illustrating an example of a cross-sectional structure of the memory pillar MP included in the semiconductor memory device 3 according to the first embodiment. More specifically, FIG. 8 illustrates a cross-sectional structure of the memory pillar MP in a layer including the interconnect layer 23. As illustrated in FIG. 8, the stacked film 32 includes, for example, a tunnel insulating film 33, an insulating film 34, and a block insulating film 35. The tunnel insulating film 33 surrounds the side surface of the semiconductor film 31. The insulating film 34 surrounds the side surface of the tunnel insulating film 33. The block insulating film 35 surrounds the side surface of the insulating film 34. The interconnect layer 23 surrounds the side surface of the block insulating film 35. Each of the tunnel insulating film 33 and the block insulating film 35 includes, for example, silicon oxide. The insulating film 34 is used as a charge storage layer of the memory cell transistor MT. The insulating film 34 includes, for example, silicon nitride (SiN).

### 1.1.4.7 Planar Layout of Contact Area

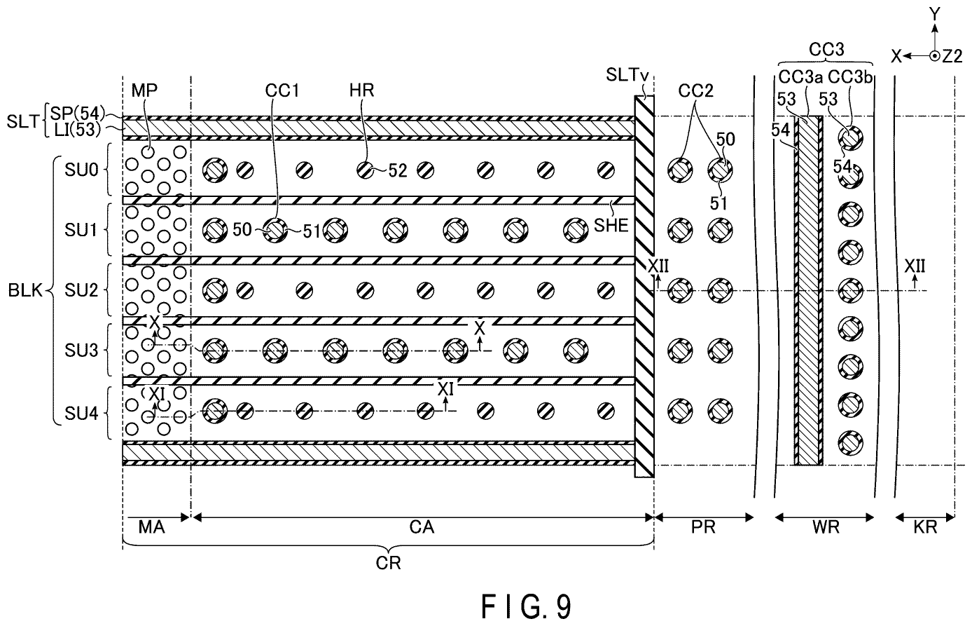

FIG. 9 is a plan view illustrating an example of a planar layout of the core region CR, the peripheral region PR, the wall region WR, and the kerf region KR of the semiconductor memory device 3 according to the first embodiment. FIG. 9 illustrates a layout in a case where a layer including the insulating layer 46 is viewed from the Z2 direction.

A planar layout of the contact area CA in the memory cell array 10 will be described. As illustrated in FIG. 9, the memory cell array 10 includes, for example, a plurality of contacts CC1 and a plurality of support pillars HR in the contact area CA. Hereinafter, the support pillars HR are also referred to as “insulating pillars HR”.

The contacts CC1 are arranged in the contact area CA (core region CR) and electrically connect the select gate line SGS, the word lines WL0 to WL10, and the select gate lines SGD to an interconnect provided above the memory cell array 10. The contacts CC1 each have, for example, a circular cross-sectional shape in the XY plane.

The contacts CC1 are arranged in the part of the contact area CA excluding the members SLT, SHE, and SLTV. In this example, five contacts CC1 are arranged in the Y direction in the vicinity of the memory area MA. These five contacts CC1 are arranged between a member SLT and a member SHE and between two members SHE, that is, in the regions corresponding to the string units SU0 to SU4, respectively. These five contacts CC1 are connected to, for example, the select gate lines SGD. In the region corresponding to the string unit SU1, six contacts CC1 are arranged in the X direction, separated in the X direction from the contact CC1 near the memory area MA. These six contacts CC1 are connected to, for example, the word lines WL10, WL8, WL6, WL4, WL2, and WL0, respectively in order from the memory area MA side. In the region corresponding to the string unit SU3, six contacts CC1 are arranged in the X direction, separated in the X direction from the contact CC1 near the memory area MA. These six contacts CC1 are connected to, for example, the word lines WL9, WL7, WL5, WL3, WL1, and the select gate line SGS, respectively.

The contacts CC1 each include a conductor 50 and an insulator 51. The conductor 50 is connected to one of the select gate line SGS, the word lines WL0 to WL10, and the select gate lines SGD. The conductor 50 includes, for example, tungsten. The insulator 51 covers the side surface of the conductor 50. The insulator 51 includes, for example, silicon oxide.

The support pillars HR are insulators arranged in the contact area CA (core region CR) and penetrate the lower and upper layer stacks L_CR and U_CR in the Z direction. For example, the support pillar HR functions as a pillar that supports an interlayer insulating film when a void is formed in the region corresponding to the lower and upper stacked interconnects during the manufacturing process. Each support pillar HR has, for example, a circular cross-sectional shape in the XY plane. The support pillars HR are appropriately arranged in the part of the contact area CA excluding the members SLT, SHE, and SLTV, and the contacts CC1. In this example, in the region corresponding to the string unit SU0, seven support pillars HR are arranged in the X direction, separated in the X direction from the contact CC1 near the memory area MA. Similarly, seven support pillars HR are arranged in each of the regions corresponding to the string units SU2 and SU4. The support pillars HR each include an insulator 52. The insulator 52 includes, for example, silicon oxide.

Note that the planar layout in the contact area CA of the memory cell array 10 included in the semiconductor memory device 3 may be another layout. For example, the number and arrangement of the contacts CC1 and the support pillars HR can be appropriately changed.

### 1.1.4.8 Planar Layout of Peripheral Region

A planar layout of the peripheral region PR will be described. As illustrated in FIG. 9, the semiconductor memory device 3 includes, for example, a plurality of contacts CC2 in the peripheral region PR. The contacts CC2 are arranged in the peripheral region PR and electrically connect a circuit provided in the circuit chip 200 with a pad PD (not illustrated) for connection to an external device. As will be described later, the holes corresponding to the contacts CC2 are formed in the step of forming holes for the contacts CC1. Therefore, the contacts CC2 each have, for example, a circular cross-sectional shape in the XY plane. In this example, the contacts CC2 are arranged in five rows. The contacts CC2 each include the conductor 50 and the insulator 51. The insulator 51 covers the side surface of the conductor 50. That is, the contact CC2 has the same structure as that of the contact CC1.

Note that the planar layout in the peripheral region PR of the semiconductor memory device 3 may be another layout. For example, the contacts CC2 may be arranged in 10 staggered rows. Furthermore, the number and arrangement of the contacts CC2 can be appropriately changed.

### 1.1.4.9 Planar Layout of Wall Region

A planar layout of the wall region WR will be described. As illustrated in FIG. 9, the semiconductor memory device 3 includes, for example, contacts CC3 in the wall region WR. The contacts CC3 are arranged in the wall region WR and electrically connect a well region (not illustrated) provided in the circuit chip 200 and the sealing portion ES. The contacts CC3 include, for example, a contact CC3a and a plurality of contacts CC3b. The contact CC3a is provided so as to surround the peripheral region PR. That is, the contact CC3a has a substantially rectangular frame-shaped cross-section in the XY plane. Since FIG. 9 illustrates a portion of the contact CC3a, the cross-sectional shape of the contact CC3a in the XY plane is a line shape. The contacts CC3b each have, for example, a circular cross-sectional shape in the XY plane. The contacts CC3b are provided so as to surround the contact CC3a. That is, the contacts CC3b are arranged in a substantially rectangular frame-shape in the XY plane. The contacts CC3 each include, for example, the conductor 53 and the insulator 54. The insulator 54 covers the side surface of the conductor 53. That is, the contact CC3 has the same structure as that of the member SLT.

Note that the planar layout in the wall region WR of the semiconductor memory device 3 may be another layout. For example, the contacts CC3b may be one contact having a substantially rectangular frame-shaped cross-section in the XY plane like the contact CC3a. In addition, the contacts CC3 may further include a plurality of contacts similar to the contact CC3a or the contacts CC3b on the outer side of the contacts CC3b.

### 1.1.4.10 Cross-Sectional Structure of Contact Area

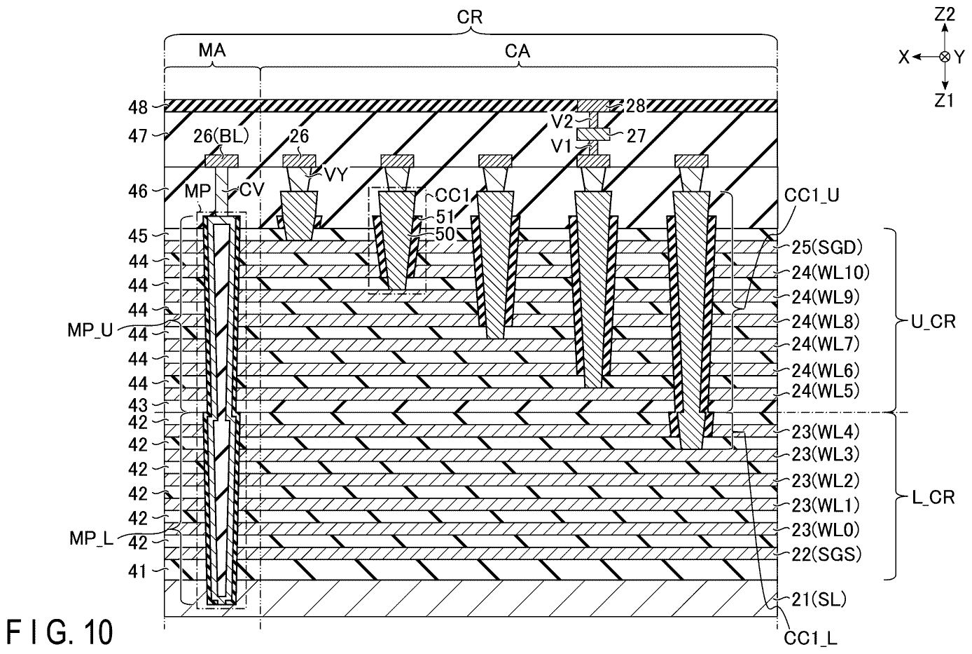

FIG. 10 is a cross-sectional view taken along line X-X of FIG. 9, illustrating an example of a cross-sectional structure in the contact area CA of the memory cell array 10 included in the semiconductor memory device 3 according to the first embodiment. FIG. 10 also illustrates a cross-sectional structure in the memory area MA near the contact area CA. The cross-sectional structure in the memory area MA is similar to that in FIG. 7. As illustrated in FIG. 10, the memory cell array 10 further includes the interconnect layers 21 to 28, the insulating layers 41 to 48, and a plurality of contacts VY, V1, and V2 in the contact area CA.

Each of the contacts CC1 is provided to extend along the Z direction and has, for example, a cylindrical shape. The contacts CC1 are provided on the select gate line SGS, the word lines WL0 to WL10, and the select gate line SGD, respectively.

First, the contacts CC1 respectively provided on the select gate line SGS and the word lines WL0 to WL4 will be described. Each of these contacts CC1 includes a lower contact CC1_L and an upper contact CC1_U.

The lower contact CC1_L extends in the Z direction and is connected to one of a plurality of interconnect layers (the interconnect layers 22 and 23). In other words, the lower contact CC1_L penetrates one or more interconnect layers 23 and one or more insulating layers 42 above the interconnect layer (the select gate line SGS and word lines WL0 to WL4) to which the contact CC1 is connected. The lower contact CC1_L includes the conductor 50 and the insulator 51 covering at least a portion of the side surface of the conductor 50. The upper contact CC1_U is provided on the lower contact CC1_L and penetrates the interconnect layers 24 and 25 and the insulating layers 43 to 45. In other words, the upper contact CC1_U penetrates the upper layer stack U_CR in the Z direction, and the upper end of the lower contact CC1_L and the lower end of the upper contact CC1_U are in contact with each other at the boundary surface between the insulating layers 42 and 43. The upper contact CC1_U includes the conductor 50 and the insulator 51 covering at least a portion of the side surface of the conductor 50.

The upper end of the conductor 50 is located in the insulating layer 46, and the lower end of the conductor 50 is in contact with the interconnect layer to which the conductor 50 is connected. The upper end of the insulator 51 is located lower than the upper end of the conductor 50 in the insulating layer 46, and the lower end of the insulator 51 is in contact with the insulating layer 42 on the interconnect layer to which the conductor 50 is connected. That is, the insulator 51 covers the side surface of the conductor 50 except for the upper and lower portions of the conductor 50.

Next, the contacts CC1 respectively provided on the word lines WL5 to WL10 and the select gate line SGD will be described. Each of these contacts CC1 includes the upper contact CC1_U.

The upper contact CC1_U extends in the Z direction and is connected to one of a plurality of interconnect layers (the interconnect layers 24 and 25). In other words, the upper contact CC1_U penetrates the interconnect layers 24 and 25 and the insulating layers 44 and 45 above the interconnect layer (the word lines WL5 to WL10 and the select gate line SGD) to which the contact CC1 is connected. The upper contact CC1_U includes the conductor 50 and the insulator 51 covering at least a portion of the side surface of the conductor 50.

The upper end of the conductor 50 is located in the insulating layer 46, and the lower end of the conductor 50 is in contact with the interconnect layer to which the conductor 50 is connected. The upper end of the insulator 51 is located lower than the upper end of the conductor 50 in the insulating layer 46, and the lower end of the insulator 51 is in contact with the insulating layer 44 on the interconnect layer to which the conductor 50 is connected. That is, the insulator 51 covers the side surface of the conductor 50 except for the upper and lower portions of the conductor 50.

For example, each of the lower and upper contacts CC1_L and CC1_U has a cross-sectional area (XY cross-sectional area) along the XY plane that increases from the lower side to the upper side.

One contact VY is provided on each of the contacts CC1 (the conductors 50). One interconnect layer 26 is provided on each of the contacts VY. The contact V1 is provided on each interconnect layer 26. Among the contacts V1, only the one corresponding to the word line WL5 is illustrated in FIG. 10. The interconnect layer 27 is provided on the contact V1. The contact V2 is provided on the interconnect layer 27. The interconnect layers 26 and 27 and the contacts V1 and V2 are covered with the insulating layer 47. On the contact V2, the interconnect layer 28 is provided penetrating the insulating layer 48.

The set of the interconnect layers 26, 27, and 28 and the contacts CC1, VY, V1, and V2 described above corresponds to interconnects and contacts for connecting one of the interconnect layers 22 to 25 and the row decoder module 15. Although not illustrated, each of the interconnect layers 22 to 25 other than the word line WL5 is similarly connected to the row decoder module 15 via a set of the interconnect layers 26, 27, and 28 and the contacts CC1, VY, V1, and V2.

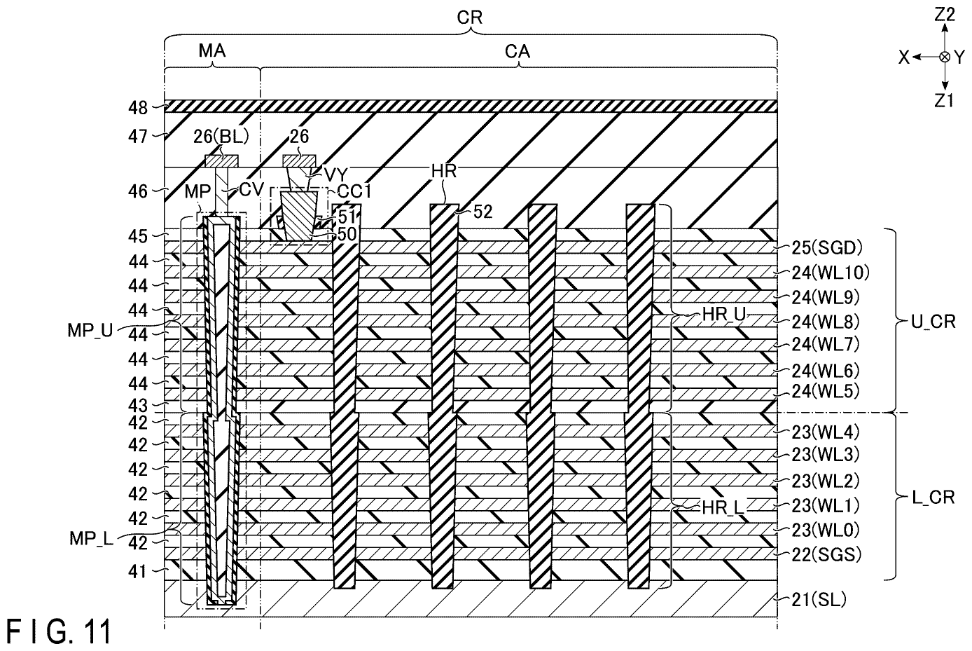

FIG. 11 is a cross-sectional view taken along line XI-XI of FIG. 9, illustrating an example of a cross-sectional structure in the contact area CA of the memory cell array 10 included in the semiconductor memory device 3 according to the first embodiment. FIG. 11 also illustrates a cross-sectional structure in the memory area MA near the contact area CA. The cross-sectional structure in the memory area MA is similar to that in FIG. 7. The cross-sectional structure of the contact CC1 is similar to that in FIG. 10.

Each of the support pillars HR is provided to extend along the Z direction, and has, for example, a cylindrical shape. Each of the support pillars HR includes a lower pillar HR_L and an upper pillar HR_U. The lower pillar HR_L penetrates the lower layer stack L_CR in the Z direction. The lower pillar HR_L includes the insulator 52. The upper pillar HR_U penetrates the upper layer stack U_CR in the Z direction. The upper pillar HR_U includes the insulator 52. The upper end of the lower pillar HR_L and the lower end of the upper pillar HR_U are in contact with each other at the boundary surface between the insulating layers 42 and 43. For example, each of the lower and upper pillars HR_L and HR_U has a cross-sectional area along the XY plane (XY cross-sectional area) that increases from the lower side to the upper side. At the junction portion between the lower and upper pillars HR_L and HR_U, the side surfaces of the lower and upper pillars HR_L and HR_U are shifted from each other. Note that the side surfaces of the lower and upper pillars HR_L and HR_U may not be shifted from each other. The upper end of the support pillar HR is located, for example, in the insulating layer 46. The lower end of the support pillar HR is located, for example, in the interconnect layer 21.

### 1.1.4.11 Cross-Sectional Structures of Peripheral Region, Wall Region, and Kerf Region

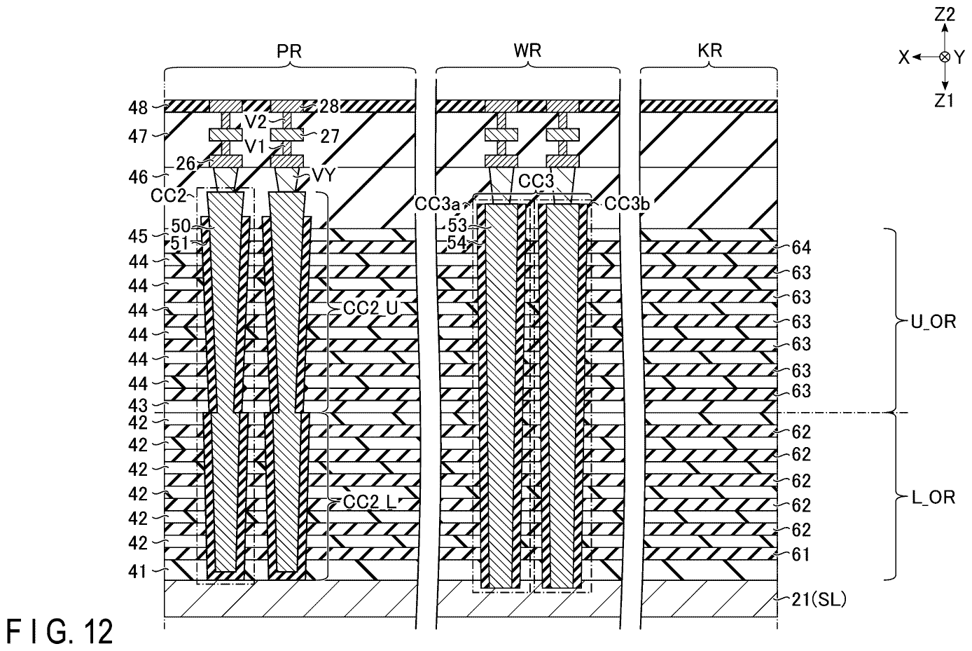

FIG. 12 is a cross-sectional view taken along line XII-XII of FIG. 9, illustrating an example of a cross-sectional structure in the peripheral region PR, the wall region WR, and the kerf region KR of the semiconductor memory device 3 according to the first embodiment.

As illustrated in FIG. 12, the semiconductor memory device 3 further includes interconnect layers 26 to 28, insulating layers 41 to 48, insulating layer 61 to 64, and a plurality of contacts VY, V1, and V2 in the peripheral region PR, the wall region WR, and the kerf region KR.

In the peripheral region PR, the wall region WR, and the kerf region KR, the insulating layers 41 and 61 are stacked in this order on the interconnect layer 21. The insulating layer 61 is provided in the same layer as the interconnect layer 22. The insulating layers 42 and 62 are alternately stacked on the insulating layer 61. Each of the insulating layers 62 is provided in the same layer as each of the interconnect layers 23. The insulating layer 43 is stacked on the uppermost insulating layer 42. The insulating layers 63 and 44 are alternately stacked on the insulating layer 43. Each of the insulating layers 63 is provided in the same layer as each of the interconnect layers 24. The insulating layer 64, the insulating layer 45, and the insulating layer 46 are stacked in this order on the uppermost insulating layer 44. The insulating layer 64 is provided in the same layer as the interconnect layer 25. The insulating layers 61 to 64 include, for example, silicon nitride.

Hereinafter, a structure in which a plurality of insulating layers (the insulating layers 41 and 42) and a plurality of insulating layers (the insulating layers 61 and 62) are alternately stacked in the Z direction is referred to as a “lower layer stack L_OR”. A structure in which a plurality of insulating layers (the insulating layers 43 to 45) and a plurality of insulating layers (the insulating layers 63 and 64) are alternately stacked in the Z direction is referred to as an “upper layer stack U_OR”. The peripheral region PR, the wall region WR, and the kerf region KR include the lower and upper layer stacks L_OR and U_OR.

In the peripheral region PR, each of the contacts CC2 is provided to extend along the Z direction and has, for example, a cylindrical shape. Each of the contacts CC2 includes a lower contact CC2_L and an upper contact CC2_U.

The lower contact CC2_L penetrates the lower layer stack L_OR in the Z direction. The lower contact CC2_L includes the conductor 50 and the insulator 51 covering at least a portion of the side surface of the conductor 50. The upper contact CC2_U is provided on the lower contact CC2_L and penetrates the insulating layers 63 and 64 and the insulating layers 43 to 45. In other words, the upper contact CC2_U penetrates the upper layer stack U_OR in the Z direction, and the upper end of the lower contact CC2_L and the lower end of the upper contact CC2_U are in contact with each other at the boundary surface between the insulating layers 42 and 43. The upper contact CC2_U includes the conductor 50 and the insulator 51 covering at least a portion of the side surface of the conductor 50. At the junction portion between the lower and upper contacts CC2_L and CC2_U, the side surfaces of the lower and upper contacts CC2_L and CC2_U are shifted from each other.

The upper end of the conductor 50 is located in the insulating layer 46, and the lower end of the conductor 50 is located in the insulating layer 41. The upper end of the insulator 51 is located lower than the upper end of the conductor 50 in the insulating layer 46, and the lower end of the insulator 51 is in contact with the interconnect layer 21. That is, the insulator 51 covers the side surface and the bottom surface of the conductor 50 except for the upper portion of the conductor 50.

For example, each of the lower and upper contacts CC2_L and CC2_U has a cross-sectional area (XY cross-sectional area) along the XY plane that increases from the lower side to the upper side.

One contact VY is provided on each of the contacts CC2 (the conductors 50). One interconnect layer 26 is provided on each of the contacts VY. The contact V1 is provided on each interconnect layer 26. The interconnect layer 27 is provided on the contact V1. The contact V2 is provided on the interconnect layer 27. The interconnect layers 26 and 27 and the contacts V1 and V2 are covered with the insulating layer 47. On the contact V2, the interconnect layer 28 is provided penetrating the insulating layer 48.

The set of the interconnect layers 26, 27, and 28 and the contacts CC2, VY, V1, and V2 described above corresponds to interconnects and contacts for connecting circuits provided in the circuit chip 200 and a pad PD for connection to an external device.

In the wall region WR, the contact CC3a is provided to extend along the Z direction, and has, for example, a tubular shape. Each of the contacts CC3b is provided to extend along the Z direction and has, for example, a cylindrical shape.

Each of the contact CC3a and the contacts CC3b penetrates the lower layer stack L_OR in the Z direction. Each of the contact CC3a and the contacts CC3b includes the conductor 53 and the insulator 54 covering at least a portion of the side surface of the conductor 53.

The upper end of the conductor 53 is located in the insulating layer 46, and the lower end of the conductor 53 is located in the interconnect layer 21. The upper end of the insulator 54 is at the same position as the upper end of the conductor 53, and the lower end of the insulator 54 is at the same position as the lower end of the conductor 53. That is, the insulator 54 covers the side surface of the conductor 53.

For example, each of the contact CC3a and the contacts CC3b has a cross-sectional area along the XY plane (XY cross-sectional area) that increases from the lower side to the upper side.

One contact VY is provided on the contact CC3a (the conductor 53). One contact VY is provided on each of the contacts CC3b (the conductors 53). One interconnect layer 26 is provided on each of the contacts VY. The contact V1 is provided on each interconnect layer 26. The interconnect layer 27 is provided on the contact V1. The contact V2 is provided on the interconnect layer 27. The interconnect layers 26 and 27 and the contacts V1 and V2 are covered with the insulating layer 47. On the contact V2, the interconnect layer 28 is provided penetrating the insulating layer 48.

The set of the interconnect layers 26, 27, and 28 and the contacts CC3, VY, V1, and V2 described above corresponds to interconnects and contacts for connecting the well region provided in the circuit chip 200 and the sealing portion ES.

### 1.1.4.12 Cross-Sectional Structure of Semiconductor Memory Device

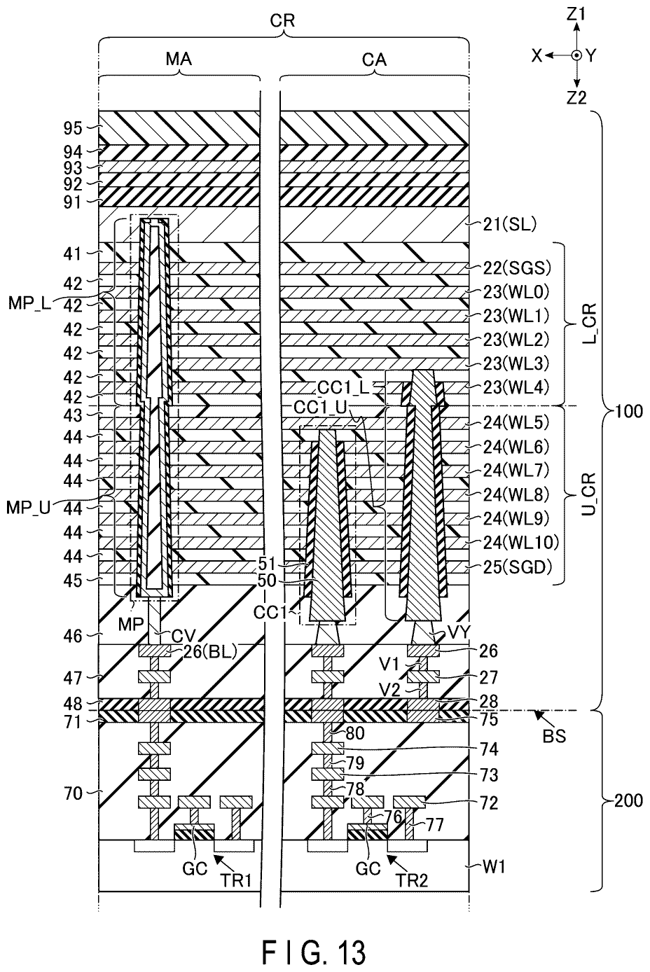

FIG. 13 is a cross-sectional view illustrating an example of a cross-sectional structure of the core region CR of the semiconductor memory device 3 according to the first embodiment. FIG. 13 illustrates a cross-sectional structure of the memory cell array 10 in the core region CR of the semiconductor memory device 3, and shows coordinate axes based on the semiconductor substrate W1. FIG. 13 illustrates a state in which the semiconductor substrate W2 has been removed and then the array chip 100 has been provided on the bonding surface BS of the circuit chip 200 in the Z direction. As illustrated in FIG. 13, the semiconductor memory device 3 includes, in the memory area MA and the contact area CA, insulating layers 70 and 71, transistors TR1 and TR2, conductive layers GC, interconnect layers 72 to 75, and contacts 76 to 80, corresponding to the circuit chip 200. In the memory area MA and the contact area CA, and corresponding to the array chip 100, the semiconductor memory device 3 includes a structure in which the structure of the memory cell array 10 illustrated in FIG. 10 is vertically inverted, and insulating layers 91 and 92, an interconnect layer 93, and insulating layers 94 and 95. In the following description, the Z1 direction is defined as upward, and the Z2 direction is defined as downward.

In the memory area MA and the contact area CA, the insulating layer 70 is provided on the semiconductor substrate W1. The insulating layer 70 covers a circuit (e.g., the conductive layer GC, the interconnect layers 72 to 75, and the contacts 76 to 80) provided on the semiconductor substrate W1. The insulating layer 70 includes, for example, silicon oxide. The insulating layer 70 can include a plurality of insulating films.

The insulating layer 71 is provided on the insulating layer 70. The insulating layer 71 is in contact with the insulating layer 48 included in the array chip 100. The boundary between the insulating layers 71 and 48 corresponds to the bonding surface BS. The insulating layer 71 includes, for example, silicon oxide.

Each of the transistors TR1 and TR2 includes the conductive layer GC and two impurity diffusion regions. The conductive layer GC corresponds to a gate. The conductive layer GC is provided on a gate insulating film provided on the semiconductor substrate W1. The two impurity diffusion regions correspond to a source and a drain, respectively. The transistor TR1 is included in the sense amplifier module 16, for example. The transistor TR2 is included in the row decoder module 15.

The contact 76 is provided on the conductive layer GC. The contact 77 is provided on each impurity diffusion region. The interconnect layer 72 is provided on each of the contacts 76 and 77. The interconnect layer 73 is provided on the interconnect layer 72 via the contact 78. The interconnect layer 74 is provided on the interconnect layer 73 via the contact 79. The interconnect layers 72 to 74 include, for example, copper. The interconnect layer 75 is provided on the interconnect layer 74 via the contact 80. The interconnect layer 75 is provided in the same layer as the insulating layer 71. The interconnect layer 75 corresponds to a bonding pad BP used for bonding. The interconnect layer 75 includes, for example, copper.

In the memory area MA, the upper pillar MP_U is in contact with the lower end of the lower pillar MP_L.

With the above structure, in the memory area MA, the bit line BL is connected to the transistor TR1 included in the sense amplifier module 16 via the contacts V1, V2, and 77 to 80 and the interconnect layers 27, 28, and 72 to 75. In the contact area CA, the word line WL5 is connected to the transistor TR2 included in the row decoder module 15 via the contacts CC1, VY, V1, V2, and 77 to 80 and the interconnect layers 26 to 28 and 72 to 75.

The insulating layers 91 and 92, the interconnect layer 93, and the insulating layers 94 and 95 are stacked in this order on the interconnect layer 21. The insulating layers 91, 92, and 94 include, for example, silicon oxide. The interconnect layer 93 includes, for example, aluminum. The insulating layer 95 includes, for example, polyimide.

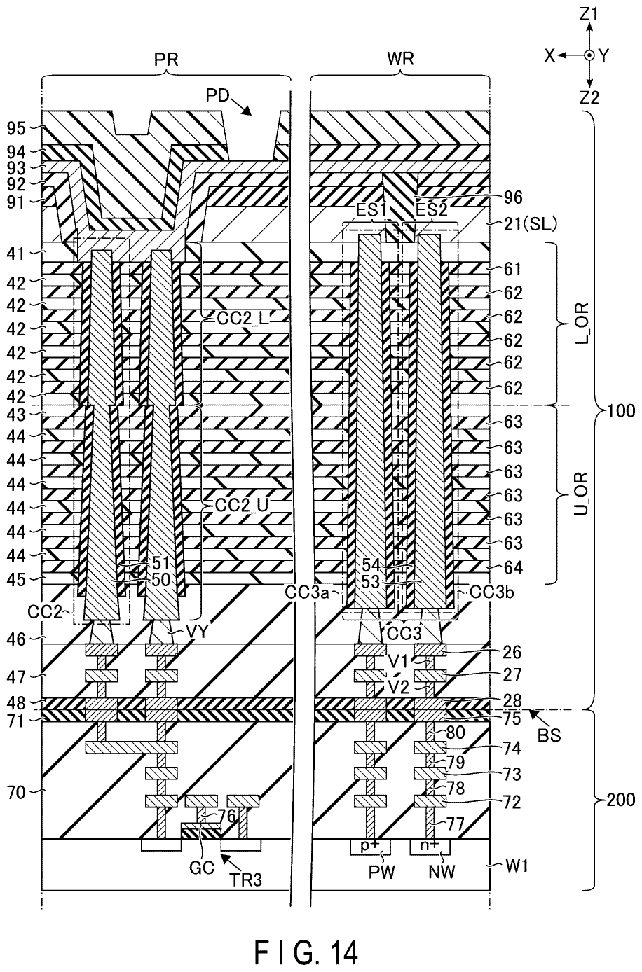

FIG. 14 is a cross-sectional view illustrating an example of a cross-sectional structure of the peripheral region PR and the wall region WR of the semiconductor memory device 3 according to the first embodiment. FIG. 14 illustrates the cross-sectional structure of the peripheral region PR and the wall region WR of the semiconductor memory device 3, and shows coordinate axes based on the semiconductor substrate W1. FIG. 14 illustrates a state in which the semiconductor substrate W2 has been removed and then the array chip 100 has been provided on the bonding surface BS of the circuit chip 200 in the Z direction. As illustrated in FIG. 14, the semiconductor memory device 3 includes, in the peripheral region PR and the wall region WR, the insulating layers 70 and 71, a transistor TR3, the conductive layer GC, the interconnect layers 72 to 75, and the contacts 76 to 80, corresponding to the circuit chip 200. In the peripheral region PR and the wall region WR, and corresponding to the array chip 100, the semiconductor memory device 3 includes a structure in which the structure of each of the peripheral region PR and the wall region WR illustrated in FIG. 12 is vertically inverted, and the insulating layers 91 and 92, the interconnect layer 93, and insulating layers 94 to 96.

The peripheral region PR includes the transistor TR3. The transistor TR3 includes the conductive layer GC and two impurity diffusion regions. The conductive layer GC corresponds to a gate. The conductive layer GC is provided on a gate insulating film provided on the semiconductor substrate W1. The two impurity diffusion regions correspond to a source and a drain, respectively.

The contact 76 is provided on the conductive layer GC. The contact 77 is provided on each impurity diffusion region. The interconnect layer 72 is provided on each of the contacts 76 and 77. The interconnect layer 73 is provided on the interconnect layer 72 via the contact 78. The interconnect layer 74 is provided on the interconnect layer 73 via the contact 79. A plurality of (two in the example of FIG. 14) interconnect layers 75 are provided on the interconnect layer 74 via the contact 80.

In the peripheral region PR, the upper contact CC2_U is in contact with the lower end of the lower contact CC2_L. The upper portion of the conductor 50 is not covered with the insulator 51. A portion of the interconnect layer 93 penetrates the insulating layer 41, the interconnect layer 21, and the insulating layers 91 and 92. The interconnect layer 93 may have a portion in contact with the contact CC2 (the conductor 50). The upper portion of the contact CC2 is covered with the interconnect layer 93 and connected to the interconnect layer 93. In other words, the contact CC2_L is connected to the interconnect layer 93 above the lower layer stack L_OR. The interconnect layers 93 and 21 are insulated by the insulating layer 92. A portion of the upper portion of the interconnect layer 93 is not covered with the insulating layers 94 and 95. This portion functions as the pad PD.

With this structure, in the peripheral region PR, the pad PD is connected to the transistor TR3 via the contacts CC2, VY, V1, V2, and 77 to 80 and the interconnect layers 26 to 28 and 72 to 75.

In the wall region WR, the semiconductor substrate W1 includes a P-type well region PW and an N-type well region NW. The P-type well region PW is a P-type impurity diffusion region provided in the vicinity of the upper surface of the semiconductor substrate W1 (p⁺). The N-type well region NW is a N-type impurity diffusion region provided in the vicinity of the upper surface of the semiconductor substrate W1 (n⁺). The P- and N-type well regions PW and NW are associated with sealing portions ES1 and ES2, respectively.

The contact 77 is provided on each of the P- and N-type well regions PW and NW. The interconnect layer 72 is provided on the contact 77. The interconnect layer 73 is provided on the interconnect layer 72 via the contact 78. The interconnect layer 74 is provided on the interconnect layer 73 via the contact 79. The interconnect layer 75 is provided on the interconnect layer 74 via the contact 80.

In the wall region WR, the upper portion of the conductor 53 is not covered with the insulator 54. The upper portion of each of the contacts CC3a and CC3b (conductor 53) is covered with the interconnect layer 21 and connected to the interconnect layer 21. That is, the contacts CC3a and CC3b are connected to the interconnect layer 21. The insulating layer 96 penetrates the interconnect layer 21 and the insulating layers 91 and 92. The insulating layer 96 insulates the contact CC3a from the contact CC3b.

With the above structure, in the wall region WR, the sealing portion ES1 is connected to the P-type well region PW via the contacts CC3a, VY, V1, V2, and 77 to 80, and the interconnect layers 26 to 28 and 72 to 75. The sealing portion ES2 is connected to the N-type well region NW via the contacts CC3b, VY, V1, V2, and 77 to 80, and the interconnect layers 26 to 28 and 72 to 75.

The sealing portions ES1 and ES2 described above are structures capable of releasing the positive and negative charges generated inside and outside the wall region WR to the semiconductor substrate W1. In addition, each of the sealing portions ES1 and ES2 can suppress moisture or the like from penetrating into the core region CR from the outside of the wall region WR.

### 1.2 Method of Manufacturing Semiconductor Memory Device

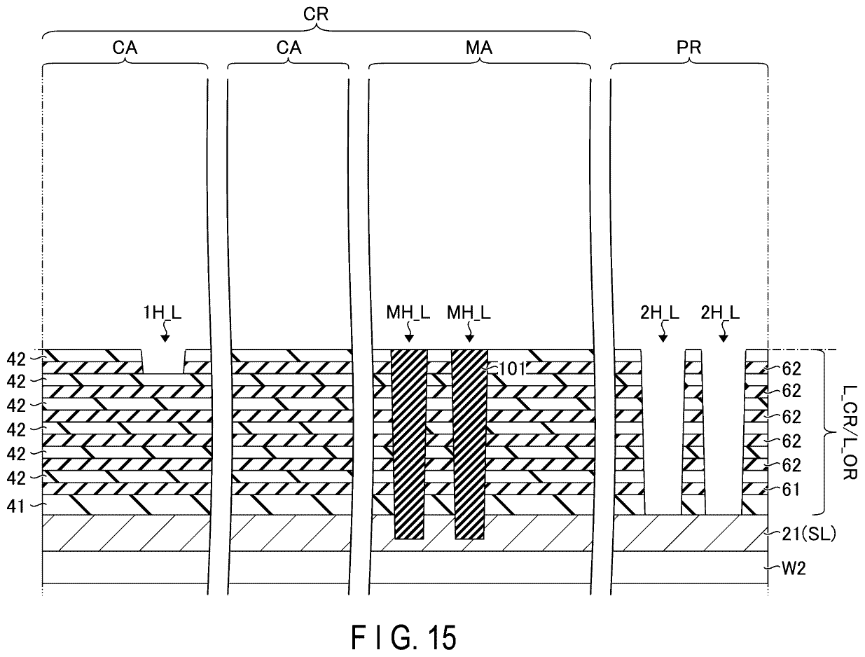

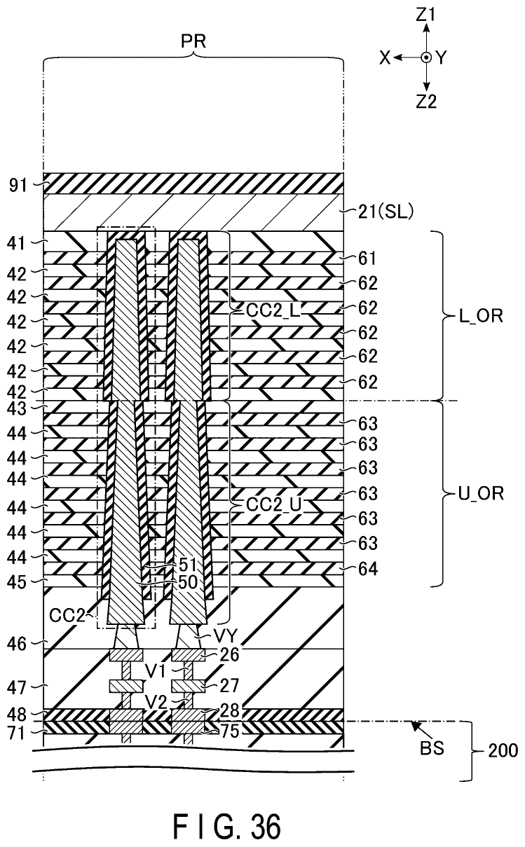

A method of manufacturing the semiconductor memory device 3 according to the first embodiment will be described with reference to FIGS. 15 to 41. FIGS. 15 to 41 are cross-sectional views each illustrating an example of a cross-sectional structure in the process of manufacturing the semiconductor memory device 3 according to the first embodiment. FIGS. 15 to 35 illustrate four cross-sectional structures side by side, which correspond to FIGS. 10, 11, 7, and 12, respectively, in order from the left side of the drawing. The cross-sectional structure corresponding to FIG. 10 includes the two contacts CC1 connected to the word lines WL3 and WL5 illustrated in FIG. 10. The cross-sectional structure corresponding to FIG. 11 includes two of the support pillars HR shown in FIG. 11. The cross-sectional structure corresponding to FIG. 7 includes two memory pillars MP and one member SLT illustrated in FIG. 7. The cross-sectional structure corresponding to FIG. 12 includes two contacts CC2 illustrated in FIG. 12. In FIGS. 15 to 35, a description will be given assuming that the Z2 direction is upward and the Z1 direction is downward. FIGS. 36 to 41 each show a cross-sectional structure of the peripheral region PR shown in FIG. 14. In FIGS. 36 to 41, a description will be given assuming that the Z1 direction is upward and the Z2 direction is downward.

In the present embodiment, as an example of the method of forming the interconnect layers 22 to 25 corresponding to the select gate line SGS, the word lines WL0 to WL10, and the select gate lines SGD, for example, a method will be described in which a structure corresponding to the interconnect layers 22, 23, 24, and 25 is formed with the insulating layers 61, 62, 63, and 64, respectively, and then the insulating layers 61, 62, 63, and 64 are replaced with a conductive material to form the interconnect layers 22, 23, 24, and 25 (hereinafter, this method is referred to as “replacement”). In addition, hereinafter, the insulating layers 61 to 64 are referred to as “sacrificial members 61 to 64”.

First, as illustrated in FIG. 15, the interconnect layer 21, the insulating layer 41, and the sacrificial member 61 are stacked in this order on the semiconductor substrate W2. Next, six insulating layers 42 and five sacrificial members 62 are alternately stacked on the sacrificial member 61. The interconnect layer 21 includes, for example, polysilicon. The insulating layers 41 and 42 include, for example, silicon oxide. The sacrificial members 61 and 62 include, for example, silicon nitride. Next, holes MH_L corresponding to the lower pillars MP_L are provided. For example, a mask having openings at the regions corresponding to the holes MH_L is formed by photolithography or the like, and the holes MH_L are formed by anisotropic etching using the mask. The lower ends of the holes MH_L reach the inside of the interconnect layer 21. After that, each of the holes MH_L is filled with a sacrificial member 101. Next, a hole 1H_L corresponding to the lower contact CC1_L and holes 2H_L corresponding to the lower contacts CC2_L are provided. For example, a mask having openings at the regions corresponding to the holes 1H_L and 2H_L is formed by photolithography or the like, and the holes 1H_L and 2H_L are formed by anisotropic etching using the mask. The lower end of the hole 1H_L corresponding to the word line WL3 reaches the upper surface of the insulating layer 42 immediately below the uppermost insulating layer 42. The lower ends of the holes 2H_L reach the interconnect layer 21.

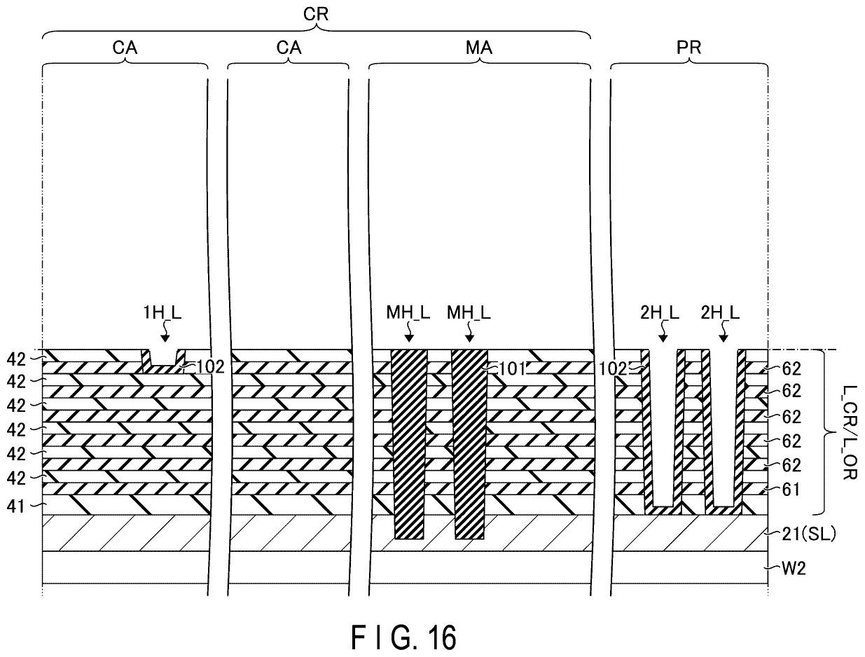

Next, as illustrated in FIG. 16, an insulator 102 is provided in each of the holes 1H_L and 2H_L. As a result, the side surface and the bottom surface of each of the holes 1H_L and 2H_L are covered with the insulator 102. The insulator 102 includes, for example, silicon oxide.

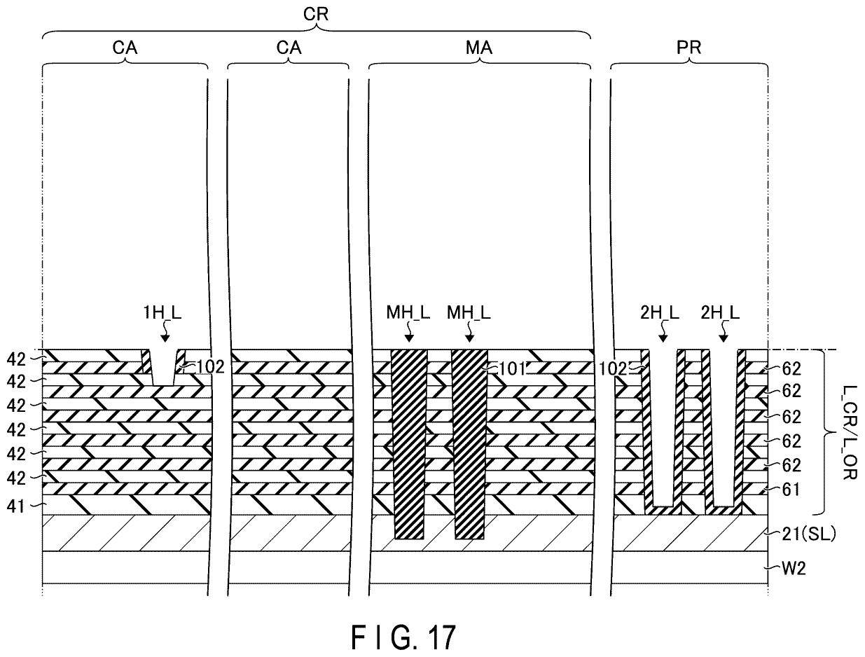

Next, as illustrated in FIG. 17, the insulator 102 on the bottom surface of the hole 1H_L is removed by, for example, anisotropic etching. At this time, the portion of the insulating layer 42 that is in contact with the bottom surface of the hole 1H_L corresponding to the word line WL3 and located under the removed insulator 102 is also removed. Hereinafter, this step is also referred to as a “bottom removing step”.

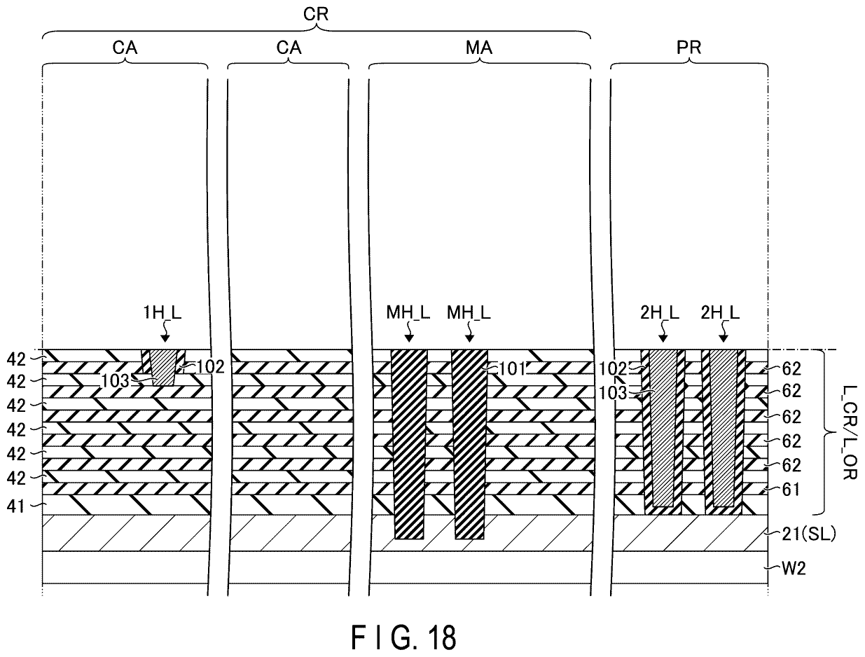

Next, as illustrated in FIG. 18, each of the holes 1H_L and 2H_L is embedded with a sacrificial member 103. The sacrificial member 103 includes, for example, polysilicon.

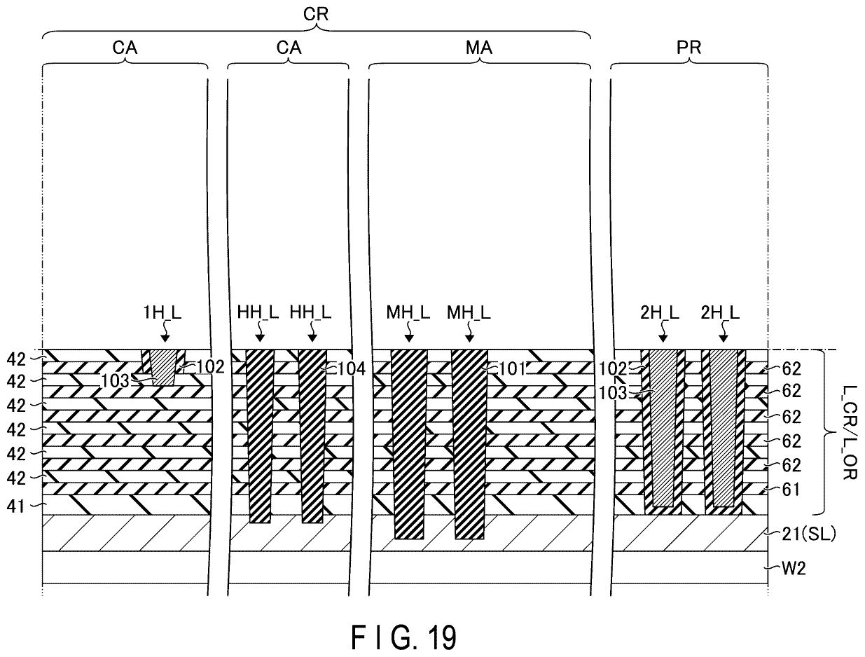

Next, as illustrated in FIG. 19, holes HH_L corresponding to the lower pillars HR_L are provided. For example, a mask having openings at the regions corresponding to the holes HH_L is formed by photolithography or the like, and the holes HH_L are formed by anisotropic etching using the mask. The lower ends of the holes HH_L reach the inside of the interconnect layer 21. After that, each of the holes HH_L are filled with a sacrificial member 104.

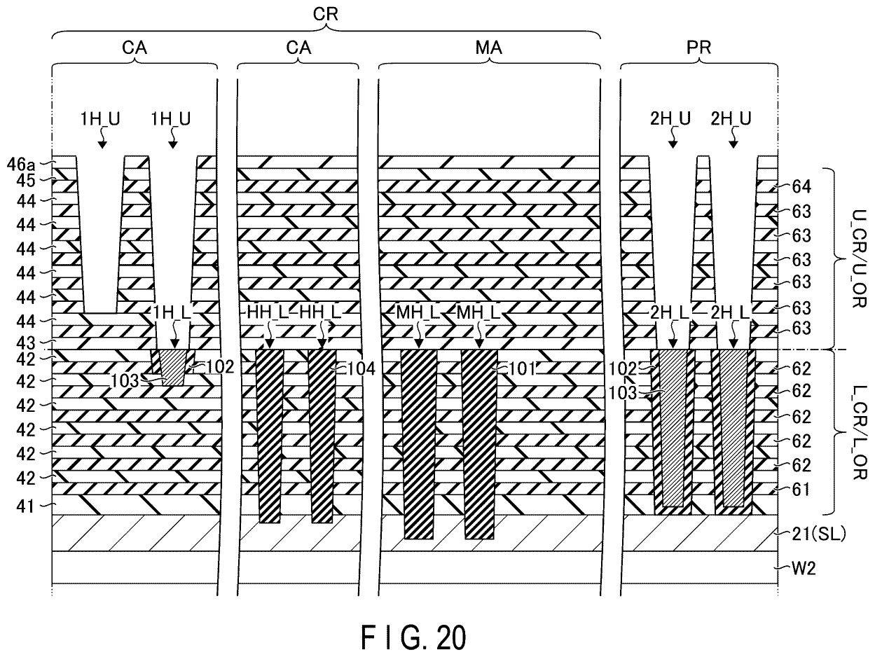

Then, as illustrated in FIG. 20, the insulating layer 43 is provided on the uppermost insulating layer 42. Six sacrificial members 63 and six insulating layers 44 are alternately stacked on the insulating layer 43. Further, the sacrificial member 64, the insulating layer 45, and an insulating layer 46a are stacked in this order on the uppermost insulating layer 44. The insulating layer 43 includes, for example, TEOS. The insulating layers 44, 45, and 46a include, for example, silicon oxide. The sacrificial members 63 and 64 include, for example, silicon nitride. Next, similarly to the holes 1H_L and 2H_L, the hole 1H_U corresponding to the upper contact CC1_U and the hole 2H_U corresponding to the upper contact CC2_U are provided. The lower end of the hole 1H_U corresponding to the word line WL3 reaches the upper surface of the sacrificial member 103. The lower end of the hole 1H_U corresponding to the word line WL5 reaches the upper surface of the lowermost insulating layer 44. The lower end of the hole 2H_U reaches the upper surface of the sacrificial member 103.

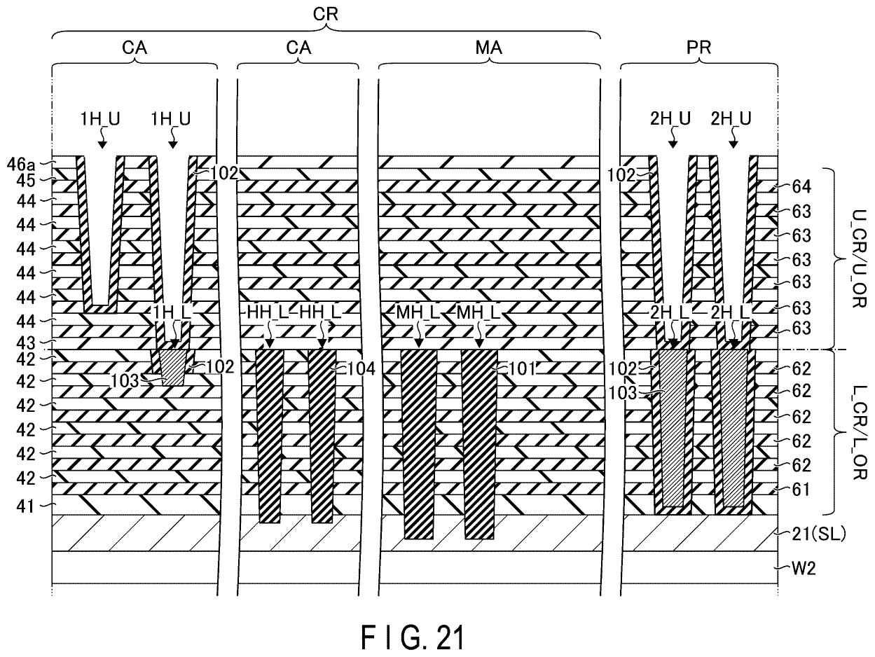

Next, as illustrated in FIG. 21, the insulator 102 is provided in each of the holes 1H_U and 2H_U. As a result, the side surface and the bottom surface of each of the holes 1H_U and 2H_U are covered with the insulator 102.

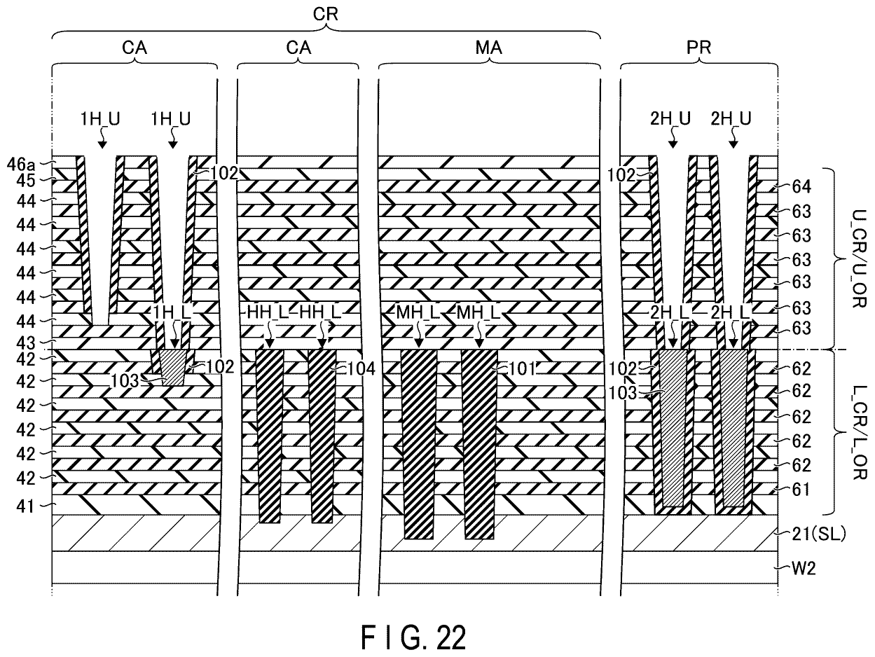

Next, as illustrated in FIG. 22, the insulator 102 on the bottom surface of each of the holes 1H_U and 2H_U is removed by, for example, anisotropic etching. At this time, the portion of the insulating layer 44 that is in contact with the bottom surface of the hole 1H_U corresponding to the word line WL5 and located under the removed insulator 102 is also removed (bottom removing step).

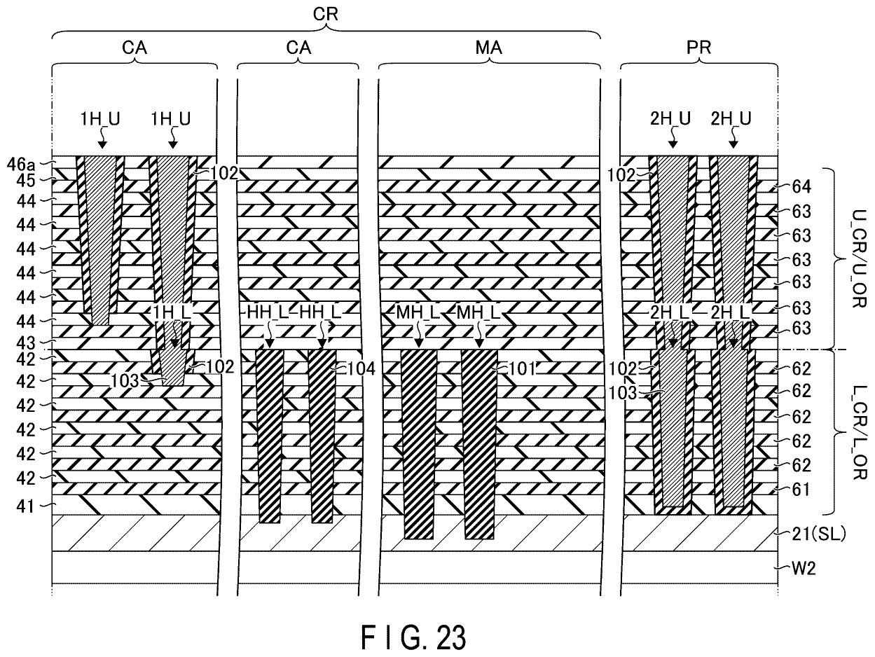

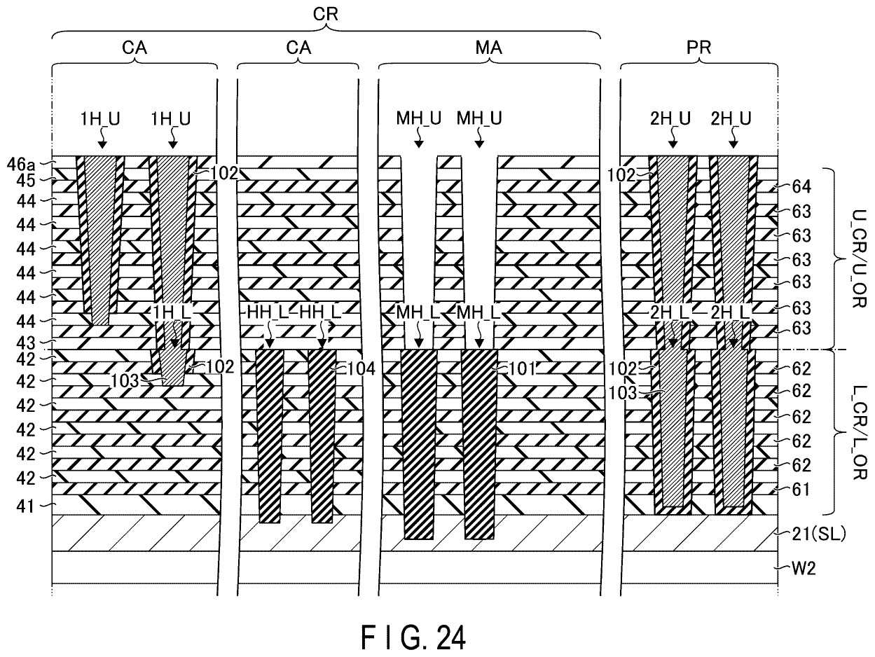

Next, as illustrated in FIG. 23, each of the holes 1H_U and 2H_U is embedded with a sacrificial member 103. Next, as illustrated in FIG. 24, holes MH_U corresponding to the upper pillars MP_U are provided similarly to the holes MH_L. The lower end of each hole MH_U reaches the upper surface of the sacrificial member 101.

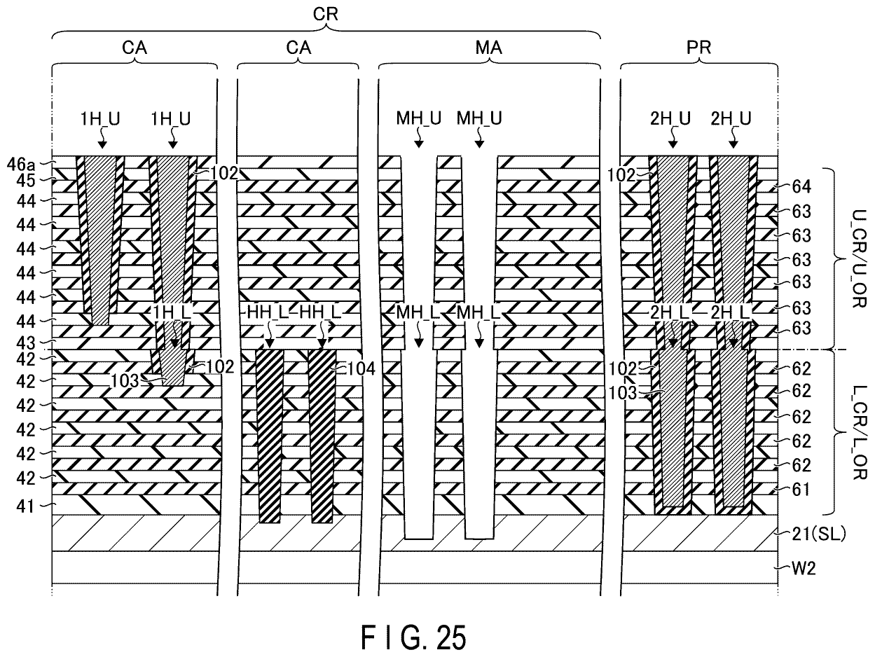

Next, as illustrated in FIG. 25, the sacrificial members 101 in the holes MH_L are removed by, for example, wet etching. This connects the holes MH_L and MH_U and exposes the interconnect layer 21.

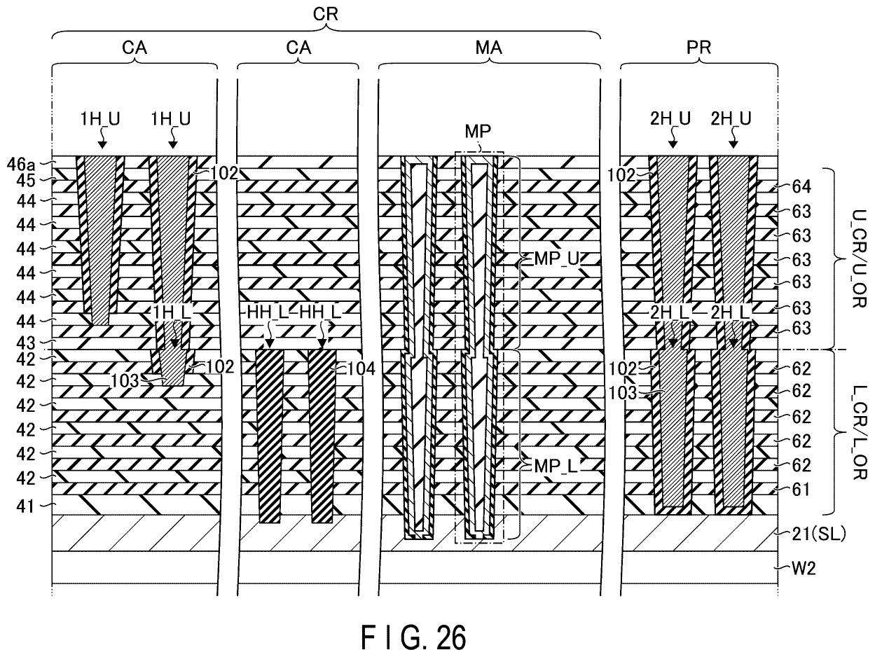

Next, as illustrated in FIG. 26, the memory pillars MP are formed in the holes MH_L and MH_U by forming various materials in the holes MH_L and MH_U.

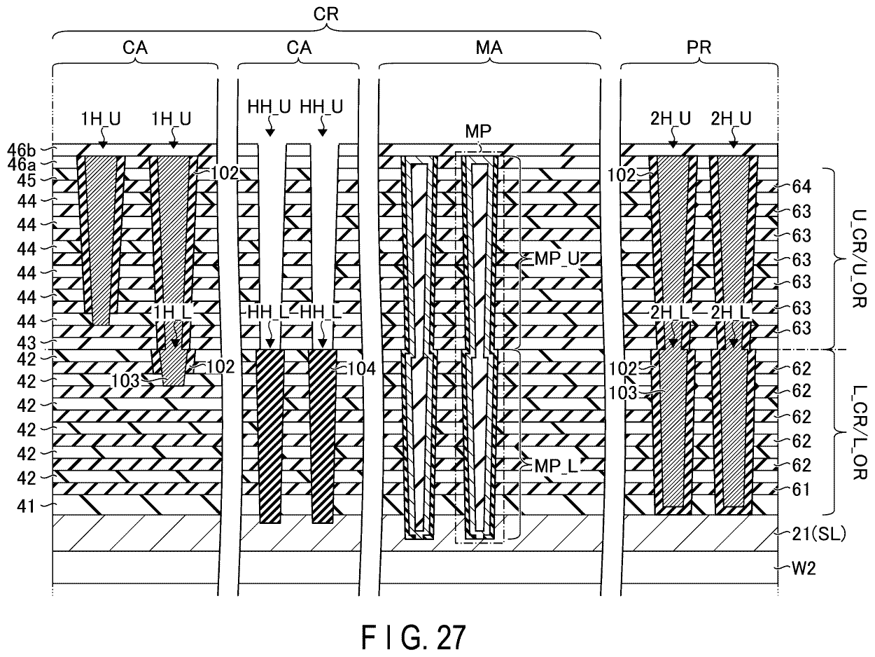

Next, as illustrated in FIG. 27, after an insulating layer 46b is provided on the insulating layer 46a, holes HH_U corresponding to the upper pillars HR_U are provided similarly to the holes HH_L. The lower end of each hole HH_U reaches the upper surface of the sacrificial member 104. The insulating layer 46b includes, for example, silicon oxide.

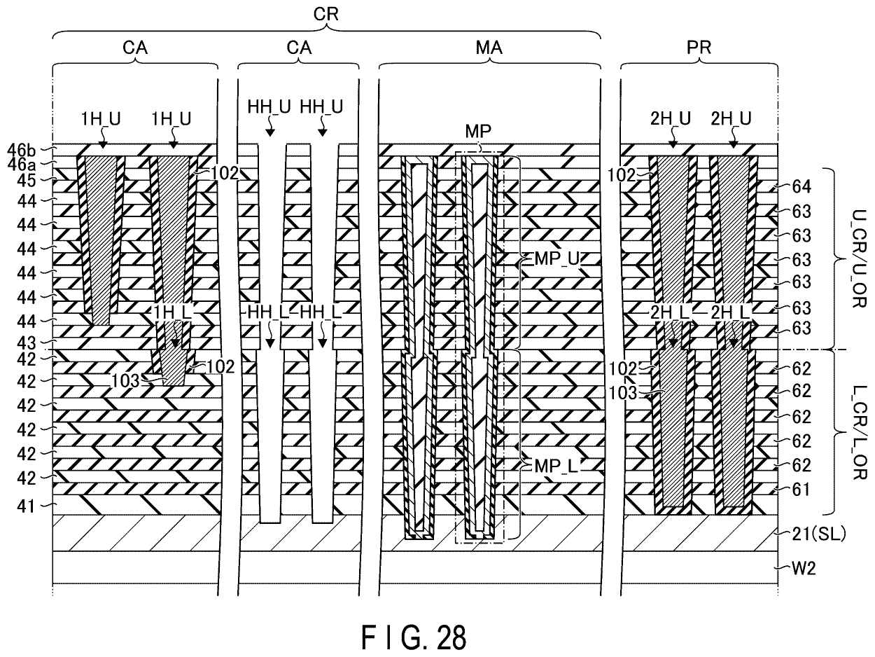

Next, as illustrated in FIG. 28, the sacrificial member 104 in each hole HH_L is removed by, for example, wet etching. As a result, the holes HH_L and HH_U are connected, and the interconnect layer 21 is exposed.

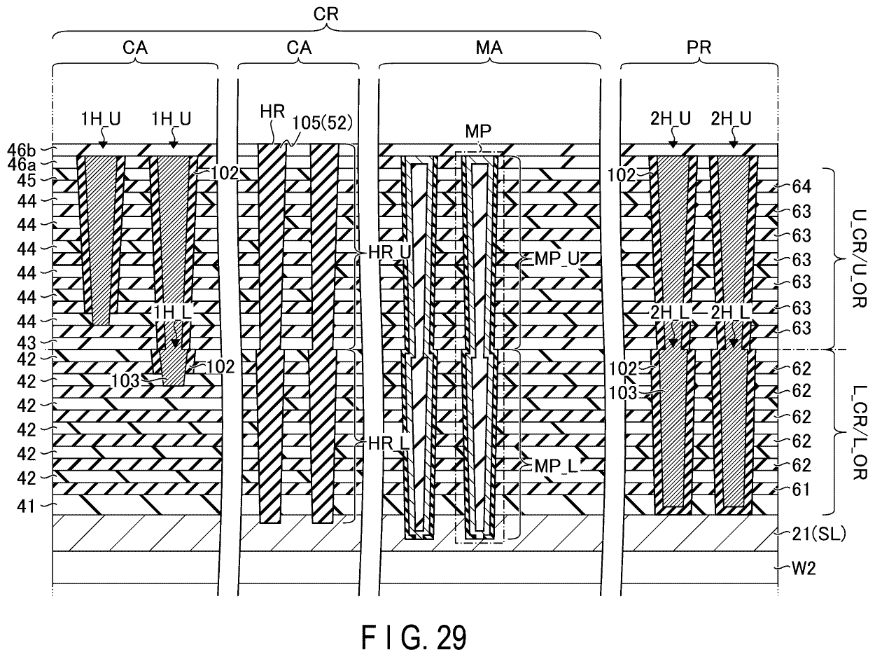

Next, as illustrated in FIG. 29, the holes HH_L and HH_U are filled with the insulator 105 to form the support pillars HR. The insulator 105 includes, for example, silicon oxide. The insulator 105 included in each support pillar HR corresponds to the insulator 52.

Next, although not illustrated, a hole SHv corresponding to the member SLTv is provided. For example, a mask having an opening at the region corresponding to the hole SHv is formed by photolithography or the like, and the hole SHv is formed by anisotropic etching using the mask. The lower end of the hole SHv reaches the inside of the interconnect layer 21. Thereafter, the hole SHv is filled with an insulator. The insulator includes, for example, silicon oxide.

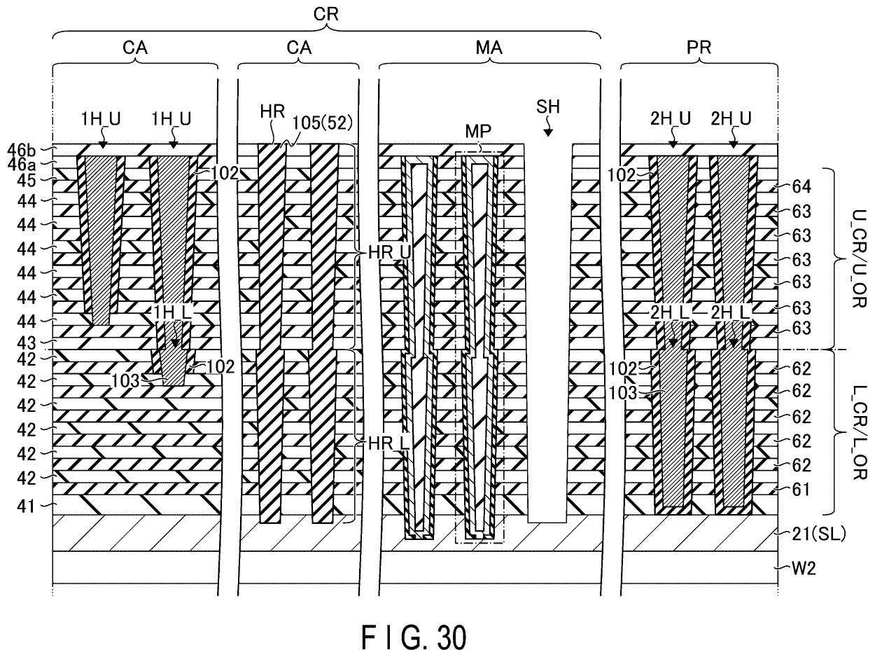

Next, as illustrated in FIG. 30, a hole SH corresponding to the member SLT is provided similarly to the hole SHv. The lower end of the hole SH reaches the inside of the interconnect layer 21.

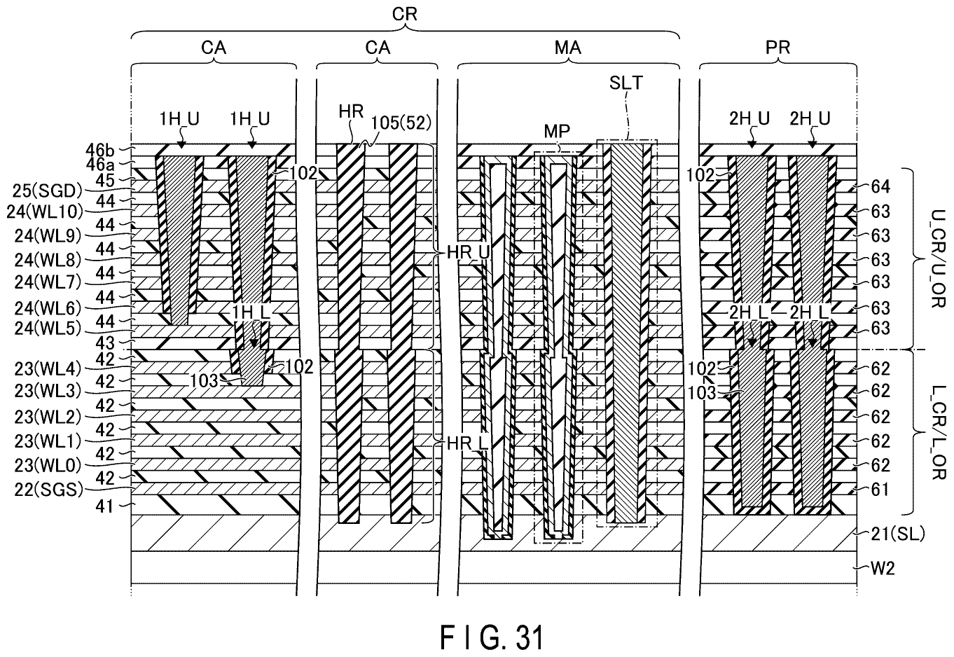

Next, as illustrated in FIG. 31, for example, after the sacrificial members 61 to 64 are removed by wet etching, the interconnect layers 22 to 25 are provided in the regions (voids) where the sacrificial members 61 to 64 have been removed (replacement). At this time, since the member SLTv (not illustrated) is provided, the sacrificial members 61 to 64 are not removed and remain in the peripheral region PR. Similarly, the sacrificial members 61 to 64 are not removed and remain in the wall region WR and the kerf region KR. Thereafter, the hole SH is filled with the spacer SP and the contact LI to form the member SLT.

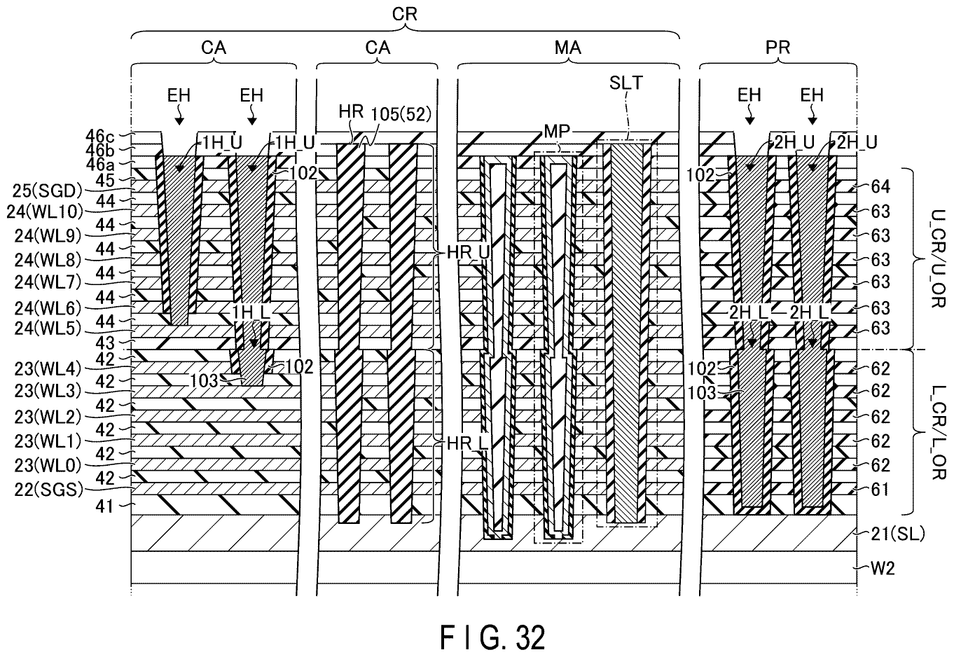

Next, as illustrated in FIG. 32, after an insulating layer 46c is provided on the insulating layer 46b, holes EH corresponding to the contacts CC1 and CC2 are provided. For example, a mask having openings at the regions corresponding to the holes EH is formed by photolithography or the like, and the holes EH are formed by anisotropic etching using the mask. The lower end of each of the holes EH corresponding to the contacts CC1 reaches the upper surface of the sacrificial member 103. The lower end of each of the holes EH corresponding to the contacts CC2 reaches the upper surface of the sacrificial member 103. The insulating layer 46c includes, for example, silicon oxide.

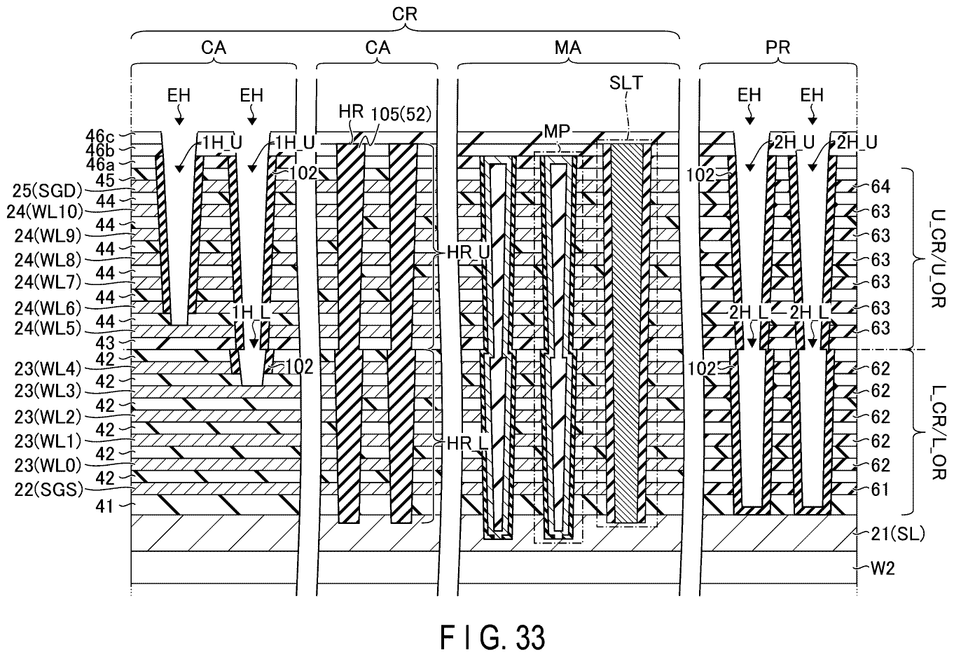

Next, as illustrated in FIG. 33, the sacrificial member 103 in each of the holes 1H_L, 1H_U, 2H_L, and 2H_U is removed by, for example, wet etching. As a result, the holes 1H_L and 1H_U corresponding to the word line WL3 are connected, and the interconnect layer 23 (word line WL3) is exposed. The interconnect layer 24 (word line WL5) is exposed in the hole 1H_U corresponding to the word line WL5. The holes 2H_L and 2H_U are connected, and the insulator 102 is exposed.

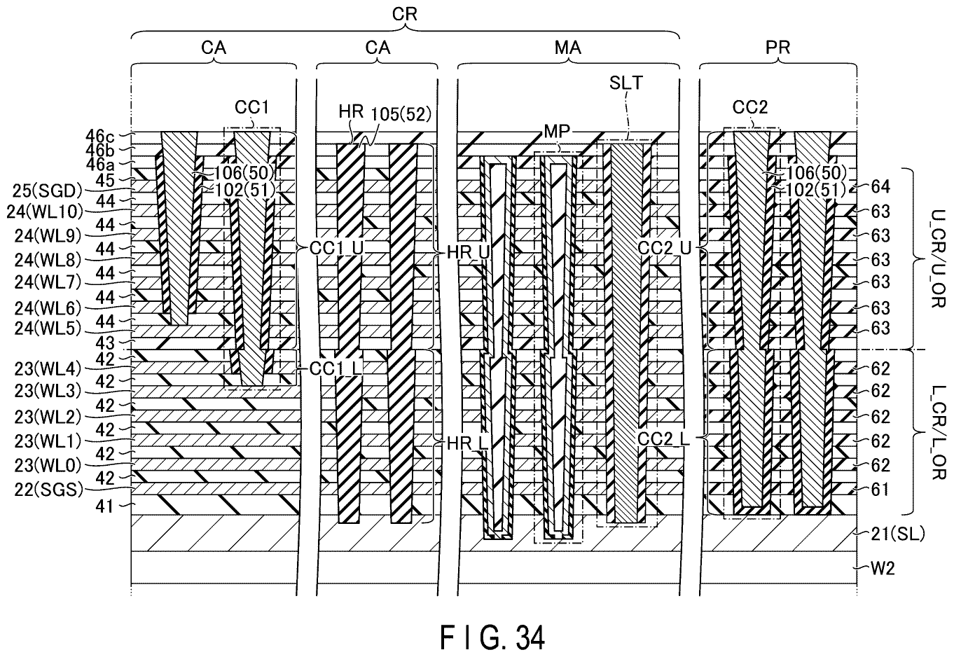

Next, as illustrated in FIG. 34, each of the holes 1H_L, 1H_U, 2H_L, and 2H_U is embedded with the conductor 106, whereby the contacts CC1 and CC2 are formed. The conductor 106 is, for example, tungsten. The insulator 102 and the conductor 106 included in each of the contacts CC1 and CC2 correspond to the insulator 51 and the conductor 50, respectively.

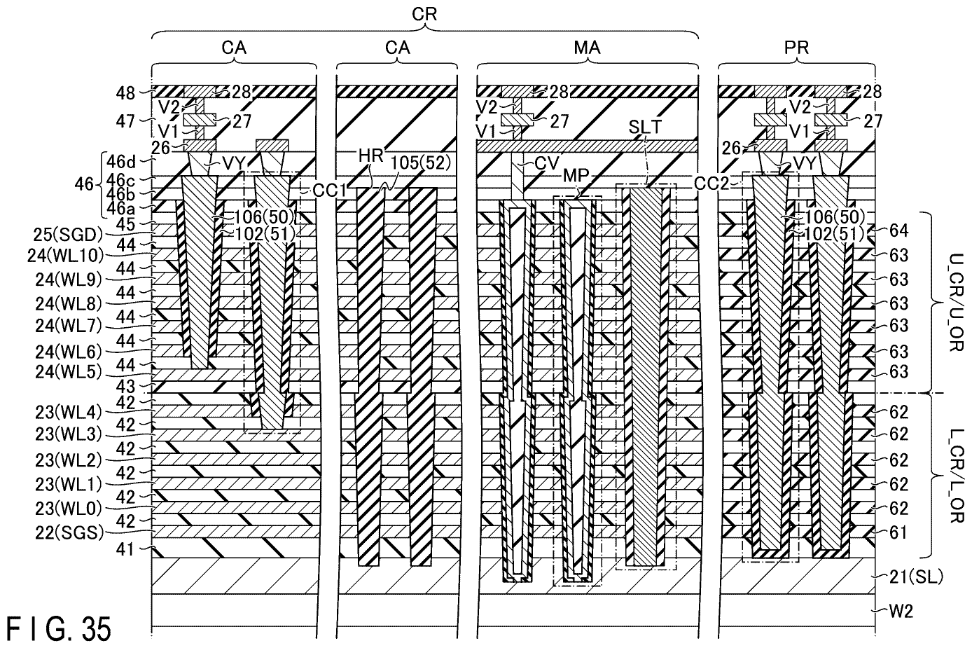

Next, as illustrated in FIG. 35, an insulating layer 46d is provided on the insulating layer 46c, and contacts VY are provided in the insulating layer 46d. The insulating layers 46a to 46d correspond to the insulating layer 46. Next, the insulating layer 47 is provided on the insulating layer 46, and the interconnect layer 26, the contact V1, the interconnect layer 27, and the contact V2 are provided in the insulating layer 47. Next, the insulating layer 48 is provided on the insulating layer 47, and an interconnect layer 28 is provided in the insulating layer 48.

Next, as illustrated in FIG. 36, the semiconductor substrate W2 is removed from the structure illustrated in FIG. 35, and a structure obtained by vertically inverting the structure is bonded onto the circuit chip 200. Next, the insulating layer 91 is provided on the interconnect layer 21. The insulating layer 91 includes, for example, silicon oxide.

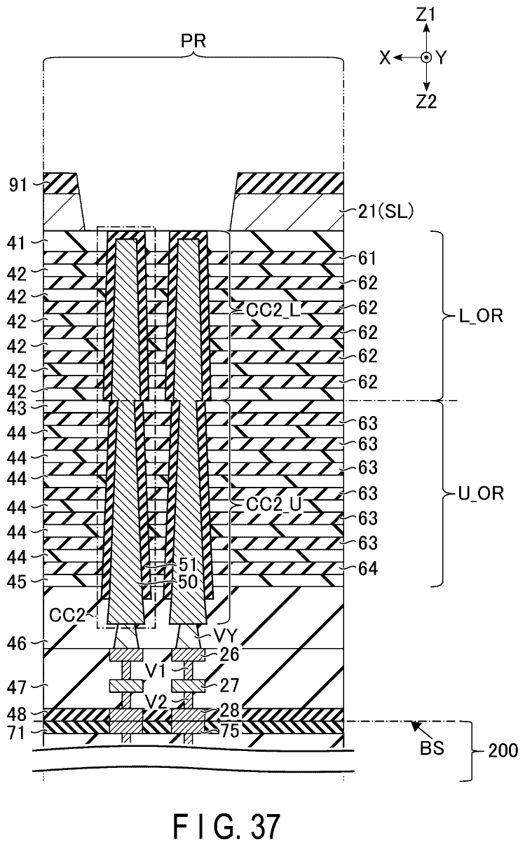

Next, as illustrated in FIG. 37, the portions of the interconnect layer 21 and the insulating layer 91 located on the contacts CC2 are removed. For example, a mask having an opening at the region where the interconnect layer 21 and the insulating layer 91 are to be removed is formed by photolithography or the like, and the interconnect layer 21 and the insulating layer 91 are removed by anisotropic etching using the mask. As a result, the upper surfaces of the contacts CC2 and the upper surface of the insulating layer 41 in the vicinity of the contacts CC2 are exposed.

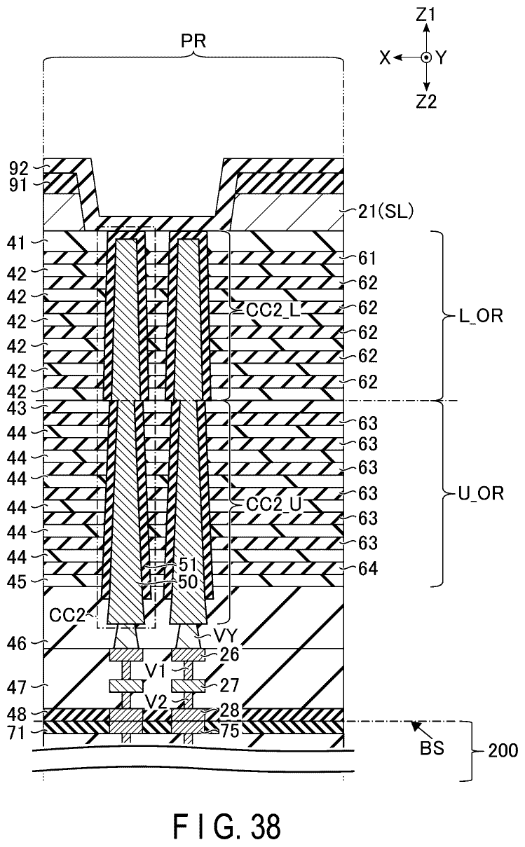

Next, as illustrated in FIG. 38, the insulating layer 92 is provided on the portion where the contacts CC2 and the insulating layer 41 are exposed, on the insulating layer 91, and on the side surfaces of the interconnect layer 21 and the insulating layer 91. The insulating layer 92 includes, for example, silicon oxide.

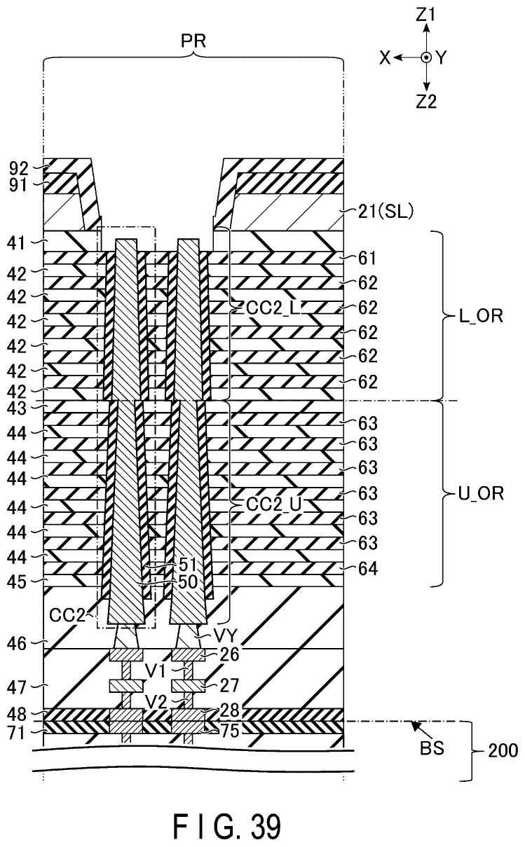

Next, as illustrated in FIG. 39, the portion of the insulating layer 92 located on the contacts CC2, the portion of the insulating layer 41 in the vicinity of the contacts CC2, and the insulating layer 92 located thereon are removed. For example, a mask having an opening at the region where the insulating layers 41 and 92 are to be removed is formed by photolithography or the like, and the insulating layers 41 and 92 are removed by anisotropic etching using the mask. At this time, the insulator 51 of an upper portion of each contact CC2 is also removed. As a result, the conductor 50 of the upper portion of each contact CC2 is exposed.

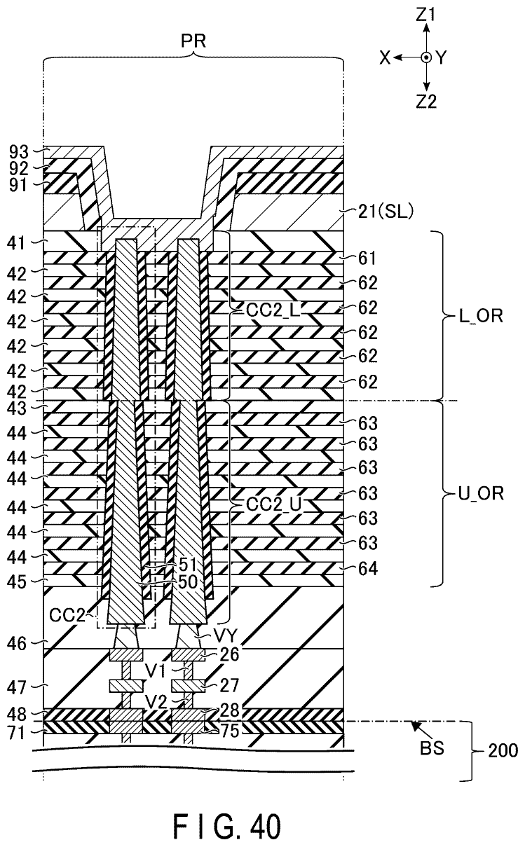

Next, as illustrated in FIG. 40, an interconnect layer 93 is provided on the exposed portion of the conductor 50, on the insulating layer 92, and on the side surface of each of the insulating layers 41 and 92. The interconnect layer 93 includes, for example, aluminum.

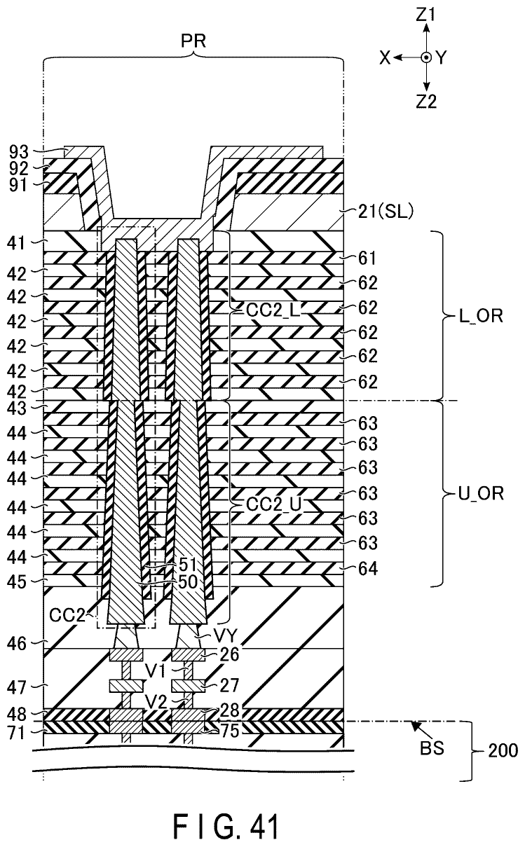

Next, as illustrated in FIG. 41, the interconnect layer 93 provided on the insulating layer 92 is processed so that a portion of the interconnect layer 93 is removed. Thereafter, the insulating layers 94 and 95 are stacked in this order, and the portion of the interconnect layer 93 corresponding to a pad PD is exposed, thereby forming the pad PD as illustrated in FIG. 14.

In the wall region WR, the contacts CC3a and CC3b are formed using the member SLT. For example, in the step of forming the hole SH corresponding to the member SLT, holes 3H (not illustrated) corresponding to the contacts CC3a and CC3b are also formed. In the step of forming the insulator 54 on the side surface of the hole SH, the insulator 54 is also provided on the side surfaces of the holes 3H. Next, in the step of embedding the conductor 53 in the hole SH, the conductor 53 is also embedded in the holes 3H. Thus, the contacts CC3a and CC3b are formed.

### 1.3 Effects According to Present Embodiment

In the array chip 100 having the structure in which each interconnect layer and the row decoder module are connected in the contact area CA by a contact (hereinafter, referred to as a “through contact”) including a conductor and an insulator covering the side surface of the conductor, the stacked structure of insulating layers remains in the peripheral region PR, the wall region WR, and the kerf region KR even after the replacement. The stacked structure of insulating layers is, for example, a stacked structure of silicon oxide and silicon nitride. Therefore, the contact provided in the peripheral region PR needs to be formed by processing the stacked structure of insulating layers. The through contact is formed by processing the stacked structure of insulating layer before the replacement.

In the semiconductor memory device 3 according to the present embodiment, the contact CC2 is formed using the contact CC1. More specifically, the step of forming the contact CC1 in the contact area CA and the step of forming the contact CC2 in the peripheral region PR are simultaneously performed. Therefore, the steps of processing insulating layers can be merged. As a result, the number of manufacturing steps can be reduced as compared with a case where the contacts CC1 and CC2 are formed in separate steps. Therefore, according to the semiconductor memory device 3 according to the present embodiment, the manufacturing cost can be reduced.

### 1.4 First Modification

A semiconductor memory device according to a first modification of the first embodiment will be described. In a semiconductor memory device 3 according to the present modification, the structure of the contact CC2 is different from that of the first embodiment. In the following, the differences from the first embodiment will be mainly described.

### 1.4.1 Cross-Sectional Structure of Peripheral Region

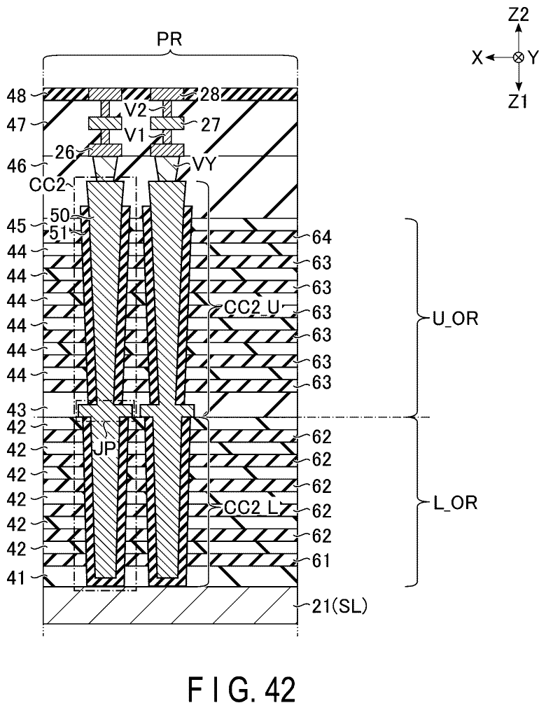

FIG. 42 is a cross-sectional view illustrating an example of a cross-sectional structure in the peripheral region PR of the semiconductor memory device 3 according to the first modification of the first embodiment. As illustrated in FIG. 42, the contact CC2 further includes a joint portion JP.

The joint potion JP includes the conductor 50. The upper end of the lower contact CC2_L and the lower end of the joint portion JP are in contact with each other at the boundary surface between the insulating layers 42 and 43. The lower end of the upper contact CC2_U is in contact with the upper end of the joint potion JP. The cross-sectional area of the joint portion JP is larger than the cross-sectional area of the upper end of the lower contact CC2_L and the cross-sectional area of the lower end of the upper contact CC2_U.

### 1.4.2 Method of Manufacturing Semiconductor Memory Device

A method of manufacturing the semiconductor memory device 3 according to the present modification will be described. For example, similarly to the first embodiment, after the steps of FIGS. 15 to 19 are performed, an insulating layer 43a (not illustrated) is formed on the uppermost insulating layer 42. Next, a hole corresponding to the joint portion JP, that is, a hole having a larger cross-sectional area than the upper end of the lower contact CC2_L and the lower end of the upper contact CC2_U is formed. Next, after the hole is filled with the sacrificial member 103, an insulating layer 43b (not illustrated) is formed. The insulating layers 43a and 43b correspond to the insulating layer 43. The subsequent steps are similar to those in FIGS. 20 to 41 shown in the first embodiment. As a result, the structure illustrated in FIG. 42 is formed.

### 1.4.3 Effects According to Present Modification

According to the present modification, effects similar to those of the first embodiment are obtained.

Further, in the semiconductor memory device 3 according to the present modification, the joint portion JP is provided between the lower and upper contacts CC2_L and CC2_U. The cross-sectional area of the joint portion JP is larger than the cross-sectional area of the upper end of the lower contact CC2_L and the cross-sectional area of the lower end of the upper contact CC2_U. Therefore, even when a positional misalignment between the lower contact CC2_L and the upper contact CC2_U occurs in the XY plane, it is possible to suppress connection failure between the lower and upper contacts CC2_L and CC2_U.

### 1.5 Second Modification

A semiconductor memory device according to a second modification of the first embodiment will be described. In a semiconductor memory device 3 according to the present modification, the structure of the contact CC2 is different from that of the first embodiment. In the following, the differences from the first embodiment will be mainly described.

### 1.5.1 Cross-Sectional Structure of Peripheral Region

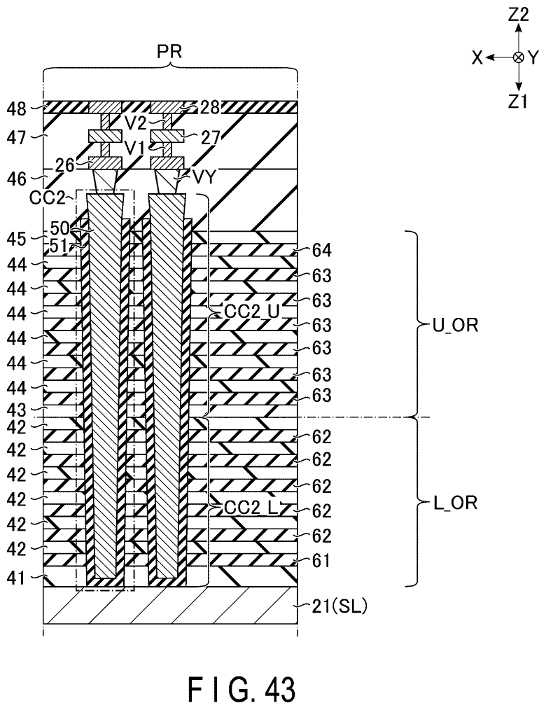

FIG. 43 is a cross-sectional view illustrating an example of a cross-sectional structure in a peripheral region PR of the semiconductor memory device 3 according to the second modification of the first embodiment. As illustrated in FIG. 43, at the junction portion between the lower and upper contacts CC2_L and CC2_U of the contact CC2, the side surfaces of the lower and upper contacts CC2_L and CC2_U are not shifted from each other.

### 1.5.2 Method of Manufacturing Semiconductor Memory Device

A method of manufacturing the semiconductor memory device 3 according to the present modification will be described. For example, the steps of FIGS. 15 to 19 are performed in the same manner as in the first embodiment except for the step of forming the hole 2H_L, the step of forming the insulator 102 in the hole 2H_L, and the step of embedding the sacrificial member 103 in the hole 2H_L. Next, similarly to the first embodiment, after the insulating layers 43 to 45 and 46a and the insulating layers 63 and 64 are stacked on the uppermost insulating layer 42, the hole 1H_U corresponding to the upper contact CC1_U and a hole 2H (not illustrated) corresponding to the contact CC2 and reaching the interconnect layer 21 are provided. Next, the insulator 102 is provided in each of the holes 1H_U and 2H. Next, the bottom removing step of the hole 1H_U is performed. Next, each of the holes 1H_U and 2H is embedded with the sacrificial member 103. The subsequent steps are similar to those in FIGS. 24 to 41 shown in the first embodiment. As a result, the structure illustrated in FIG. 43 is formed.

### 1.5.3 Effects According to Present Modification

According to the present modification, effects similar to those of the first embodiment are obtained.

In addition, in the semiconductor memory device 3 according to the present modification, the hole 2H_L corresponding to the lower contact CC2_L and the hole 2H_U corresponding to the upper contact CC2_U are collectively formed. Therefore, it is not necessary to consider the positional misalignment between the lower and upper contacts CC2_L and CC2_U in the XY plane.

### 1.6 Third Modification

A semiconductor memory device according to a third modification of the first embodiment will be described. In a semiconductor memory device 3 according to the present modification, the structure of the contact CC2 is different from that of the first embodiment. In the following, the differences from the first embodiment will be mainly described.

### 1.6.1 Cross-Sectional Structure of Peripheral Region

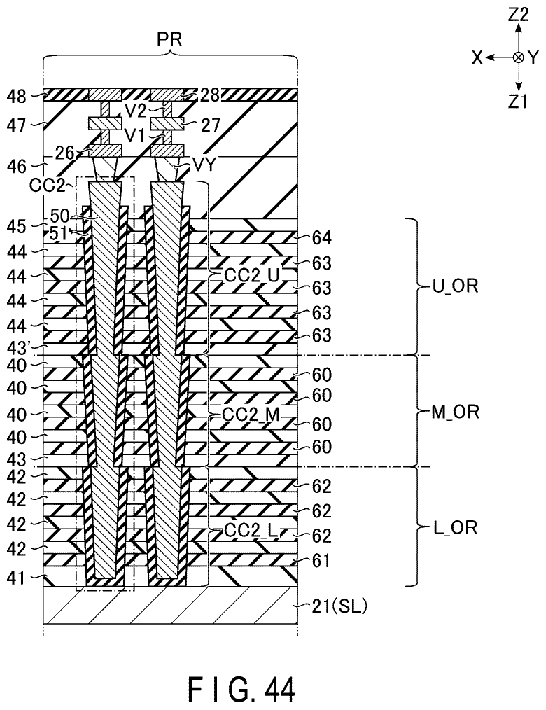

FIG. 44 is a cross-sectional view illustrating an example of a cross-sectional structure in the peripheral region PR of the semiconductor memory device 3 according to the third modification of the first embodiment. As illustrated in FIG. 44, the semiconductor memory device 3 further includes a plurality of insulating layers 40, an insulating layer 43′, and a plurality of insulating layers 60 in the peripheral region PR.

In the peripheral region PR, four insulating layers 42 and three insulating layers 62 are alternately stacked on the insulating layer 61. Each of the insulating layers 62 is provided in the same layer as the corresponding one of a plurality of interconnect layers 23 corresponding to the word lines WL0 to WL2. The insulating layer 43 is stacked on the uppermost insulating layer 42. Four insulating layers 60 and four insulating layers 40 are alternately stacked on the insulating layer 43. Each of the insulating layers 60 is provided in the same layer as the corresponding one of a plurality of interconnect layers 20 (not illustrated) corresponding to the word lines WL3 to WL6. The insulating layer 43′ is stacked on the uppermost insulating layer 40. Four insulating layers 63 and four insulating layers 44 are alternately stacked on the insulating layer 43′. Each of the insulating layers 63 is provided in the same layer as the corresponding one of a plurality of interconnect layers 24 corresponding to the word lines WL7 to WL10. The insulating layer 40 includes, for example, silicon oxide. The insulating layer 43′ includes, for example, TEOS. The insulating layers 60 include, for example, silicon nitride.

The contact CC2 further includes a middle contact CC2_M. Hereinafter, a structure in which a plurality of insulating layers (insulating layers 40) and a plurality of insulating layers (insulating layers 60) are alternately stacked in the Z direction is referred to as “middle layer stack M_OR”. The peripheral region PR includes the lower layer stack L_OR, the middle layer stack M_OR, and the upper layer stack U_OR.

The middle contact CC2_U penetrates the middle layer stack M_OR in the Z direction. The middle contact CC2_M includes the conductor 50 and the insulator 51 covering the side surface of the conductor 50. The middle contact CC2_M is provided between the lower and upper contacts CC2_L and CC2_U. In other words, the upper end of the lower contact CC2_L and the lower end of the middle contact CC2_M are in contact with each other at the boundary surface between the insulating layers 42 and 43, and the upper end of the middle contact CC2_M and the lower end of the upper contact CC2_U are in contact with each other at the boundary surface between the insulating layers 40 and 43′.

At the junction portion between the lower and middle contacts CC2_L and CC2_M, the side surfaces of the lower and middle contacts CC2_L and CC2_M are shifted from each other. At the junction portion between the middle and upper contacts CC2_M and CC2_U, the side surfaces of the middle and upper contacts CC2_M and CC2_U are shifted from each other.

For example, each of the lower, middle, and upper contacts CC2_L, CC2_M, and CC2_U has a cross-sectional area (XY cross-sectional area) along the XY plane that increases from the lower side to the upper side.

### 1.6.2 Method of Manufacturing Semiconductor Memory Device

A method of manufacturing the semiconductor memory device 3 according to the present modification will be described. For example, similarly to the first embodiment, the steps of FIGS. 15 to 19 are performed on the lower layer stack L_OR. Next, similarly to the first embodiment, the steps of FIGS. 15 to 19 are performed on the middle layer stack M_OR. Next, similarly to the first embodiment, the steps of FIGS. 20 to 41 are performed on the upper layer stack U_OR. As a result, the structure illustrated in FIG. 44 is formed.

### 1.6.3 Effects According to Present Modification

According to the present modification, effects similar to those of the first embodiment are obtained.

### 1.7 Fourth Modification

A semiconductor memory device according to a fourth modification of the first embodiment will be described. In a semiconductor memory device 3 according to the present modification, the structure of the contact CC2 is different from that of the third modification of the first embodiment. In the following, the differences from the third modification of the first embodiment will be mainly described.

### 1.7.1 Cross-Sectional Structure of Peripheral Region

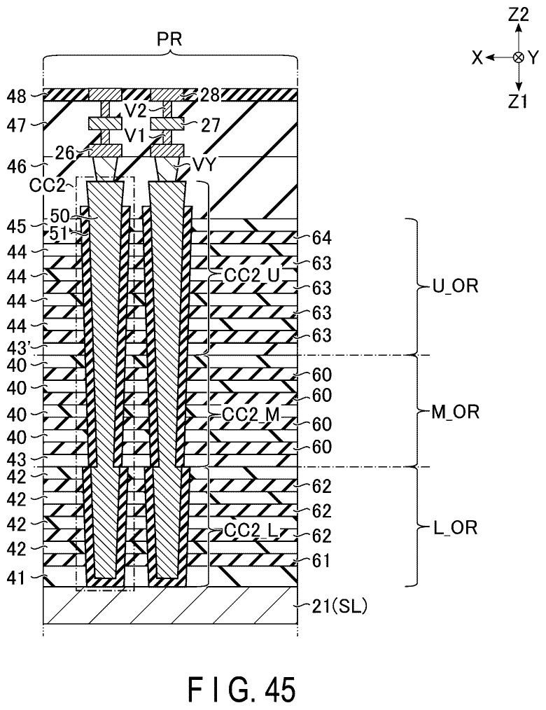

FIG. 45 is a cross-sectional view illustrating an example of a cross-sectional structure in the peripheral region PR of the semiconductor memory device 3 according to the fourth modification of the first embodiment. As illustrated in FIG. 45, at the junction portion between the lower and middle contacts CC2_L and CC2_M, the side surfaces of the lower and middle contacts CC2_L and CC2_M are shifted from each other. At the junction portion between the middle and upper contacts CC2_M and CC2_U, the side surfaces of the middle and upper contacts CC2_M and CC2_U are not shifted from each other.

### 1.7.2 Method of Manufacturing Semiconductor Memory Device

A method of manufacturing the semiconductor memory device 3 according to the present modification will be described. For example, similarly to the first embodiment, the steps of FIGS. 15 to 19 are performed on the lower layer stack L_OR. Next, similarly to the second modification of the first embodiment, the steps for the middle and upper layer stacks M_OR and U_OR are performed. As a result, the structure illustrated in FIG. 45 is formed.

### 1.7.3 Effects According to Present Modification

According to the present modification, effects similar to those of the first embodiment are obtained.

Further, in the semiconductor memory device 3 according to the present modification, after the hole 2H_L corresponding to the lower contact CC2_L is formed, the hole 2H_M corresponding to the middle contact CC2_M and the hole 2H_U corresponding to the upper contact CC2_U are collectively formed. Therefore, it is not necessary to consider the positional misalignment between the middle and upper contacts CC2_M and CC2_U in the XY plane.

### 1.8 Fifth Modification

A semiconductor memory device according to a fifth modification of the first embodiment will be described. In a semiconductor memory device 3 according to the present modification, the structure of the contact CC2 is different from that of the third modification of the first embodiment. In the following, the differences from the third modification of the first embodiment will be mainly described.

### 1.8.1 Cross-Sectional Structure of Peripheral Region

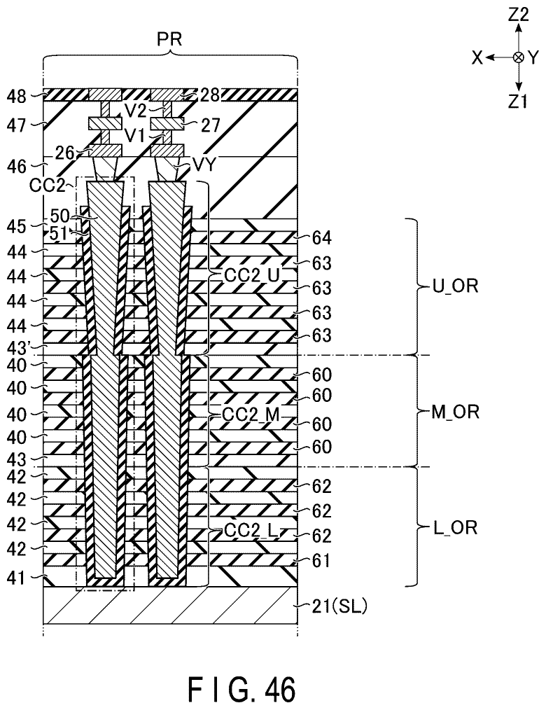

FIG. 46 is a cross-sectional view illustrating an example of a cross-sectional structure in the peripheral region PR of the semiconductor memory device 3 according to the fifth modification of the first embodiment. As illustrated in FIG. 46, at the junction portion between the lower and middle contacts CC2_L and CC2_M, the side surfaces of the lower and middle contacts CC2_L and CC2_M are not shifted from each other. At the junction portion between the middle and upper contacts CC2_M and CC2_U, the side surfaces of the middle and upper contacts CC2_M and CC2_U are shifted from each other.

### 1.8.2 Method of Manufacturing Semiconductor Memory Device

A method of manufacturing the semiconductor memory device 3 according to the present modification will be described. For example, similarly to the second modification of the first embodiment, the steps up to the step of embedding the sacrificial member 103 are performed on the lower and middle layer stacks L_OR and M_OR. Next, similarly to the first embodiment, the steps of FIGS. 24 to 41 are performed on the upper layer stack U_OR. As a result, the structure illustrated in FIG. 46 is formed.

### 1.8.3 Effects According to Present Modification

According to the present modification, effects similar to those of the first embodiment are obtained.

Further, in the semiconductor memory device 3 according to the present modification, the hole 2H_L corresponding to the lower contact CC2_L and the hole 2H_M corresponding to the middle contact CC2_M are collectively formed, and then the hole 2H_U corresponding to the upper contact CC2_U is formed. Therefore, it is not necessary to consider the positional misalignment between the lower and middle contacts CC2_L and CC2_M in the XY plane.

### 1.9 Sixth Modification

A semiconductor memory device according to a sixth modification of the first embodiment will be described. In a semiconductor memory device 3 according to the present modification, the structure of the contact CC2 is different from that of the third modification of the first embodiment. In the following, the differences from the third modification of the first embodiment will be mainly described.

### 1.9.1 Cross-Sectional Structure of Peripheral Region

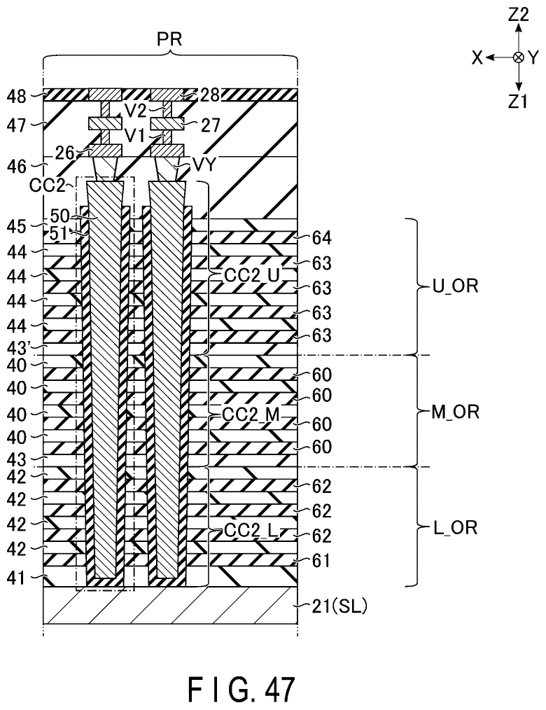

FIG. 47 is a cross-sectional view illustrating an example of a cross-sectional structure in the peripheral region PR of the semiconductor memory device 3 according to the sixth modification of the first embodiment. As illustrated in FIG. 47, at the junction portion between the lower and middle contacts CC2_L and CC2_M, the side surfaces of the lower and middle contacts CC2_L and CC2_M are not shifted from each other. At the junction portion between the middle and upper contacts CC2_M and CC2_U, the side surfaces of the middle and upper contacts CC2_M and CC2_U are not shifted from each other.

### 1.9.2 Method of Manufacturing Semiconductor Memory Device

A method of manufacturing the semiconductor memory device 3 according to the present modification will be described. For example, the steps of FIGS. 15 to 19 are performed on the lower and middle layer stacks L_OR and M_OR in the same manner as in the first embodiment, except for the step of forming the hole 2H_L and the hole 2H_M corresponding to the middle contact CC2_M, the step of forming the insulator 102 in the holes 2H_L and 2H_M, and the step of embedding the sacrificial member 103 in the holes 2H_L and 2H_M. Next, similarly to the first embodiment, after the insulating layers 43′, 44, 45, and 46a and the insulating layers 63 and 64 are stacked on the uppermost insulating layer 40, the hole 1H_U corresponding to the upper contact CC1_U and the hole 2H (not illustrated) corresponding to the contact CC2 and reaching the interconnect layer 21 are provided. Next, the insulator 102 is provided in each of the holes 1H_U and 2H. Next, the bottom removing step of the hole 1H_U is performed. Next, each of the holes 1H_U and 2H is embedded with the sacrificial member 103. The subsequent steps are similar to those in FIGS. 24 to 41 shown in the first embodiment. As a result, the structure illustrated in FIG. 47 is formed.

### 1.9.3 Effects According to Present Modification

According to the present modification, effects similar to those of the first embodiment are obtained.

Further, in the semiconductor memory device 3 according to the present modification, the hole 2H_L corresponding to the lower contact CC2_L, the hole 2H_M corresponding to the middle contact CC2_M, and the hole 2H_U corresponding to the upper contact CC2_U are collectively formed. Therefore, it is not necessary to consider the positional misalignment between the lower and middle contacts CC2_L and CC2_M in the XY plane and the positional misalignment between the middle and upper contacts CC2_M and CC2_U in the XY plane.

### 1.10 Seventh Modification

A semiconductor memory device according to a seventh modification of the first embodiment will be described. In a semiconductor memory device 3 according to the present modification, the structure of the array chip 100 is different from that of the first embodiment. In the following, the differences from the first embodiment will be mainly described.

### 1.10.1 Cross-Sectional Structure of Peripheral Region

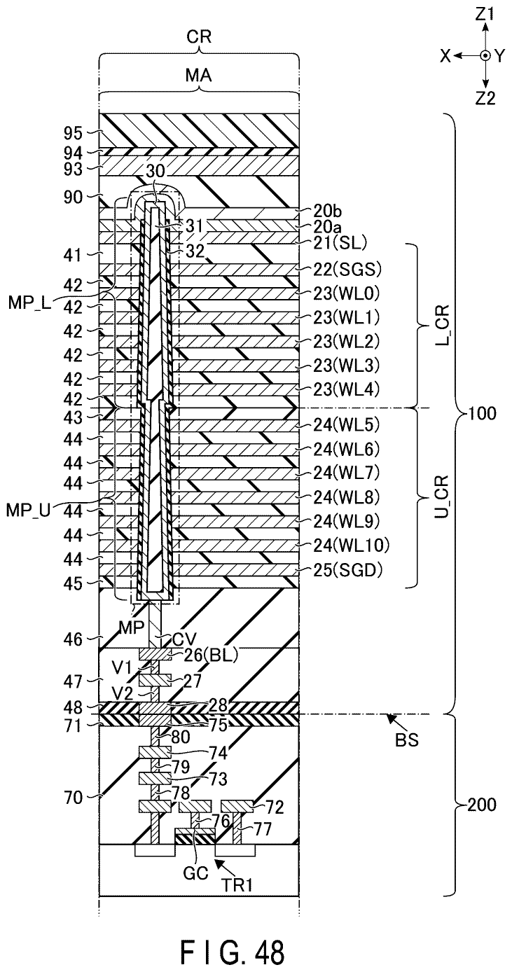

FIG. 48 is a cross-sectional view illustrating an example of a cross-sectional structure in the peripheral region PR of the semiconductor memory device 3 according to the seventh modification of the first embodiment. FIG. 48 illustrates a cross-sectional structure of the memory cell array 10 in the core region CR of the semiconductor memory device 3, and shows coordinate axes based on the semiconductor substrate W1. FIG. 48 illustrates a state in which the semiconductor substrate W2 has been removed and then the array chip 100 has been provided on the bonding surface BS of the circuit chip 200 in the Z direction. As illustrated in FIG. 48, the semiconductor memory device 3 includes, in the memory area MA, interconnect layers 20a and 20b, an insulating layer 90, the interconnect layer 93, and insulating layers 94 and 95, corresponding to the array chip 100. In the following description, the Z1 direction is defined as upward, and the Z2 direction is defined as downward.

The interconnect layers 20a and 20b, the insulating layer 90, the interconnect layer 93, and the insulating layers 94 and 95 are stacked in this order on the interconnect layer 21. The interconnect layer 20a includes, for example, polysilicon. The interconnect layer 20b includes, for example, at least one of tungsten, aluminum, titanium, and titanium nitride. The insulating layer 90 includes, for example, silicon oxide. The upper portion of the semiconductor film 31 is not covered with the stacked film 32. The interconnect layer 20a may have a portion in contact with the semiconductor film 31. The upper portion of the semiconductor film 31 is covered with the interconnect layer 20a and connected to the interconnect layer 20a.

In the memory area MA, the upper pillar MP_U is in contact with the lower end of the lower pillar MP_L.

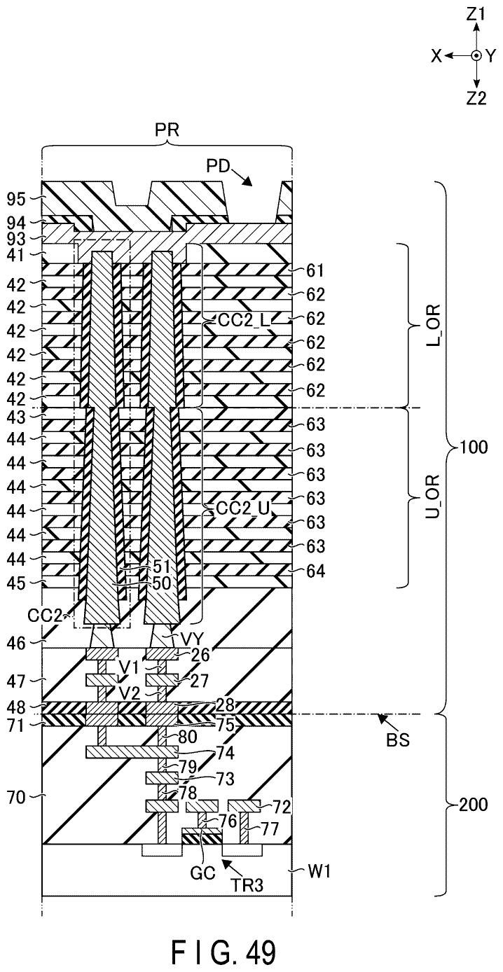

FIG. 49 is a cross-sectional view illustrating an example of a cross-sectional structure of the peripheral region PR of the semiconductor memory device 3 according to the seventh modification of the first embodiment. FIG. 49 illustrates the cross-sectional structure of the peripheral region PR of the semiconductor memory device 3, and shows coordinate axes based on the semiconductor substrate W1. FIG. 49 illustrates a state in which the semiconductor substrate W2 has been removed and then the array chip 100 has been provided on the bonding surface BS of the circuit chip 200 in the Z direction. As illustrated in FIG. 49, the semiconductor memory device 3 includes the interconnect layer 93 and the insulating layers 94 and 95 corresponding to the array chip 100 in the peripheral region PR.

In the peripheral region PR, the interconnect layer 21 is removed. The upper contact CC2_U is in contact with the lower end of the lower contact CC2_L. The upper portion of the conductor 50 is not covered with the insulator 51. A portion of the interconnect layer 93 penetrates the insulating layer 41. The interconnect layer 93 may have a portion in contact with the contact CC2 (the conductor 50). The upper portion of the contact CC2 is covered with the interconnect layer 93 and connected to the interconnect layer 93. In other words, the contact CC2_L is connected to the interconnect layer 93 above the lower layer stack L_OR. A portion of the upper portion of the interconnect layer 93 is not covered with the insulating layers 94 and 95. This portion functions as the pad PD.

### 1.10.2 Method of Manufacturing Semiconductor Memory Device

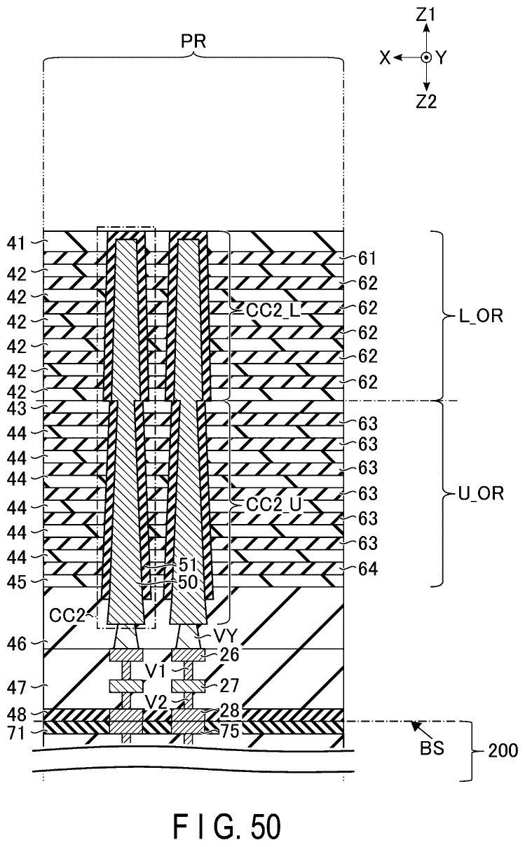

A method of manufacturing the semiconductor memory device 3 according to the present modification will be described with reference to FIGS. 50 to 53. FIGS. 50 to 53 are cross-sectional views each illustrating an example of a cross-sectional structure in the process of manufacturing the semiconductor memory device 3 according to the seventh modification of the first embodiment. FIGS. 50 to 53 each show a cross-sectional structure of the peripheral region PR shown in FIG. 49. In FIGS. 50 to 53, a description will be given assuming that the Z1 direction is upward and the Z2 direction is downward.

For example, the steps in FIGS. 15 to 35 are performed in the same manner as in the first embodiment. Next, as illustrated in FIG. 50, the interconnect layer 21 is removed after bonding.

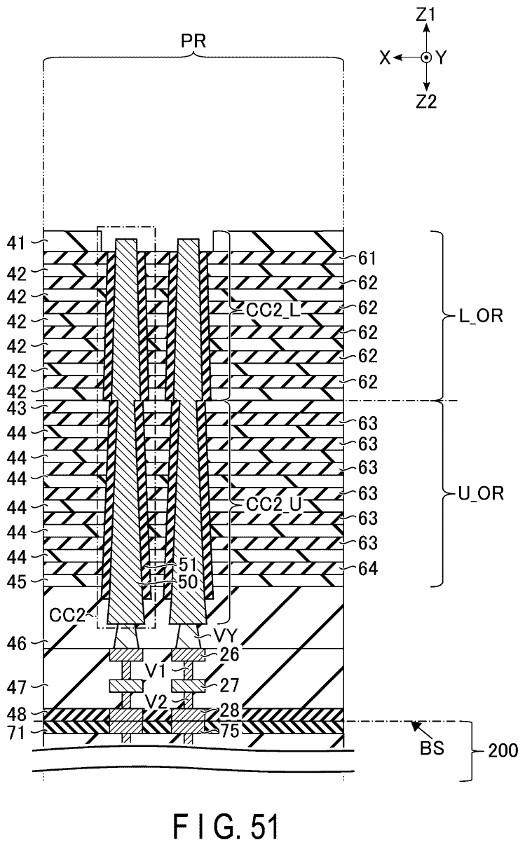

Next, as illustrated in FIG. 51, a portion of the insulating layer 41 in the vicinity of the contact CC2 (the portion covering the contact CC2) is removed. For example, a mask having an opening at the region where the insulating layer 41 is to be removed is formed by photolithography or the like, and the insulating layer 41 is removed by anisotropic etching using the mask. At this time, the insulator 51 of an upper portion of each contact CC2 is also removed. As a result, the upper surface of the contact CC2 (the conductor 50) is exposed.

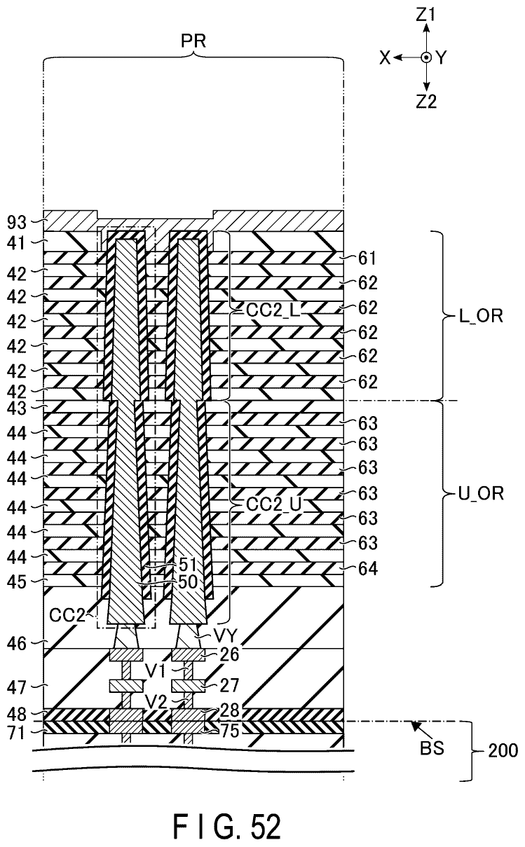

Next, as illustrated in FIG. 52, the interconnect layer 93 is provided on the exposed portion of the contact CC2, on the insulating layer 41, and on the side surface of the insulating layer 41. The interconnect layer 93 includes, for example, aluminum.

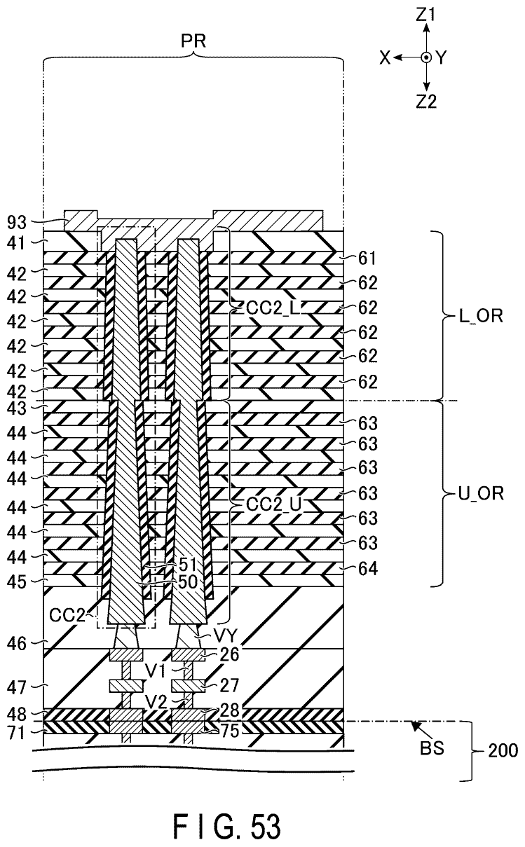

Next, as illustrated in FIG. 53, the interconnect layer 93 provided on the insulating layer 41 is processed so that a portion of the interconnect layer 93 is removed. Thereafter, the insulating layers 94 and 95 are stacked in this order, and the portion of the interconnect layer 93 corresponding to a pad PD is exposed, thereby forming the pad PD as illustrated in FIG. 49.

### 1.10.3 Effects According to Present Modification

According to the present modification, effects similar to those of the first embodiment are obtained.

### 2. SECOND EMBODIMENT

A semiconductor memory device according to the second embodiment will be described. A semiconductor memory device 3 according to the present embodiment is different from the first embodiment in that the contacts CC2 have a structure formed using the support pillars HR. In the following, the differences from the first embodiment will be mainly described.

### 2.1 Cross-Sectional Structure of Peripheral Region

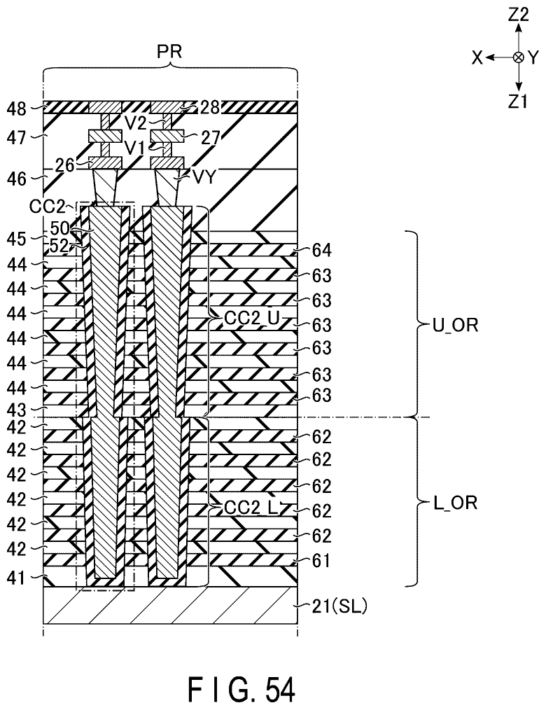

FIG. 54 is a cross-sectional view illustrating an example of a cross-sectional structure in the peripheral region PR of the semiconductor memory device 3 according to the second embodiment. As illustrated in FIG. 54, the contact CC2 (each of the lower and upper contacts CC2_L and CC2_U) includes an insulator 52 and the conductor 50 embedded in the insulator 52. The insulator 52 covers the side surface and the bottom surface of the conductor 50. In other words, the position of the upper end of the conductor 50 is the same as the position of the upper end of the insulator 52. At the junction portion between the lower and upper contacts CC2_L and CC2_U, the side surfaces of the lower and upper contacts CC2_L and CC2_U are shifted from each other. Note that the side surfaces of the lower and upper contacts CC2_L and CC2_U may not be shifted from each other.

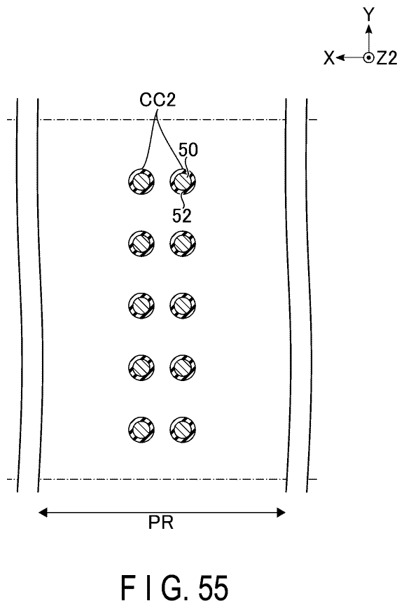

FIG. 55 is a plan view illustrating an example of a planar layout of the peripheral region PR of the semiconductor memory device 3 according to the second embodiment. As illustrated in FIG. 55, the semiconductor memory device 3 includes, for example, a plurality of contacts CC2 in the peripheral region PR. As will be described later, holes corresponding to the contacts CC2 are formed in a step of forming holes for support pillars HR. Therefore, the contacts CC2 each have, for example, a circular cross-sectional shape in the XY plane. In this example, the contacts CC2 are arranged in five rows. The cross-sectional area of the lower contact CC2_L is larger than the cross-sectional area of the lower pillar HR_L. The cross-sectional area of the upper contact CC2_U is larger than the cross-sectional area of the upper pillar HR_U. That is, each contact CC2 has a structure in which the conductor 50 is embedded in the support pillar HR (insulator 52).

### 2.2 Method of Manufacturing Semiconductor Memory Device

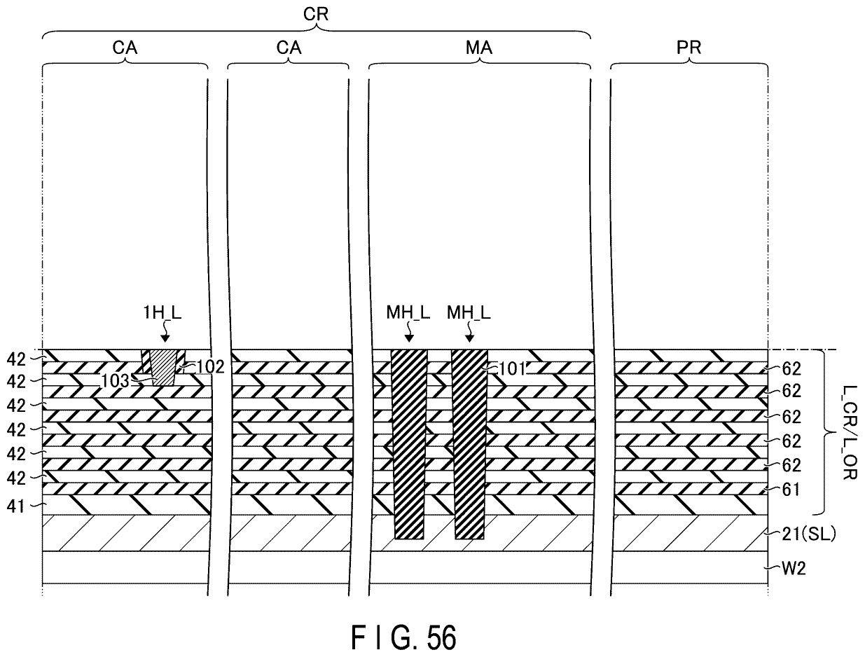

A method of manufacturing the semiconductor memory device 3 according to the second embodiment will be described with reference to FIGS. 56 to 66. FIGS. 56 to 66 are cross-sectional views each illustrating an example of a cross-sectional structure in the process of manufacturing the semiconductor memory device 3 according to the second embodiment. FIGS. 56 to 66 illustrate four cross-sectional structures side by side, which correspond to FIGS. 10, 11, 7, and 54, respectively, in order from the left side of the drawing. In FIGS. 56 to 66, a description will be given assuming that the Z2 direction is upward and the Z1 direction is downward.

As illustrated in FIG. 56, the steps of FIGS. 15 to 18 are performed in the same manner as in the first embodiment except for the step of forming the hole 2H_L, the step of forming the insulator 102 in the hole 2H_L, and the step of embedding the sacrificial member 103 in the hole 2H_L.

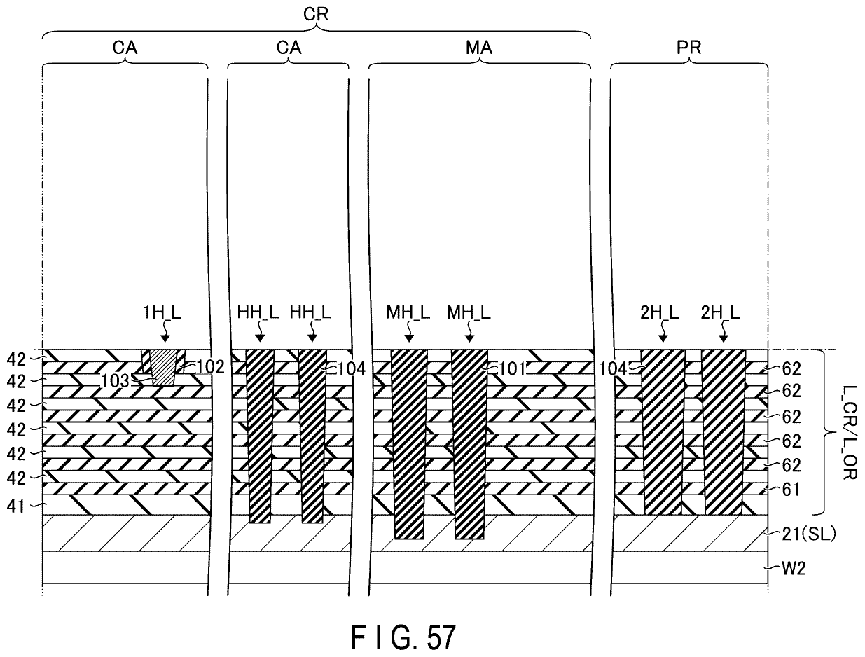

Next, as illustrated in FIG. 57, similarly to the first embodiment, holes HH_L corresponding to the lower pillars HR_L and holes 2H_L corresponding to the lower contacts CC2_L are provided. The cross-sectional area of each hole 2H_L is larger than the cross-sectional area of each hole HH_L. The lower ends of the holes HH_L reach the inside of the interconnect layer 21. The lower ends of the holes 2H_L reach the interconnect layer 21. Thereafter, each of the holes HH_L and 2H_L is filled with a sacrificial member 104.

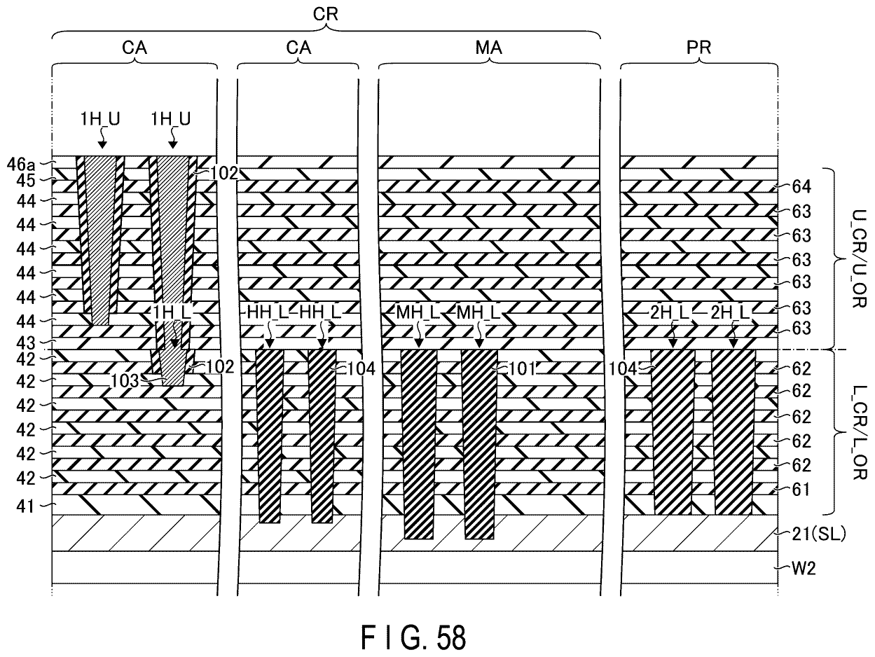

Next, as illustrated in FIG. 58, the steps in FIGS. 20 to 23 are performed in the same manner as in the first embodiment, except for the step of forming holes 2H_U, the step of forming the insulator 102 in each hole 2H_U, and the step of embedding the sacrificial member 103 in each hole 2H_U.

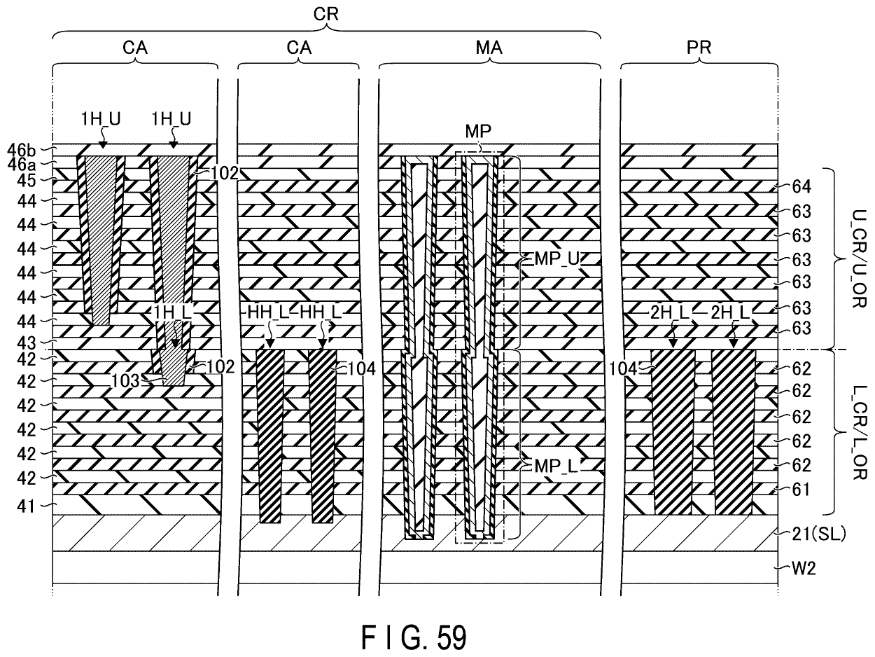

Next, as illustrated in FIG. 59, similarly to the first embodiment, after memory pillars MP are formed, the insulating layer 46b is provided on the insulating layer 46a.

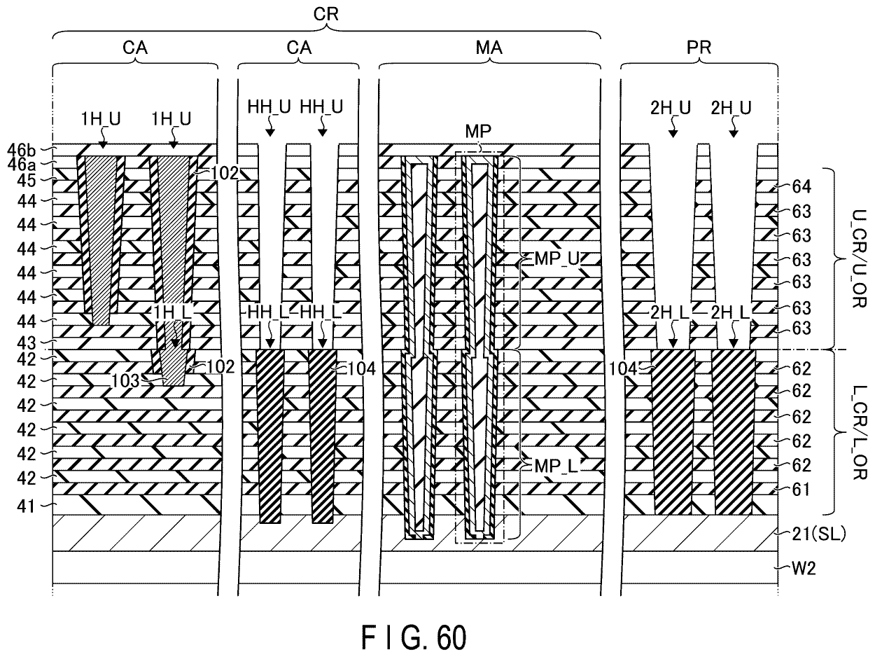

Next, as illustrated in FIG. 60, similarly to the first embodiment, holes HH_U corresponding to the upper pillars HR_U and holes 2H_U corresponding to the upper contacts CC2_U are provided. The cross-sectional area of each hole 2H_U is larger than the cross-sectional area of each hole HH_U. The lower end of each hole HH_U reaches the upper surface of the sacrificial member 104. The lower end of each hole 2H_U reaches the upper surface of the sacrificial member 104. The insulating layer 46b includes, for example, silicon oxide.

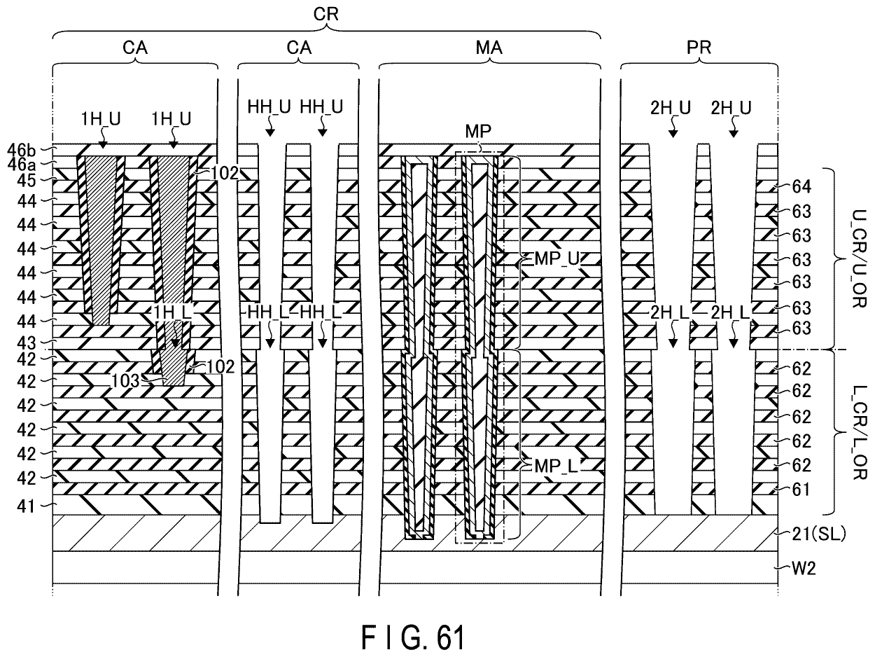

Next, as illustrated in FIG. 61, the sacrificial member 104 in each of the holes HH_L and the sacrificial member 104 in each of the holes 2H_L are removed by, for example, wet etching similarly to the first embodiment. As a result, the holes HH_L and HH_U are connected, and the interconnect layer 21 is exposed. The holes 2H_L and 2H_U are connected, and the interconnect layer 21 is exposed.

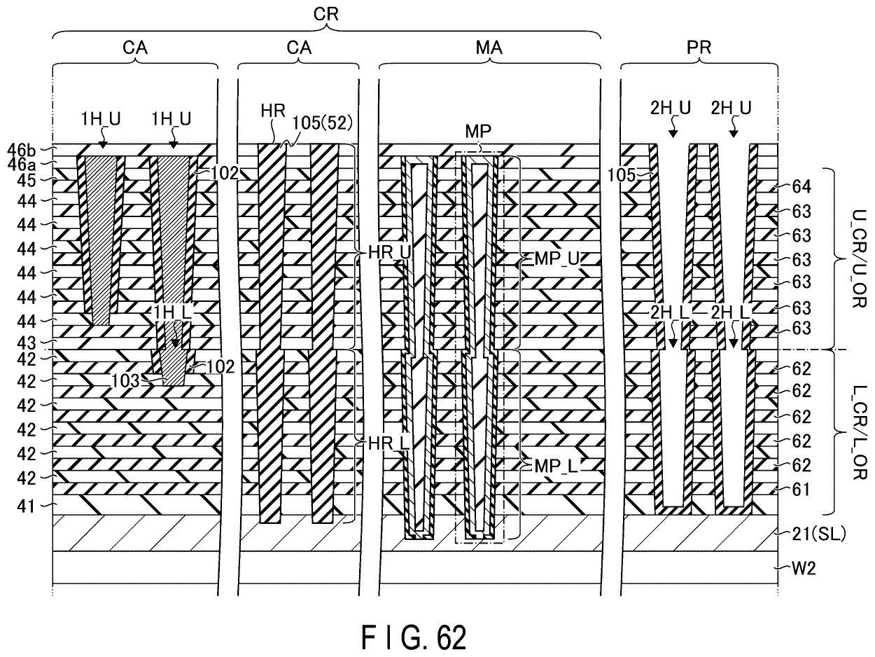

Next, as illustrated in FIG. 62, as in the first embodiment, the holes HH_L and HH_U are filled with the insulator 105 to form the support pillars HR. At this time, the insulator 105 is also provided in each of the holes 2H_L and 2H_U. That is, the step of embedding the insulator 105 in the holes HH_L and HH_U and the step of forming the insulator 105 in the holes 2H_L and 2H_U are simultaneously performed. Since the cross-sectional area of the hole 2H_L is larger than the cross-sectional area of the hole HH_L, and the cross-sectional area of the hole 2H_U is larger than the cross-sectional area of the hole HH_U, each of the holes 2H_L and 2H_U is not filled with the insulator 105, and the insulator 105 is provided on the side surface and the bottom surface of each of the holes 2H_L and 2H_U. The insulator 105 includes, for example, silicon oxide. The insulator 105 included in each support pillar HR corresponds to the insulator 52.

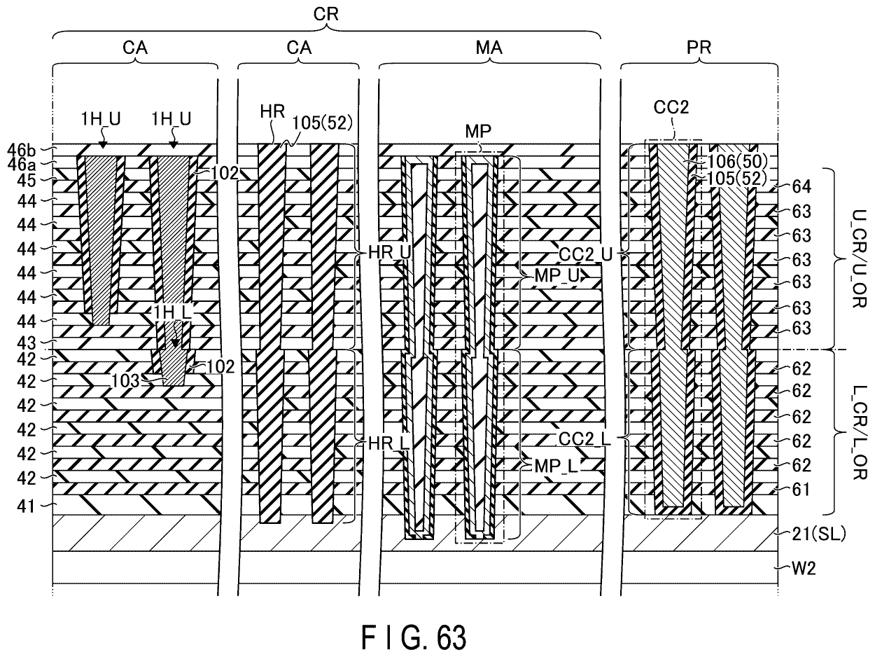

Next, as illustrated in FIG. 63, the contacts CC2 are formed by embedding each of the holes 2H_L and 2H_U with the conductor 106, similarly to the first embodiment. The conductor 106 is, for example, tungsten. The insulator 105 and the conductor 106 included in each of the contacts CC2 correspond to the insulator 52 and the conductor 50, respectively.

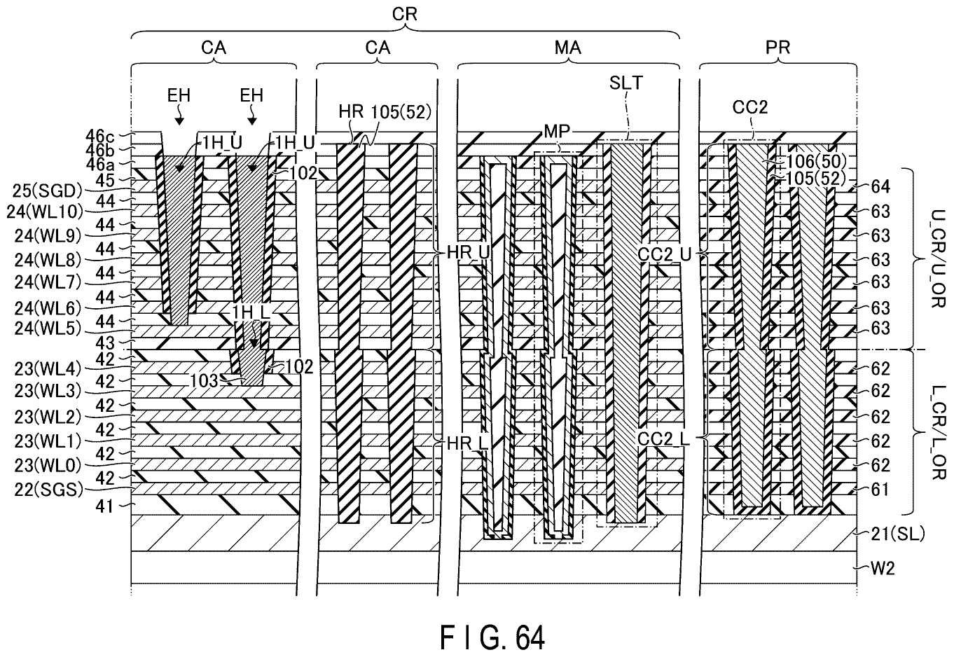

Next, as illustrated in FIG. 64, similarly to the first embodiment, after the insulating layer 46c is provided on the insulating layer 46b, the hole EH corresponding to the contact CC1 is provided. The lower end of the hole EH reaches the upper surface of the sacrificial member 103. The insulating layer 46c includes, for example, silicon oxide.

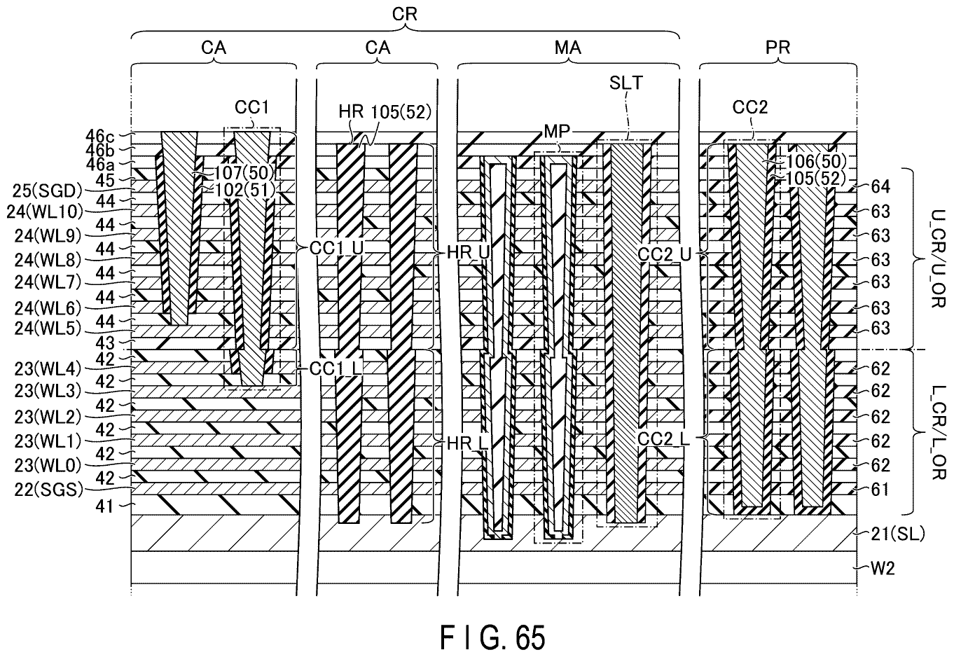

Next, as illustrated in FIG. 65, similarly to the first embodiment, for example, the sacrificial member 103 of each of the holes 1H_L and 1H_U is removed by wet etching, and then each of the holes 1H_L and 1H_U is embedded with a conductor 107, whereby the contact CC1 is formed. The conductor 107 is, for example, tungsten. The insulator 102 and the conductor 107 included in the contact CC1 correspond to the insulator 51 and the conductor 50, respectively. The upper surface of the contact CC2 is positioned below the upper surface of the contact CC1. This means that the lower surface of the contact CC2 is positioned above the lower surface of the contact CC1 in the structure after bonding.

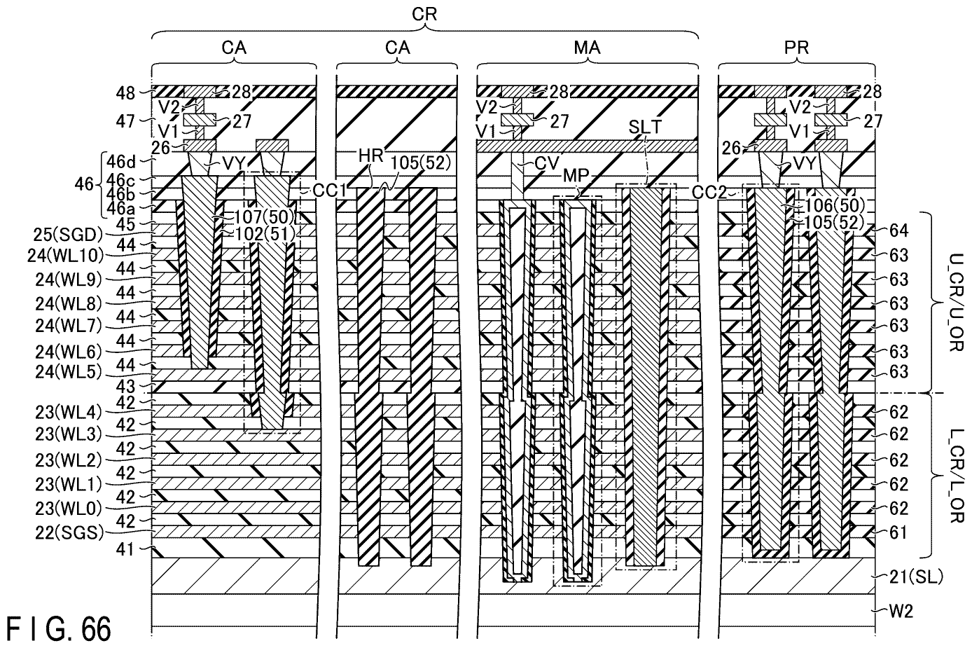

Next, as illustrated in FIG. 66, similarly to the first embodiment, an insulating layer 46d, the insulating layer 47, the interconnect layer 26, the contact V1, the interconnect layer 27, the contact V2, the insulating layer 48, and the interconnect layer 28 are provided on the insulating layer 46c.

### 2.3 Effects According to Present Embodiment

In the semiconductor memory device 3 according to the present embodiment, the contacts CC2 are formed using the support pillars HR. More specifically, the step of forming the support pillar HR in the contact area CA and the step of forming the insulator 52 in the holes 2H_L and 2H_U corresponding to the contacts CC2 in the peripheral region PR are simultaneously performed. Thereafter, the holes 2H_L and 2H_U are filled with the conductor 50. As a result, the contacts CC2 are formed. Therefore, the steps of processing insulating layers can be merged. As a result, the number of manufacturing steps can be reduced as compared with the case where the formation of the support pillars HR and the formation of the insulator in the holes 2H_L and 2H_U are performed in separate steps. Therefore, according to the semiconductor memory device 3 according to the present embodiment, the manufacturing cost can be reduced, similarly to the first embodiment.

### 2.4 Modification

A semiconductor memory device according to a modification of the second embodiment will be described. In the semiconductor memory device 3 according to the present modification, the manufacturing method is different from that of the second embodiment. In the following, the differences from the second embodiment will be mainly described.

### 2.4.1 Cross-Sectional Structure of Peripheral Region

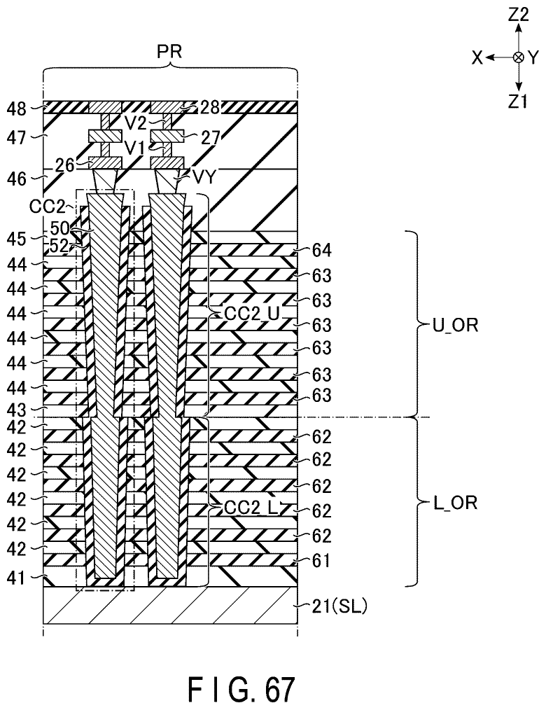

FIG. 67 is a cross-sectional view illustrating an example of a cross-sectional structure in the peripheral region PR of the semiconductor memory device 3 according to the modification of the second embodiment. As illustrated in FIG. 67, the contact CC2 (each of the lower and upper contacts CC2_L and CC2_U) includes the insulator 52 and the conductor 50 embedded in the insulator 52. The insulator 52 covers the side surface and the bottom surface of the conductor 50 except for the upper portion of the conductor 50. In other words, the upper end of the conductor 50 is positioned above the upper end of the insulator 52. At the junction portion between the lower and upper contacts CC2_L and CC2_U, the side surfaces of the lower and upper contacts CC2_L and CC2_U are shifted from each other.

### 2.4.2 Method of Manufacturing Semiconductor Memory Device

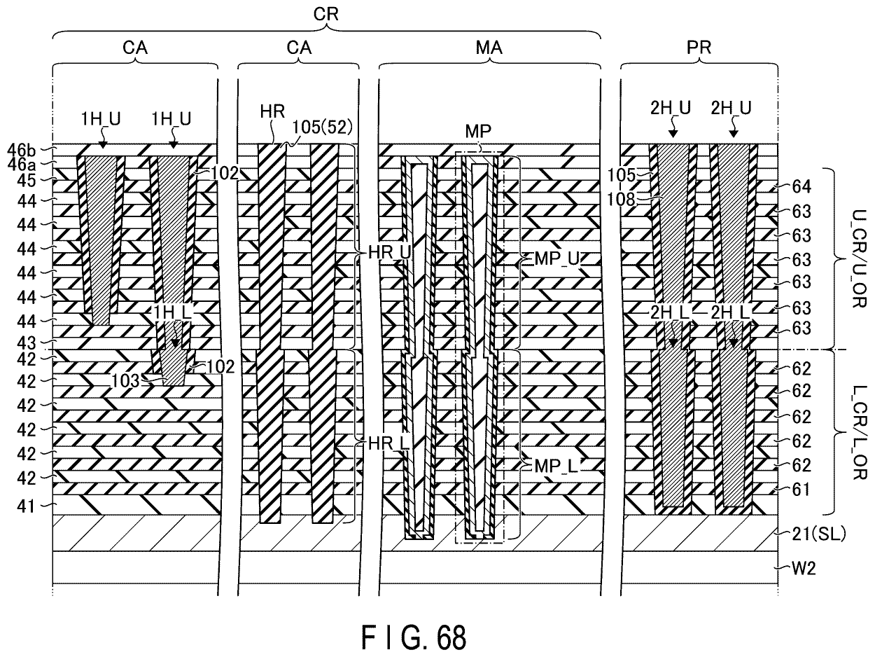

A method of manufacturing the semiconductor memory device 3 according to the present modification will be described with reference to FIGS. 68 to 72. FIGS. 68 to 72 are cross-sectional views each illustrating an example of a cross-sectional structure in the process of manufacturing the semiconductor memory device 3 according to the modification of the second embodiment. FIGS. 68 to 72 illustrate four cross-sectional structures side by side, which correspond to FIGS. 10, 11, 7, and 67, respectively, in order from the left side of the drawing. In FIGS. 68 to 72, a description will be given assuming that the Z2 direction is upward and the Z1 direction is downward.

As shown in FIG. 68, similarly to the second embodiment, after the steps of FIGS. 56 to 62 are performed, each of the holes 2H_L and 2H_U is embedded with a sacrificial member 108. The sacrificial member 108 includes, for example, polysilicon.

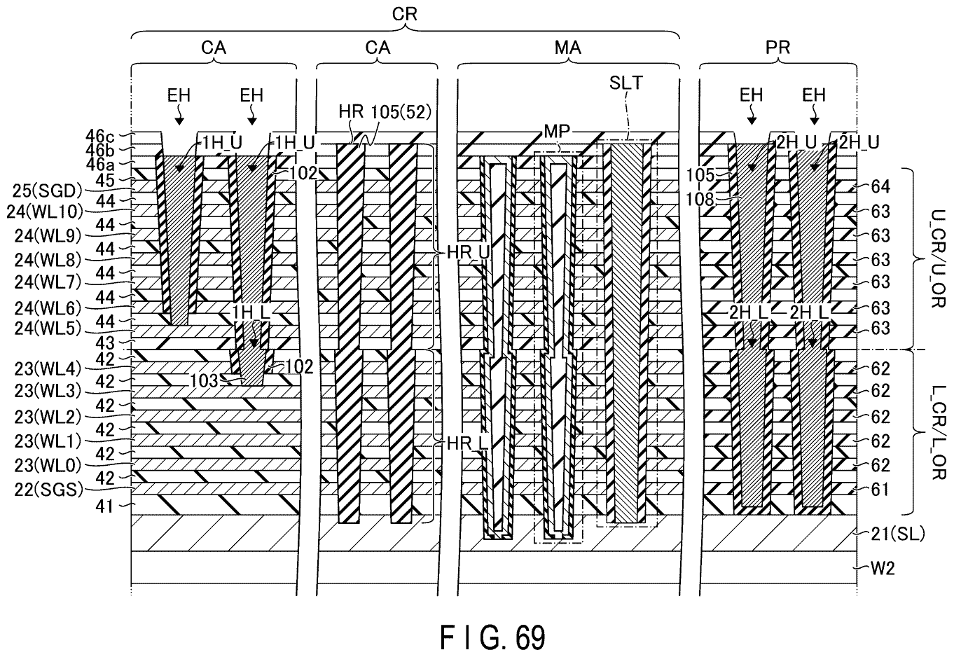

Next, as illustrated in FIG. 69, similarly to the second embodiment, after the insulating layer 46c is provided on the insulating layer 46b, holes EH corresponding to the contacts CC1 and CC2 are provided. The lower end of each of the holes EH corresponding to the contacts CC1 reaches the upper surface of the sacrificial member 103. The lower end of each of the holes EH corresponding to the contacts CC2 reaches the upper surface of the sacrificial member 108.

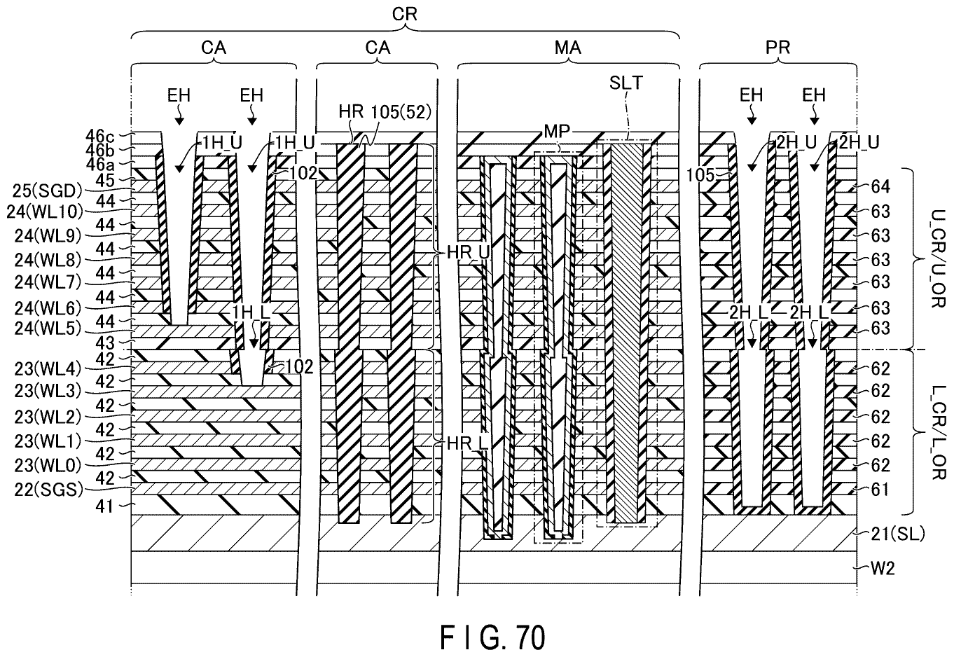

Next, as illustrated in FIG. 70, the sacrificial member 103 in each of the holes 1H_L and 1H_U and the sacrificial member 108 in each of the holes 2H_L and 2H_U are removed by, for example, wet etching similarly to the second embodiment.

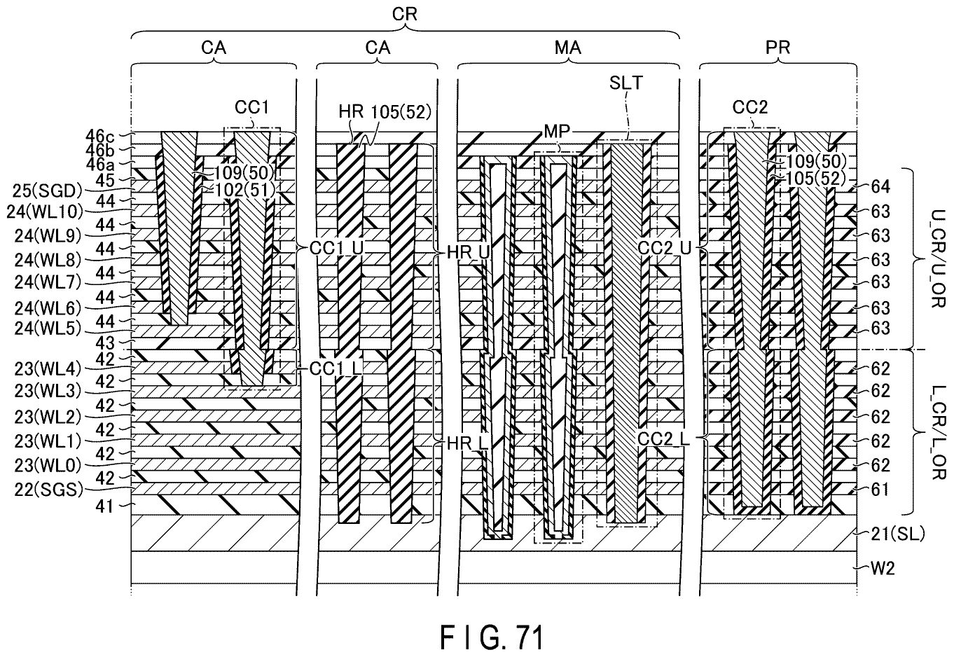

Next, as illustrated in FIG. 71, each of the holes 1H_L, 1H_U, 2H_L, and 2H_U is embedded with a conductor 109, whereby the contacts CC1 and CC2 are formed. The conductor 109 is, for example, tungsten. The insulator 102 and the conductor 109 included in the contact CC1 correspond to the insulator 51 and the conductor 50, respectively. The insulator 105 and the conductor 109 included in the contact CC2 correspond to the insulator 52 and the conductor 50, respectively.

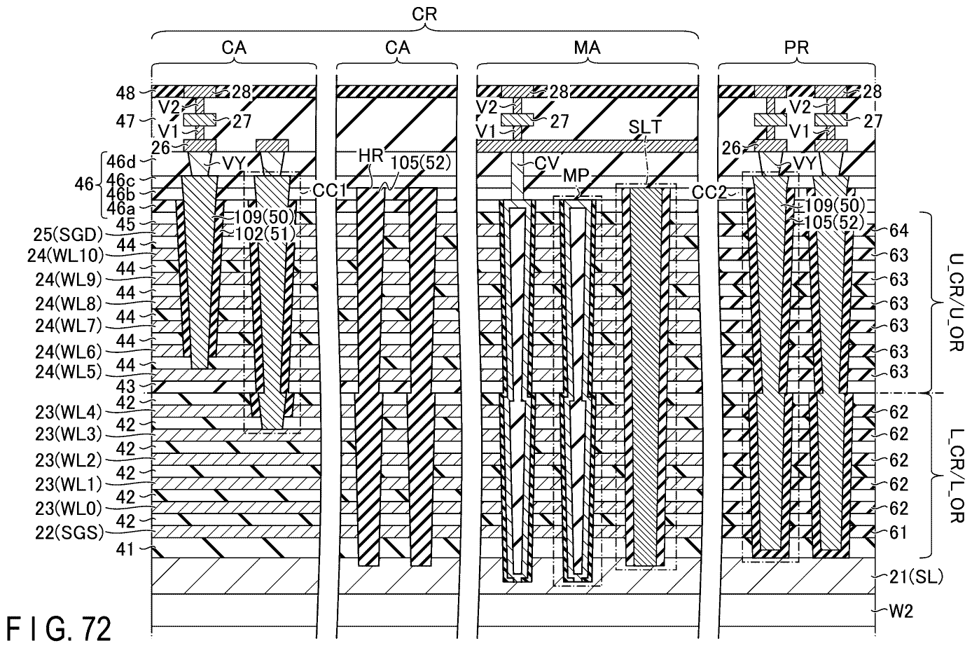

Next, as illustrated in FIG. 72, similarly to the first embodiment, the insulating layer 46d, the insulating layer 47, the interconnect layer 26, the contact V1, the interconnect layer 27, the contact V2, the insulating layer 48, and the interconnect layer 28 are provided on the insulating layer 46c.

### 2.4.3 Effects According to Present Modification

In the semiconductor memory device 3 according to the present modification, the step of forming the support pillars HR in the contact area CA and the step of forming the insulator 52 in the holes 2H_L and 2H_U corresponding to the contacts CC2 in the peripheral region PR are simultaneously performed, and then sacrificial members are embedded in the holes 2H_L and 2H_U. Thereafter, a step of removing the sacrificial member in each of the holes 1H_L and 1H_U corresponding to the contact hole CC1 and the holes 2H_L and 2H_U and a step of embedding the conductor 50 in each of the holes 1H_L, 1H_U, 2H_L, and 2H_U are simultaneously performed. As a result, the contacts CC2 are formed. Therefore, the steps of processing insulating layers can be merged. As a result, the number of manufacturing steps can be reduced as compared with the case where the formation of the support pillars HR and the formation of the insulator in the holes 2H_L and 2H_U are performed in separate steps. Therefore, according to the semiconductor memory device 3 according to the present modification, the manufacturing cost can be reduced, similarly to the first embodiment.

### 3. THIRD EMBODIMENT

A semiconductor memory device according to the third embodiment will be described. A semiconductor memory device 3 according to the present embodiment is different from that of the first embodiment in that the contact CC2 has a structure formed using the member SLT. In the following, the differences from the first embodiment will be mainly described.

### 3.1 Cross-sectional Structure of Peripheral Region

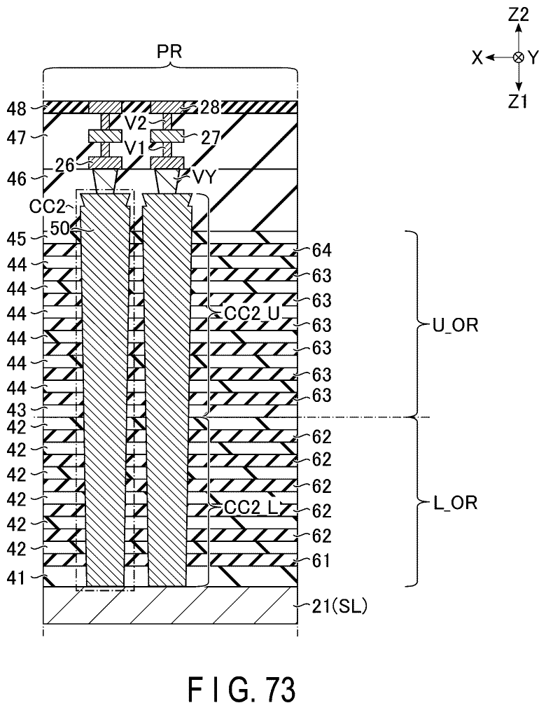

FIG. 73 is a cross-sectional view illustrating an example of a cross-sectional structure in the peripheral region PR of the semiconductor memory device 3 according to the third embodiment. As illustrated in FIG. 73, the contact CC2 (each of the lower and upper contacts CC2_L and CC2_U) includes the conductor 50. At the junction portion between the lower and upper contacts CC2_L and CC2_U, the side surfaces of the lower and upper contacts CC2_L and CC2_U are not shifted from each other.

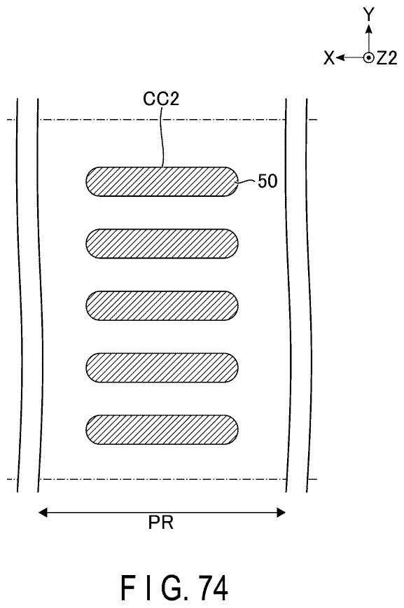

FIG. 74 is a plan view illustrating an example of a planar layout of the peripheral region PR of the semiconductor memory device 3 according to the third embodiment. As illustrated in FIG. 74, the semiconductor memory device 3 includes, for example, a plurality of contacts CC2 in the peripheral region PR. As will be described later, holes corresponding to the contacts CC2 are formed using the member SLT. Further, the holes corresponding to the contacts CC2 are filled with the conductor 50 in the step of forming contacts CC1. Therefore, the contacts CC2 each have, for example, an elliptical cross-sectional shape in the XY plane and include the conductor 50. In this example, the contacts CC2 are arranged in five rows. Each contact CC2 may include an insulator, and the insulator may cover the side surface of the conductor 50.

### 3.2 Method of Manufacturing Semiconductor Memory Device

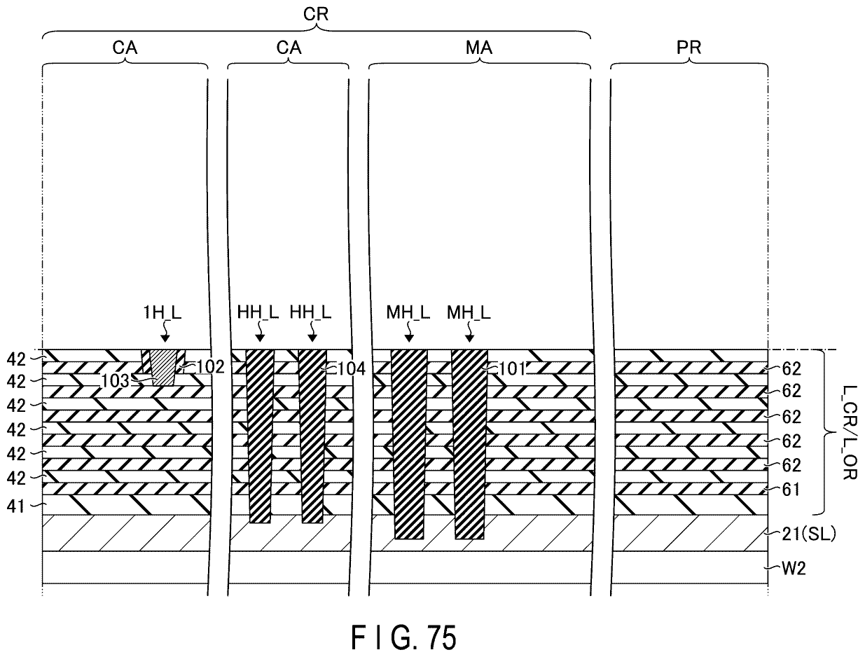

A method of manufacturing the semiconductor memory device 3 according to the third embodiment will be described with reference to FIGS. 75 to 84. FIGS. 75 to 84 are cross-sectional views each illustrating an example of a cross-sectional structure in the process of manufacturing the semiconductor memory device 3 according to the third embodiment. FIGS. 75 to 84 illustrate four cross-sectional structures side by side, which correspond to FIGS. 10, 11, 7, and 74, respectively, in order from the left side of the drawing. In FIGS. 75 to 84, a description will be given assuming that the Z2 direction is upward and the Z1 direction is downward.

As illustrated in FIG. 75, the steps of FIGS. 15 to 19 are performed in the same manner as in the first embodiment except for the step of forming the hole 2H_L, the step of forming the insulator 102 in the hole 2H_L, and the step of embedding the sacrificial member 103 in the hole 2H_L.

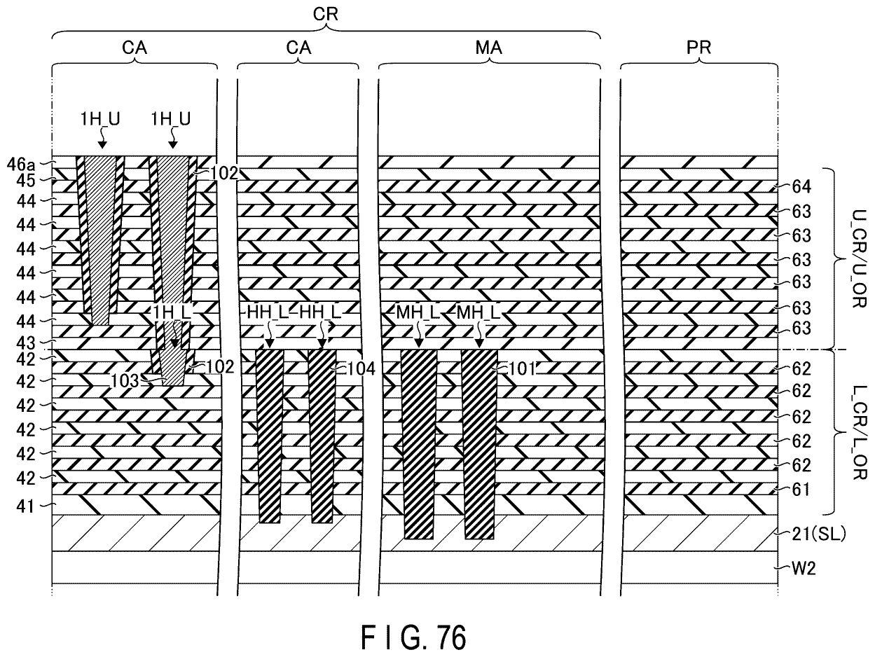

Next, as illustrated in FIG. 76, similarly to the first embodiment, after the insulating layers 43 to 45 and 46a and the insulating layers 63 and 64 are stacked on the uppermost insulating layer 42, a step of forming holes 1H_U, a step of forming the insulator 102 in the holes 1H_U, a step of removing the bottoms of the holes 1H_U, and a step of embedding the sacrificial member 103 in the holes 1H_U are performed.

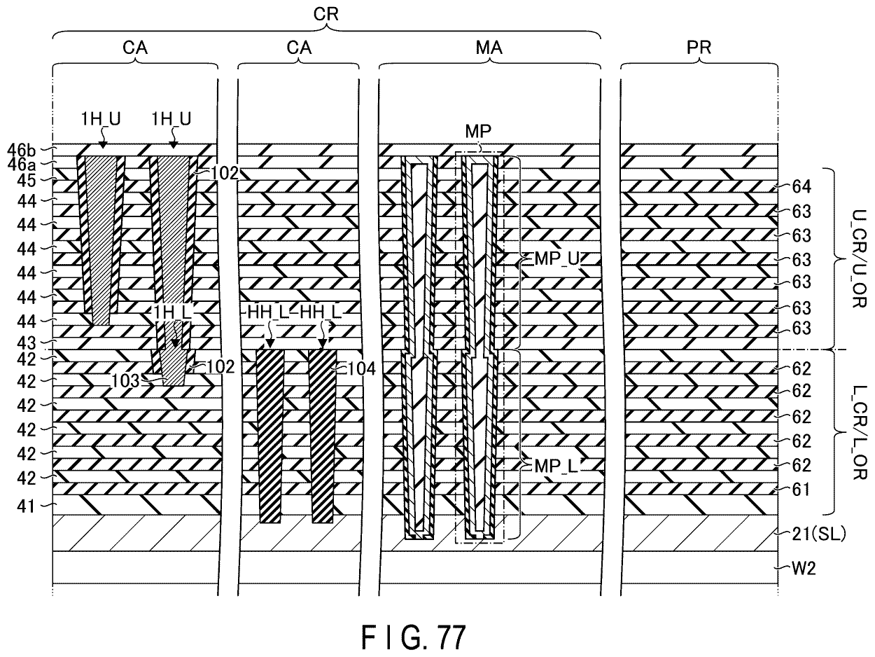

Next, as illustrated in FIG. 77, similarly to the first embodiment, after memory pillars MP are formed, the insulating layer 46b is provided on the insulating layer 46a.

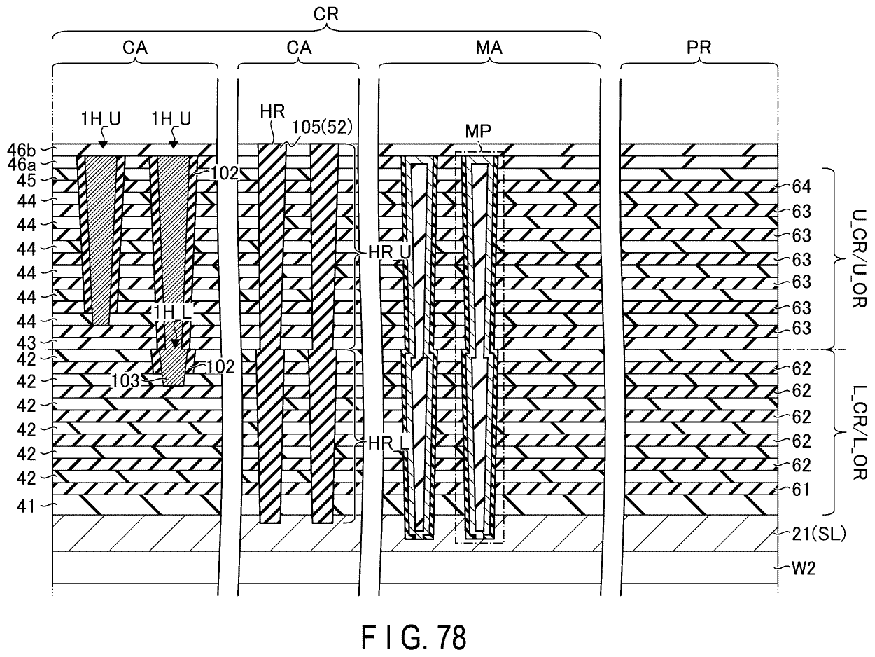

Next, as illustrated in FIG. 78, support pillars HR are formed in the same manner as in the first embodiment.

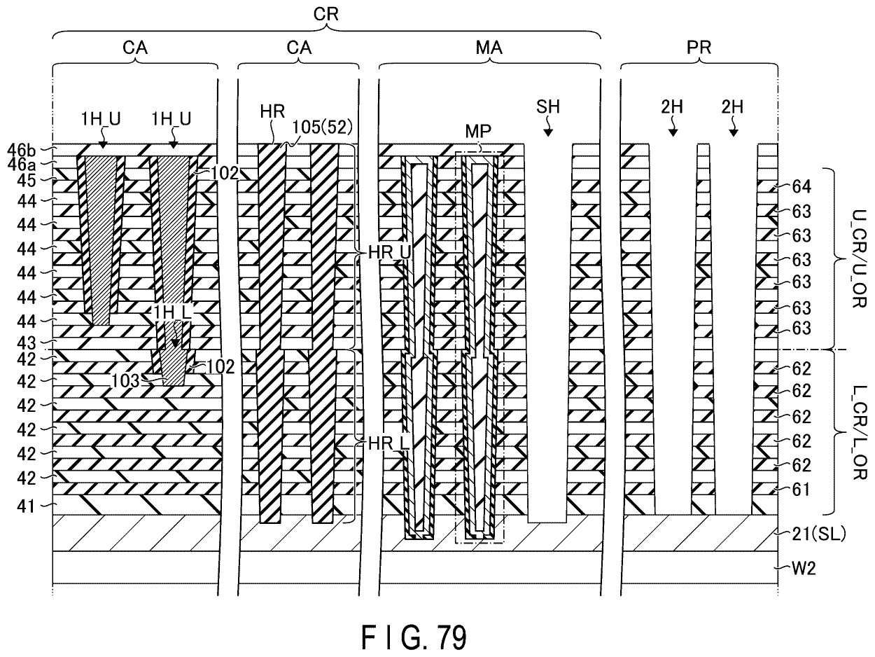

Next, as illustrated in FIG. 79, similarly to the first embodiment, holes SH corresponding to the members SLT and holes 2H corresponding to the contacts CC2 are provided. The lower end of the holes SH reaches the inside of the interconnect layer 21. The lower ends of the holes 2H reach the interconnect layer 21.

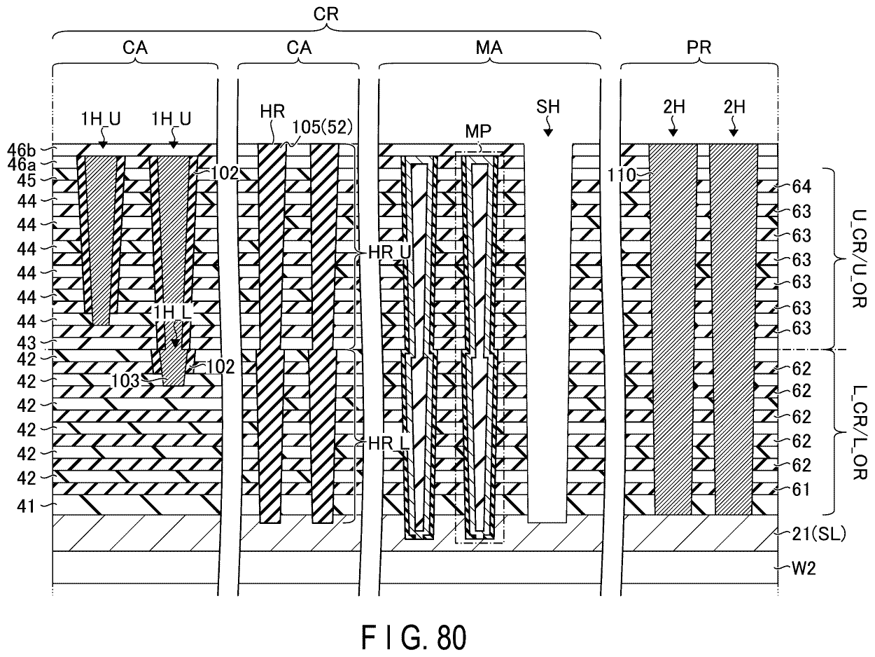

Next, as illustrated in FIG. 80, each of the holes 2H is filled with a sacrificial member 110 in the same manner as in the first embodiment. Thereafter, each of the holes SH is filled with the spacer SP and the contact LI to form the member SLT.

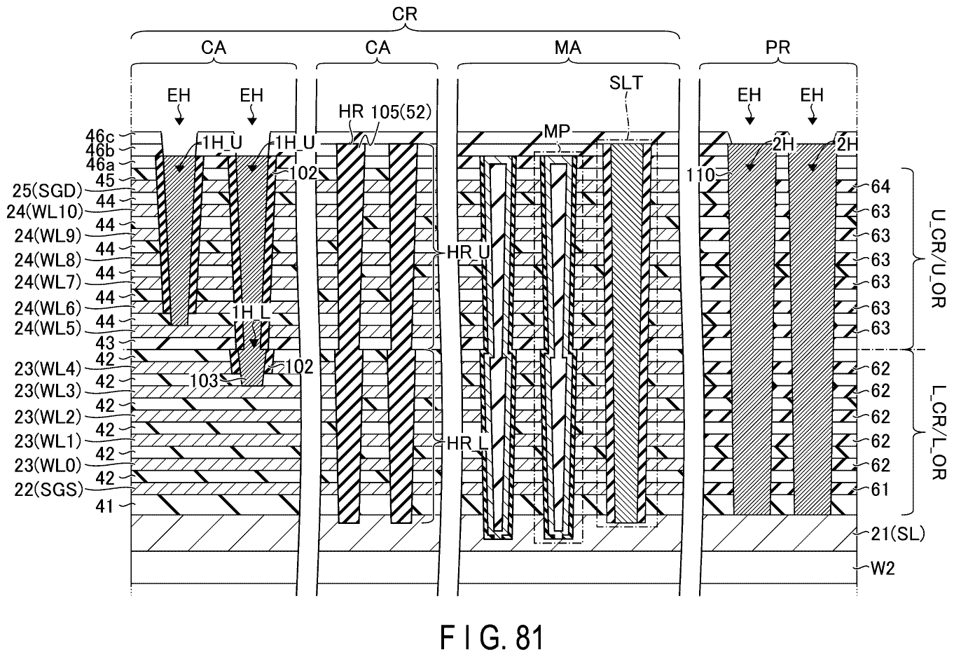

Next, as illustrated in FIG. 81, similarly to the first embodiment, after the insulating layer 46c is provided on the insulating layer 46b, holes EH corresponding to the contacts CC1 and CC2 are provided. The lower end of each of the holes EH corresponding to the contacts CC1 reaches the upper surface of the sacrificial member 103. The lower ends of each of the holes EH corresponding to the contacts CC2 reaches the upper surface of the sacrificial member 110.

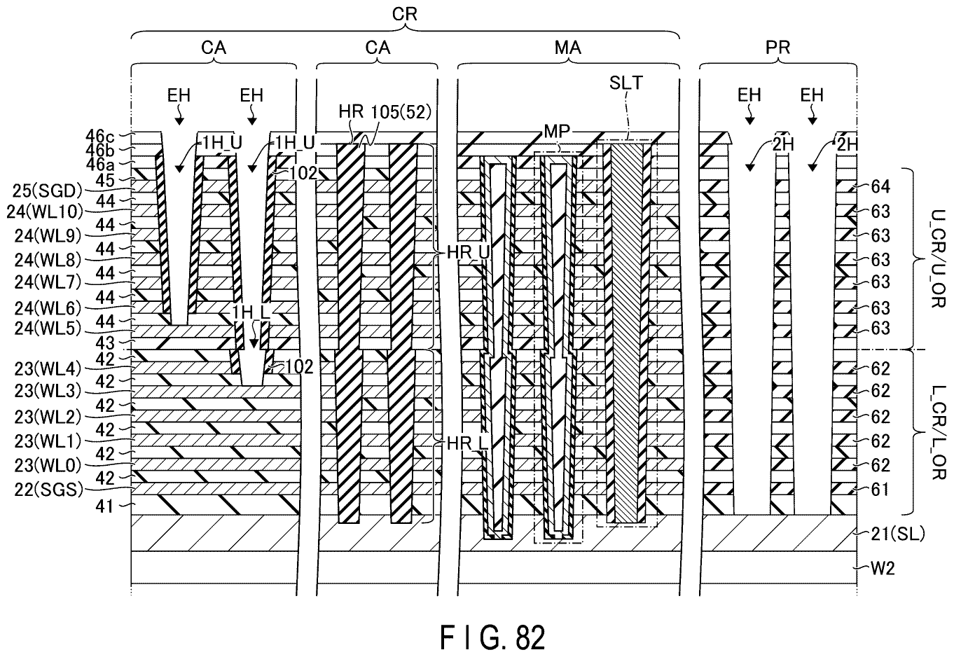

Next, as illustrated in FIG. 82, the sacrificial member 103 in each of the holes 1H_L and 1H_U and the sacrificial member 110 in each of the holes 2H are removed by, for example, wet etching similarly to the first embodiment.

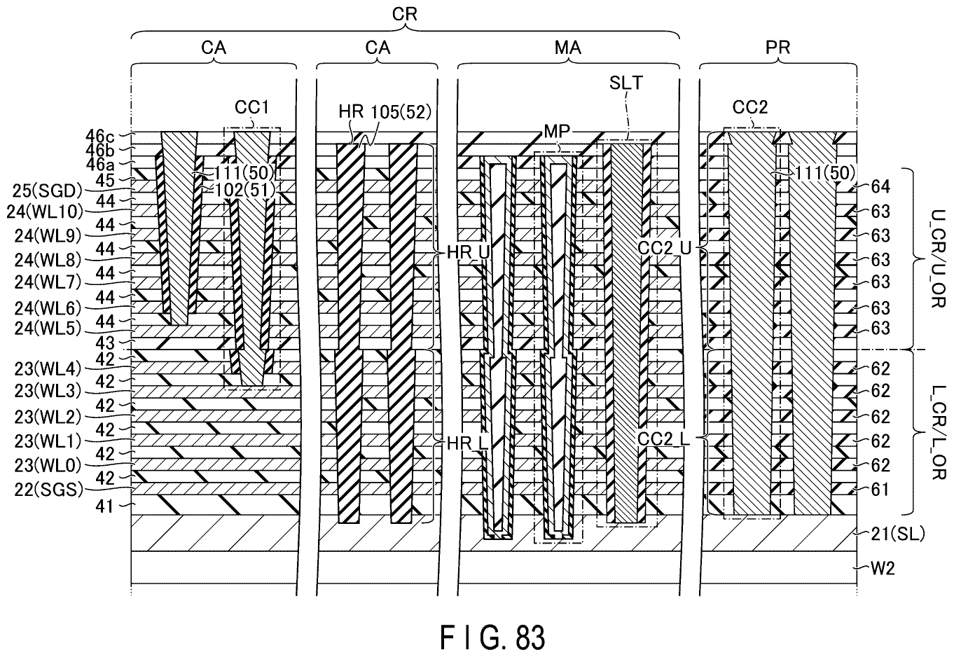

Next, as illustrated in FIG. 83, similarly to the first embodiment, each of the holes 1H_L, 1H_U, and 2H is embedded with a conductor 111, thereby forming the contacts CC1 and CC2. The conductor 111 is, for example, tungsten. The insulator 102 and the conductor 111 included in the contact CC1 correspond to the insulator 51 and the conductor 50, respectively. The conductor 111 included in the contact CC2 corresponds to the conductor 50.

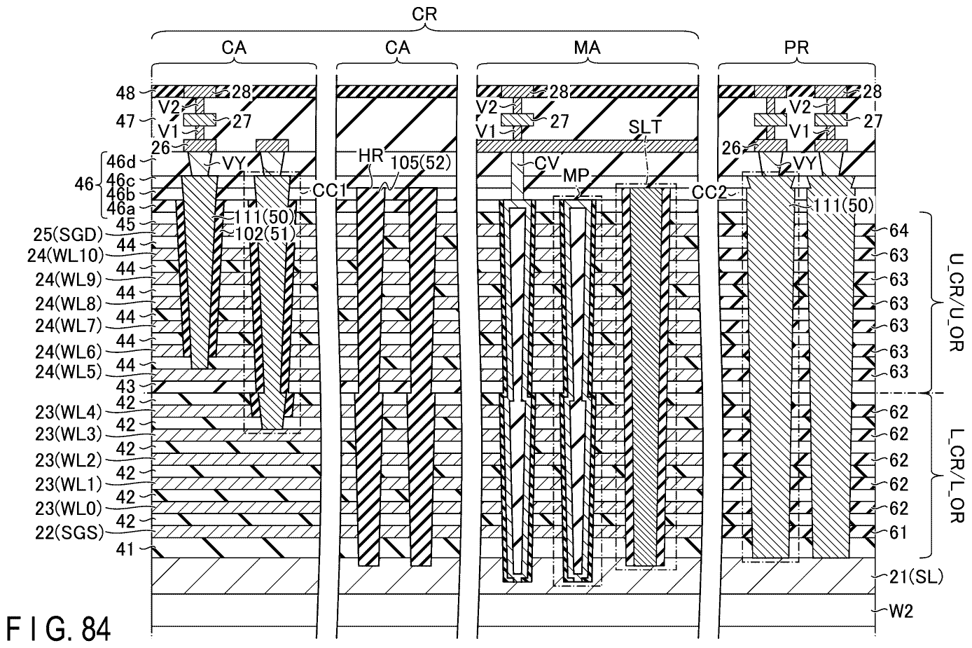

Next, as illustrated in FIG. 84, similarly to the first embodiment, the insulating layer 46d, the insulating layer 47, the interconnect layer 26, the contact V1, the interconnect layer 27, the contact V2, the insulating layer 48, and the interconnect layer 28 are provided on the insulating layer 46c.

### 3.3 Effects According to Present Embodiment

In the semiconductor memory device 3 according to the present embodiment, the contacts CC2 are formed using the member SLT. More specifically, after the step of forming the hole SH corresponding to the member SLT in the contact area CA and the step of forming the holes 2H corresponding to the contacts CC2 in the peripheral region PR are simultaneously performed, the holes 2H are filled with the sacrificial members. Thereafter, the step of removing the sacrificial member in each of the holes 1H_L and 1H_U corresponding to the contact hole CC1 and holes 2H and the step of embedding the conductor 50 in each of the holes 1H_L, 1H_U, and 2H are simultaneously performed. As a result, the contacts CC2 are formed. Therefore, the steps of processing insulating layers can be merged. As a result, the number of manufacturing steps can be reduced as compared with the case where the formation of the holes SH and the formation of the holes 2H are performed in separate steps. Therefore, according to the semiconductor memory device 3 according to the present embodiment, the manufacturing cost can be reduced, similarly to the first embodiment.

### 3.4 Modification

A semiconductor memory device according to a modification of the third embodiment will be described. In a semiconductor memory device 3 according to the present modification, the structure of the contacts CC2 is different from that of the third embodiment. In the following, the differences from the third embodiment will be mainly described.

### 3.4.1 Cross-sectional Structure of Peripheral Region

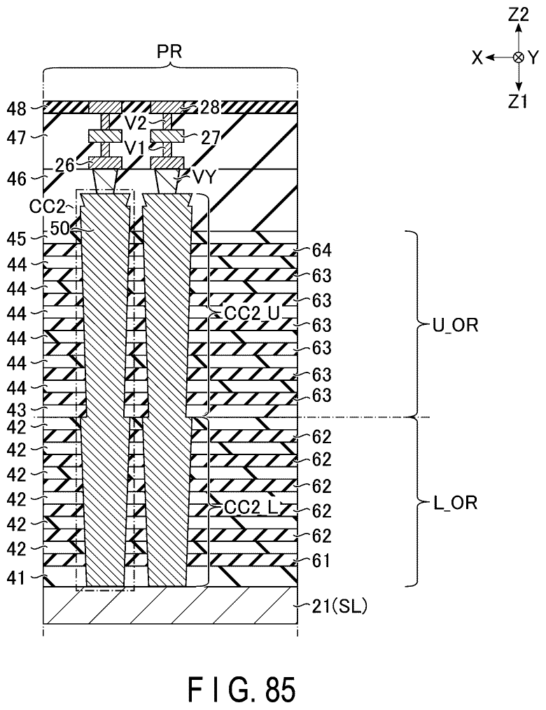

FIG. 85 is a cross-sectional view illustrating an example of a cross-sectional structure in the peripheral region PR of the semiconductor memory device 3 according to the modification of the third embodiment. As illustrated in FIG. 85, the contact CC2 (each of the lower and upper contacts CC2_L and CC2_U) includes the conductor 50. At the junction portion between the lower and upper contacts CC2_L and CC2_U, the side surfaces of the lower and upper contacts CC2_L and CC2_U are shifted from each other.

### 3.4.2 Method of Manufacturing Semiconductor Memory Device

A method of manufacturing the semiconductor memory device 3 according to the present modification will be described. For example, the step in FIG. 75 is performed in the same manner as in the third embodiment. Next, after the holes 2H_L (not illustrated) corresponding to the contacts CC2_L are formed, each of the holes 2H_L is filled with the sacrificial member 110. Next, the steps in FIGS. 76 to 78 are performed. Next, after the holes SH corresponding to the members SLT and the holes 2H_U (not illustrated) corresponding to the contacts CC2_U are formed, each of the holes 2H_U is filled with the sacrificial member 110. Next, the steps in FIGS. 81 to 84 are performed. As a result, the structure illustrated in FIG. 85 is formed.

### 3.4.3 Effects According to Present Modification

According to the present modification, effects similar to those of the third embodiment are obtained.

### 4. FOURTH EMBODIMENT

A semiconductor memory device according to the fourth embodiment will be described. In a semiconductor memory device 3 according to the present embodiment, the structure of the array chip 100 is different from that of the second embodiment. In the following, the differences from the second embodiment will be mainly described.

### 4.1 Planar Layout of Memory Cell Array

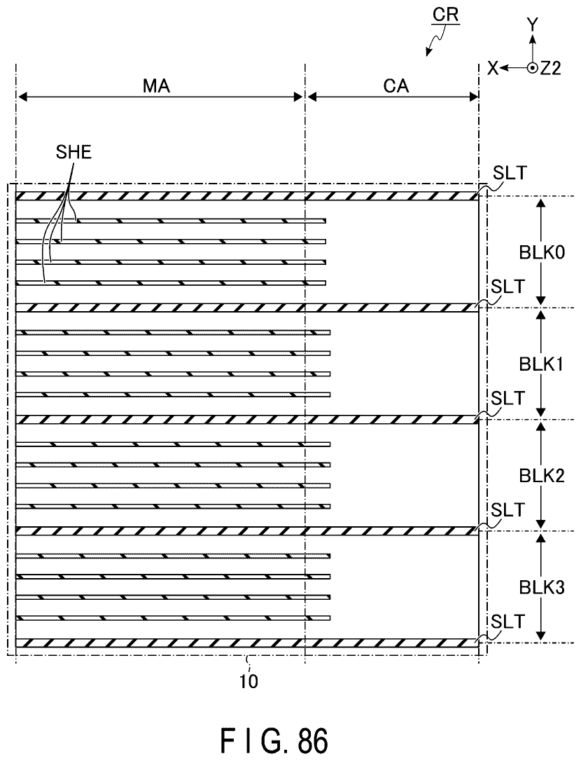

FIG. 86 is a plan view illustrating an example of a planar layout of the memory cell array 10 in the core region CR of the semiconductor memory device 3 according to the fourth embodiment. FIG. 86 illustrates a region corresponding to the four blocks BLK0 to BLK3 included in the memory cell array 10. As illustrated in FIG. 86, the memory cell array 10 includes, for example, a plurality of members SLT and a plurality of members SHE. In addition, the memory cell array 10 includes, for example, the memory area MA and the contact area CA arranged in the X direction.

Each member SLT has a portion extending along the X direction, and crosses the contact area CA and the memory area MA along the X direction. The members SLT are arranged in the Y direction. Each member SLT separates adjacent interconnects (for example, the word lines WL0 to WL7 and the select gate lines SGD and SGS), with the member SLT interposed between them. In each member SLT, a conductor with a side wall including an insulating spacer may be arranged, insulated from these interconnects, or an insulator may be embedded. In the memory cell array 10, each of the regions divided by the member SLT corresponds to one block BLK.

Each member SHE has a portion extending along the X direction, and crosses the memory area MA along the X direction. The members SHE are arranged in the Y direction. In this example, four members SHE are arranged between each adjacent pair of members SLT in the Y direction. Each member SHE has, for example, a structure in which an insulator is embedded. Each member SHE divides adjacent interconnects (at least the select gate lines SGD), with the member SHE interposed between them. In the memory cell array 10, each of the regions divided by the members SLT and SHE corresponds to one string unit SU.

Note that the planar layout of the memory cell array 10 included in the semiconductor memory device 3 may be another layout. For example, the number of members SHE arranged between two adjacent members SLT can be designed as appropriate. The number of string units SU included in each block BLK can be changed based on the number of members SHE arranged between two adjacent members SLT.

### 4.2 Planar Layout of Memory Area

The planar layout of the memory area MA is similar to that of FIG. 6 illustrated in the first embodiment.

### 4.3 Cross-Sectional Structure of Memory Area

The cross-sectional structure of the memory area MA is similar to that of FIG. 7 illustrated in the first embodiment.

### 4.4 Planar Layout of Contact Area

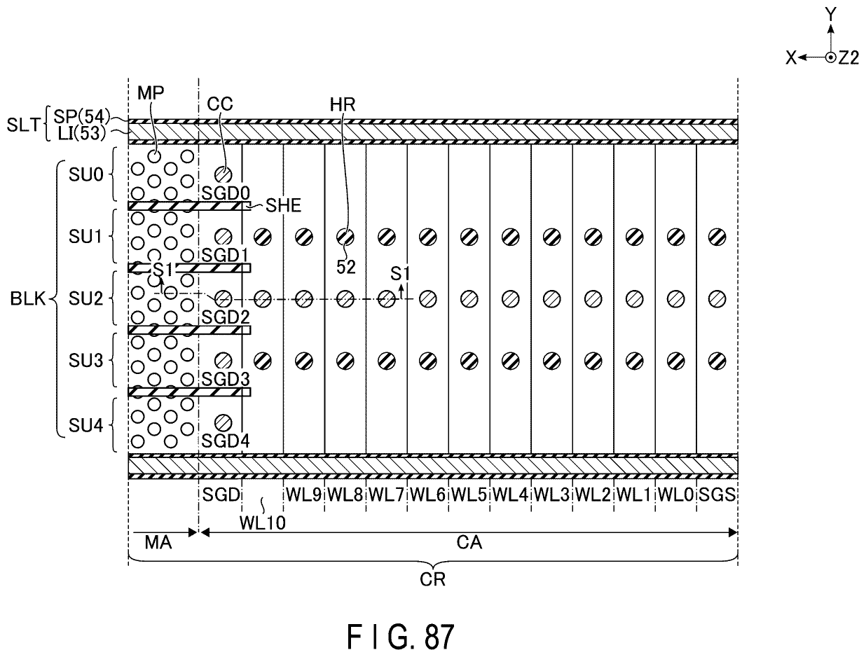

FIG. 87 is a plan view illustrating an example of a planar layout of the core region CR of the semiconductor memory device 3 according to the fourth embodiment. FIG. 87 also illustrates a portion of the memory area MA near the contact area CA. As illustrated in FIG. 87, in the contact area CA, for example, the end portions of the select gate line SGS, the word lines WL0 to WL10, and the select gate line SGD each have a terrace portion.

The terrace portion corresponds to a portion of the stacked interconnects that does not overlap the upper interconnect layer (conductive layer). The structure formed by a plurality of terrace portions resembles steps, terraces, rimstones, and the like. In this example, a stepped structure in which steps are arranged in the X direction is formed by the end portions of the select gate line SGS, the word lines WL0 to WL10, and the select gate line SGD. In other words, steps are formed between the select gate line SGS and the word line WL0, between the word lines WL0 and WL1, . . . , between the word lines WL9 and WL10, and between the word line WL10 and the select gate line SGD, respectively.

In addition, the semiconductor memory device 3 includes a plurality of contacts CC in a block BLK of the contact area CA. The contacts CC are members used to connect the row decoder module 15 and the stacked interconnects. Each contact CC is connected to one of the lower and upper stacked interconnects provided in the memory cell array 10 in the block BLK, that is, one of the terrace portions of the interconnect layers 22 to 25 (the select gate line SGS, word lines WL0 to WL10, and select gate line SGD).

Each support pillar HR has, for example, a circular cross-sectional shape in the XY plane. The support pillars HR are appropriately arranged in the part of the contact area CA excluding the members SLT and SHE and the contacts CC. The support pillars HR each include the insulator 52.

### 4.5 Cross-Sectional Structure of Contact Area

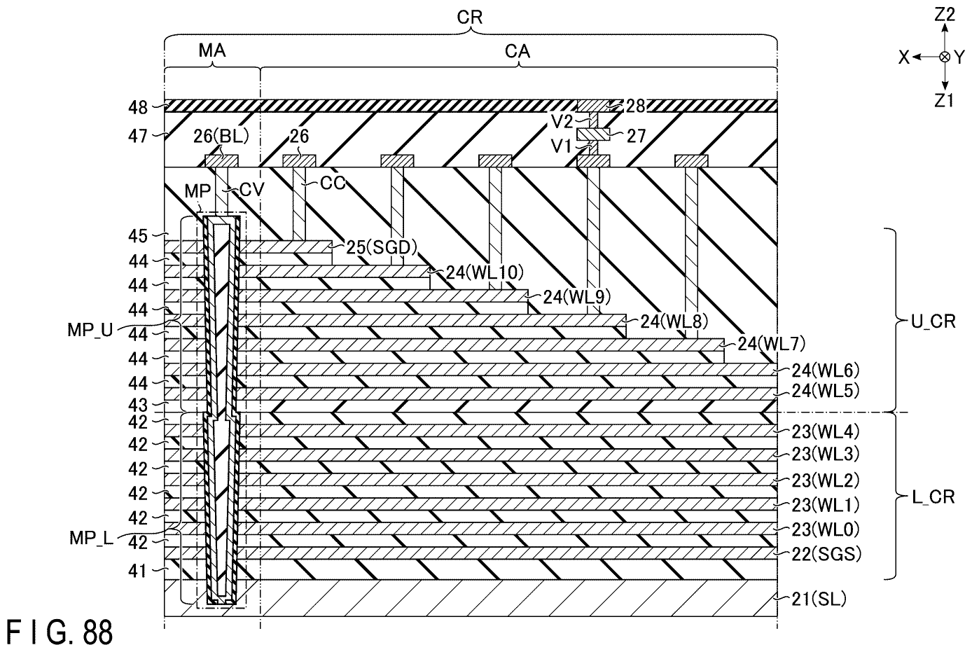

FIG. 88 is a cross-sectional view taken along line S1-S1 of FIG. 87, illustrating an example of a cross-sectional structure in the contact area CA of the memory cell array 10 included in the semiconductor memory device 3 according to the fourth embodiment. FIG. 88 also illustrates a cross-sectional structure in the memory area MA near the contact area CA. The cross-sectional structure in the memory area MA is similar to that of FIG. 7 illustrated in the first embodiment. As illustrated in FIG. 88, the end portions of the interconnect layers 22 to 25 are provided in a stepped structure, and the side surface and the upper surface of each of the interconnect layers 22 to 25 are covered with the insulating layer 45. The insulating layer 45 includes a portion provided in the same layer as the lower layer stack L_CR and a portion provided in the same layer as the upper layer stack U_CR. In the contact area CA, the insulating layers 47 and 48 are stacked on the insulating layer 45.

The contacts CC are provided on the terrace portions of the select gate line SGS, the word lines WL0 to WL7, and the select gate line SGD, respectively. Each contact CC penetrates the insulating layer 45. One interconnect layer 26 is provided on each of the contacts CC. The contact V1 is provided on each interconnect layer 26. Among the contacts V1, only the one corresponding to the word line WL8 is illustrated in FIG. 88. The interconnect layer 27 is provided on the contact V1. The contact V2 is provided on the interconnect layer 27. The interconnect layers 26 and 27 and the contacts V1 and V2 are covered with the insulating layer 47. On the contact V2, the interconnect layer 28 is provided penetrating the insulating layer 48.

In the contact area CA, each support pillar HR has the same structure as that in FIG. 11 described in the first embodiment. Each of the support pillars HR includes the lower pillar HR_L and the upper pillar HR_U. The lower pillar HR_L penetrates the lower layer stack L_CR in the Z direction. The lower pillar HR_L includes the insulator 52. The upper pillar HR_U penetrates the upper layer stack U_CR in the Z direction. The upper pillar HR_U includes the insulator 52.

### 4.6 Cross-sectional Structure of Peripheral Region

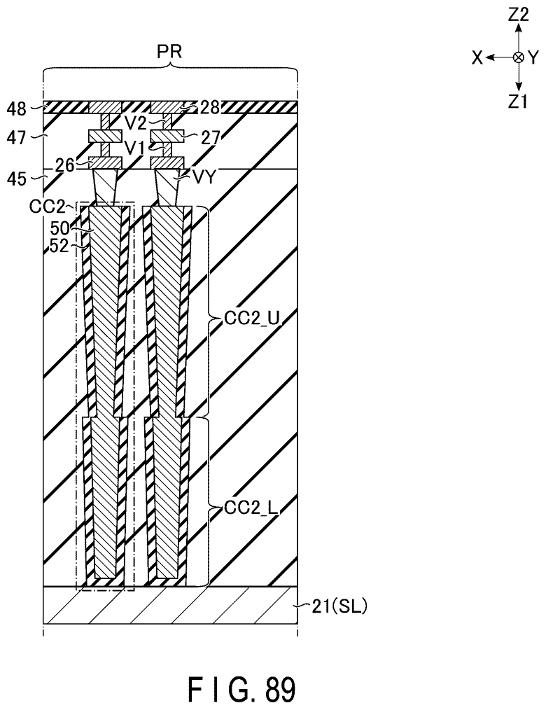

FIG. 89 is a cross-sectional view illustrating an example of a cross-sectional structure in the peripheral region PR of the semiconductor memory device 3 according to the fourth embodiment. As illustrated in FIG. 89, the contacts CC2 (each of the lower and upper contacts CC2_L and CC2_U) are arranged in the peripheral region PR, extend in the Z direction, and are provided in the insulating layer 45. Each contact CC2 includes the insulator 52 and the conductor 50 embedded in the insulator 52. The insulator 52 covers the side surface and the bottom surface of the conductor 50. In other words, the position of the upper end of the conductor 50 is the same as the position of the upper end of the insulator 52. At the junction portion between the lower and upper contacts CC2_L and CC2_U, the side surfaces of the lower and upper contacts CC2_L and CC2_U are shifted from each other.

Holes corresponding to the contacts CC2 are formed in a step of forming holes for the support pillars HR. Therefore, the contacts CC2 each have, for example, a circular cross-sectional shape in the XY plane. The cross-sectional area of the lower contact CC2_L is larger than the cross-sectional area of the lower pillar HR_L. The cross-sectional area of the upper contact CC2_U is larger than the cross-sectional area of the upper pillar HR_U. That is, each contact CC2 has a structure in which the conductor 50 is embedded in the support pillar HR (insulator 52).

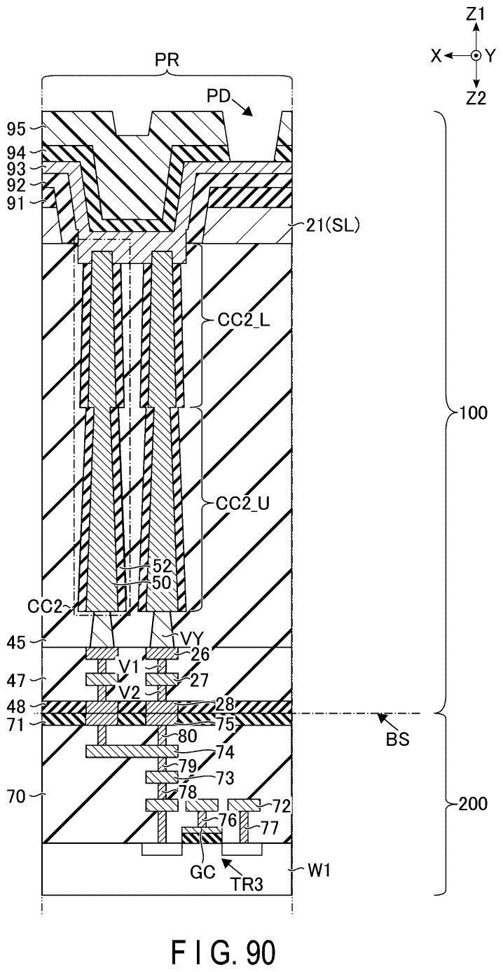

FIG. 90 is a cross-sectional view illustrating an example of a cross-sectional structure of the peripheral region PR of the semiconductor memory device 3 according to the fourth embodiment. FIG. 90 illustrates a cross-sectional structure of the peripheral region PR of the semiconductor memory device 3, and shows coordinate axes based on the semiconductor substrate W1. FIG. 90 illustrates a state in which the array chip 100 is provided on the bonding surface BS of the circuit chip 200 in the Z direction after the semiconductor substrate W2 is removed.

As illustrated in FIG. 90, in the peripheral region PR, the upper contact CC2_U is in contact with the lower end of the lower contact CC2_L. The upper portion of the conductor 50 is not covered with the insulator 51. The upper portion of the contact CC2 (conductor 50) is covered with the interconnect layer 93 and connected to the interconnect layer 93. In other words, the contact CC2_L is connected to the interconnect layer 93 above the lower layer stack L_OR.

### 4.7 Method of Manufacturing Semiconductor Memory Device

A method of manufacturing the semiconductor memory device 3 according to the present embodiment will be described. In the following, the steps up to the formation of the contacts CC2 will be described. For example, after the end portions of the interconnect layers 22 to 25 are processed in the stepped structure, the insulating layer 45 is formed. Then, the step of forming the support pillar HR in the contact area CA and the step of forming the insulator 52 in the holes 2H_L and 2H_U corresponding to the contact CC2 in the peripheral region PR are simultaneously performed. Thereafter, the holes 2H_L and 2H_U are filled with the conductor 50. As a result, the contacts CC2 are formed.

### 4.8 Effects According to Present Embodiment

In the semiconductor memory device 3 according to the present embodiment, as described above, the contacts CC2 are formed using the support pillars HR. Therefore, the steps of processing insulating layers can be merged. As a result, the number of manufacturing steps can be reduced as compared with the case where the formation of the support pillars HR and the formation of the insulator 52 in the holes 2H_L and 2H_U are performed in separate steps. Therefore, according to the semiconductor memory device 3 according to the present embodiment, the manufacturing cost can be reduced, similarly to the first embodiment.

### 4.9 Modification

A semiconductor memory device according to a modification of the fourth embodiment will be described. In a semiconductor memory device 3 according to the present modification, the structure of the contacts CC2 is different from that of the fourth embodiment. In the following, the differences from the fourth embodiment will be mainly described.

### 4.9.1 Cross-Sectional Structure of Peripheral Region

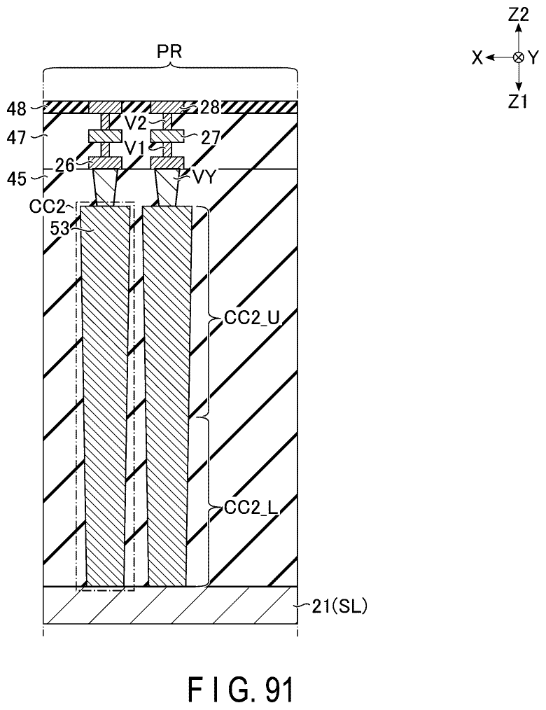

FIG. 91 is a cross-sectional view illustrating an example of a cross-sectional structure in the peripheral region PR of the semiconductor memory device 3 according to the modification of the fourth embodiment. As illustrated in FIG. 91, the contact CC2 (each of the lower and upper contacts CC2_L and CC2_U) includes a conductor 53. At the junction portion between the lower and upper contacts CC2_L and CC2_U, the side surfaces of the lower and upper contacts CC2_L and CC2_U are not shifted from each other.

Holes corresponding to the contacts CC2 are formed in a step of forming holes for members SLT. Therefore, the contacts CC2 each have, for example, an elliptical cross-sectional shape in the XY plane. Each contact CC2 may include an insulator, and the insulator may cover the side surface of the conductor 53.

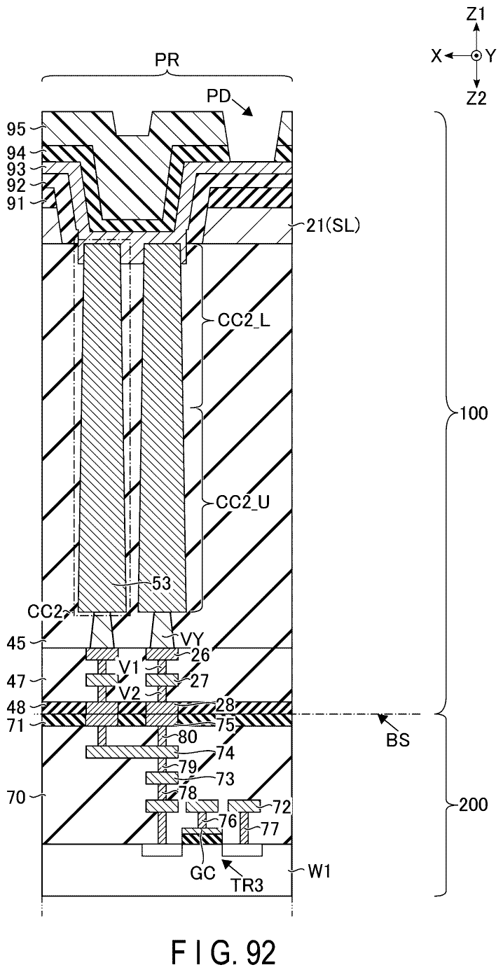

FIG. 92 is a cross-sectional view illustrating an example of a cross-sectional structure of the peripheral region PR of the semiconductor memory device 3 according to the modification of the fourth embodiment. FIG. 92 illustrates a cross-sectional structure of the peripheral region PR of the semiconductor memory device 3, and shows coordinate axes based on the semiconductor substrate W1. FIG. 92 illustrates a state in which the array chip 100 is provided on the bonding surface BS of the circuit chip 200 in the Z direction after the semiconductor substrate W2 is removed.

As illustrated in FIG. 92, in the peripheral region PR, the upper contact CC2_U is in contact with the lower end of the lower contact CC2_L. The upper portion of the contact CC2 (conductor 53) is covered with the interconnect layer 93 and connected to the interconnect layer 93. In other words, the contact CC2_L is connected to the interconnect layer 93 above the lower layer stack L_OR.

### 4.9.2 Method of Manufacturing Semiconductor Memory Device

A method of manufacturing the semiconductor memory device 3 according to the present modification will be described. In the following, the steps up to the formation of the contacts CC2 will be described. For example, after the end portions of the interconnect layers 22 to 25 are processed in the stepped structure, the insulating layer 45 is formed. Next, a step of forming holes SH corresponding to the members SLT in the contact area CA and a step of forming holes 2H (not illustrated) corresponding to the contacts CC2 in the peripheral region PR are simultaneously performed. Thereafter, after the insulator 54 is formed in each hole SH, each of the holes SH and 2H is filled with the conductor 53. As a result, the contacts CC2 are formed.

### 4.9.3 Effects According to Present Modification

In the semiconductor memory device 3 according to the present modification, as described above, the contacts CC2 are formed using the member SLT. More specifically, after the step of forming the holes SH corresponding to the members SLT in the contact area CA and the step of forming the holes 2H corresponding to the contacts CC2 in the peripheral region PR are simultaneously performed, each of the holes SH and 2H is embedded with the conductor 53. As a result, the contacts CC2 are formed. Therefore, the steps of processing insulating layers can be merged. As a result, the number of manufacturing steps can be reduced as compared with a case where the formation of the holes SH and the embedding of the conductor 53 in the holes SH, and the formation of the holes 2H and the embedding of the conductor 53 in the holes 2H are performed in separate steps. Therefore, according to the semiconductor memory device 3 according to the present modification, the manufacturing cost can be reduced, similarly to the first embodiment.

### 5. OTHERS

As described above, the semiconductor memory device (3) according to any one of the embodiments includes a first chip (200) and a second chip (100) provided on a first surface (BS) of the first chip (200) in a first direction (Z). The second chip (100) includes: a first region (CR) including a first layer stack (L_CR) in which a plurality of first insulating layers (41, 42) and a plurality of first interconnect layers (22, 23) are alternately stacked in the first direction (Z); a second region (PR) including a second layer stack (L_OR) in which the plurality of first insulating layers (41, 42) and a plurality of second insulating layers (61, 62) are alternately stacked in the first direction (Z); a first memory pillar (MP_L) arranged in the first region (CR) and penetrating the first layer stack (L_CR) in the first direction (Z); and a first contact (CC2_L) arranged in the second region (PR), penetrating the second layer stack (L_CR) in the first direction (Z), and connected to a second interconnect layer (93) above the second layer stack (L_OR).

Note that embodiments are not limited to those described above, and various modifications are possible.

The manufacturing steps described in the above embodiments are merely examples, and the present invention is not limited thereto. For example, another processing may be inserted between manufacturing steps, or some steps may be omitted or integrated. In addition, manufacturing steps may be interchanged if possible.

The interconnect layer to which the contacts CC2 are connected is not limited to the interconnect layer 93. The interconnect layer to which the contacts CC3 are connected is not limited to the interconnect layer 21. The contacts CC2 and CC3 may be connected to other interconnect layers. The other interconnect layers include, for example, tungsten, copper, titanium, titanium nitride, tantalum, or tantalum nitride.

The two contacts CC2 illustrated in FIG. 12 may be formed by, for example, one contact CC2.

The contacts CC3 illustrated in FIG. 12 may each include a lower contact CC3_L and an upper contact CC3_U. In that case, at the junction portion between the lower and upper contacts CC3_L and CC3_U, the side surfaces of the lower and upper contacts CC3_L and CC3_U may or may not be shifted from each other.

The contact CC3 may be formed using the contact CC1 or may be formed using the support pillar HR.

The member SLT may include a lower member SLT and an upper member SLT. In that case, at the junction portion between the lower and upper members SLT, the side surfaces of the lower and upper members SLT may or may not be shifted from each other.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a first chip; and
a second chip provided on a first surface of the first chip in a first direction,
wherein the second chip includes:
a first region including a first layer stack in which a plurality of first insulating layers and a plurality of first interconnect layers are alternately stacked in the first direction;
a second region including a second layer stack in which the plurality of first insulating layers and a plurality of second insulating layers are alternately stacked in the first direction;
a first memory pillar arranged in the first region and penetrating the first layer stack in the first direction; and
a first contact arranged in the second region, penetrating the second layer stack in the first direction, and connected to a second interconnect layer above the second layer stack.

2. The device according to claim 1, wherein
the second chip further includes:
a second contact arranged in the first region, extending in the first direction, and connected to one of the plurality of first interconnect layers; and
each of the first contact and the second contact includes a first conductor and a first insulator covering at least a portion of a side surface of the first conductor.

3. The device according to claim 2, wherein
the first contact has a circular cross-sectional shape.

4. The device according to claim 2, wherein
the first region further includes
a third layer stack in which a plurality of third insulating layers and a plurality of third interconnect layers are alternately stacked in the first direction,
the second region further includes
a fourth layer stack in which the plurality of third insulating layers and a plurality of fourth insulating layers are alternately stacked in the first direction,
the second chip further includes
a second memory pillar arranged in the first region, penetrating the third layer stack in the first direction, and being in contact with a lower end of the first memory pillar, and
a third contact arranged in the second region, penetrating the fourth layer stack in the first direction, and being in contact with a lower end of the first contact,
the third contact includes the first conductor and the first insulator covering at least a portion of the side surface of the first conductor, and
side surfaces of the first contact and the third contact are shifted from each other at a junction portion between the first contact and the third contact.

5. The device according to claim 2, wherein
the first region further includes
a third layer stack in which a plurality of third insulating layers and a plurality of third interconnect layers are alternately stacked in the first direction,
the second region further includes
a fourth layer stack in which the plurality of third insulating layers and a plurality of fourth insulating layers are alternately stacked in the first direction,
the second chip further includes
a second memory pillar arranged in the first region, penetrating the third layer stack in the first direction, and being in contact with a lower end of the first memory pillar, and
a third contact arranged in the second region, penetrating the fourth layer stack in the first direction, and being in contact with a lower end of the first contact,
the third contact includes the first conductor and the first insulator covering at least a portion of the side surface of the first conductor, and
side surfaces of the first contact and the third contact are not shifted from each other at a junction portion between the first contact and the third contact.

6. The device according to claim 1, wherein
the second chip further includes
a first member that is arranged in the first region, extends in the first direction and a second direction intersecting the first direction, and divides the first layer stack in a third direction intersecting
the first direction and the second direction,
the first contact includes a first conductor, and the first contact has an elliptical cross-sectional shape.

7. The device according to claim 6, wherein
the first member includes a second conductor and a first insulator covering a side surface of the second conductor.

8. The device according to claim 6, wherein
the first region further includes
a third layer stack in which a plurality of third insulating layers and a plurality of third interconnect layers are alternately stacked in the first direction,
the second region further includes
a fourth layer stack in which the plurality of third insulating layers and a plurality of fourth insulating layers are alternately stacked in the first direction,
the second chip further includes
a second memory pillar arranged in the first region, penetrating the third layer stack in the first direction, and being in contact with a lower end of the first memory pillar, and
a second contact arranged in the second region, penetrating the fourth layer stack in the first direction, and being in contact with a lower end of the first contact,
the second contact includes the first conductor, and
side surfaces of the first contact and the second contact are not shifted from each other at a junction portion between the first contact and the second contact.

9. The device according to claim 6, wherein
the first region further includes
a third layer stack in which a plurality of third insulating layers and a plurality of third interconnect layers are alternately stacked in the first direction,
the second region further includes
a fourth layer stack in which the plurality of third insulating layers and a plurality of fourth insulating layers are alternately stacked in the first direction,
the second chip further includes
a second memory pillar arranged in the first region, penetrating the third layer stack in the first direction, and being in contact with a lower end of the first memory pillar, and
a second contact arranged in the second region, penetrating the fourth layer stack in the first direction, and being in contact with a lower end of the first contact,
the second contact includes the first conductor, and
side surfaces of the first contact and the second contact are shifted from each other at a junction portion between the first contact and the second contact.

10. The device according to claim 1, wherein
the second chip further includes
a first insulating pillar arranged in the first region and penetrating the first layer stack in the first direction,
the first insulating pillar and the first contact each include a first insulator, and
the first contact further includes a first conductor embedded in the first insulator.

11. The device according to claim 10, wherein
the first contact has a circular cross-sectional shape.

12. The device according to claim 10, wherein
the first region further includes
a third layer stack in which a plurality of third insulating layers and a plurality of third interconnect layers are alternately stacked in the first direction,
the second region further includes
a fourth layer stack in which the plurality of third insulating layers and a plurality of fourth insulating layers are alternately stacked in the first direction,
the second chip further includes
a second memory pillar arranged in the first region, penetrating the third layer stack in the first direction, and being in contact with a lower end of the first memory pillar, and
a second contact arranged in the second region, penetrating the fourth layer stack in the first direction, and being in contact with a lower end of the first contact,
the second contact includes the first insulator and the first conductor embedded in the first insulator, and
side surfaces of the first contact and the second contact are shifted from each other at a junction portion between the first contact and the second contact.

13. The device according to claim 10, wherein
a cross-sectional area of the first contact is larger than a cross-sectional area of the first insulating pillar.

14. The device according to claim 10, wherein
the second chip further includes
a second contact arranged in the first region, extending in the first direction, and connected to one of the first interconnect layers, and
a lower surface of the first contact is positioned above a lower surface of the second contact.

15. The device according to claim 1, wherein
the second interconnect layer includes aluminum, tungsten, copper, titanium, titanium nitride, tantalum, or tantalum nitride.

16. A semiconductor memory device comprising:
a first chip; and
a second chip provided on a first surface of the first chip in a first direction,
wherein the second chip includes:
a first region including a first layer stack in which a plurality of first insulating layers and a plurality of first interconnect layers are alternately stacked in the first direction;
a second region including a second insulating layer provided in the same layer as the first layer stack;
a first memory pillar arranged in the first region and penetrating the first layer stack in the first direction; and
a first contact arranged in the second region, extending in the first direction, provided in the second insulating layer, and connected to a second interconnect layer above the second insulating layer,
wherein end portions of the first interconnect layers are provided in a stepped structure.

17. The device according to claim 16, wherein
the second chip further includes
a first member that is arranged in the first region, extends in the first direction and a second direction intersecting the first direction, and divides the first layer stack in a third direction intersecting
the first direction and the second direction,
the first contact includes a first conductor, and the first contact has an elliptical cross-sectional shape.

18. The device according to claim 16, wherein
the second chip further includes
a first insulating pillar arranged in the first region and penetrating the first layer stack in the first direction,
the first insulating pillar and the first contact each include a first insulator, and
the first contact further includes a first conductor embedded in the first insulator.

19. The device according to claim 18, wherein
a cross-sectional area of the first contact is larger than a cross-sectional area of the first insulating pillar.

20. The device according to claim 1, wherein
a portion of an upper portion of the second interconnect layer is a pad.
